(19) United States
(12) Patent Application Publication
(10) Pub. No.: US 2021/0132503 A1
(43) Pub. Date: May 6, 2021

(54) CHEMICAL LIQUID, KIT, PATTERN FORMING METHOD, CHEMICAL LIQUID MANUFACTURING METHOD, AND CHEMICAL LIQUID STORAGE BODY

(71) Applicant: FUJIFILM Corporation, Tokyo (JP)

(72) Inventors: Tadashi OOMATSU, Shizuoka (JP); Tetsuya KAMIMURA, Shizuoka (JP); Tetsuya SHIMIZU, Shizuoka (JP); Satomi TAKAHASHI, Shizuoka (JP); Akihiko OHTSU, Shizuoka (JP)

(73) Assignee: FUJIFILM Corporation, Tokyo (JP)

(21) Appl. No.: 17/144,259

(22) Filed: Jan. 8, 2021

Related U.S. Application Data
(63) Continuation of application No. PCT/JP2019/027289, filed on Jul. 10, 2019.

(30) Foreign Application Priority Data
Jul. 13, 2018 (JP) 2018-133580

(51) Int. Cl. G03F 7/40; G03F 7/32; C11D 3/43; C11D 3/20; C11D 3/04; C11D 3/12; C11D 3/34; C11D 11/00

(52) U.S. Cl. CPC G03F 7/405; G03F 7/325; C11D 3/43; C11D 3/2079; C11D 3/2082; C11D 3/2086; H01L 21/02087; C11D 3/1206; C11D 3/046; C11D 3/349; C11D 3/2093; C11D 11/0047; C11D 3/042

(57) ABSTRACT

An object of the present invention is to provide a chemical liquid which exhibits excellent defect inhibition performance even after long-term preservation, a kit, a pattern forming method, a chemical liquid manufacturing method, and a chemical liquid storage body. The chemical liquid according to an embodiment of the present invention is a chemical liquid containing an organic solvent, an acid component, and a metal component. The content of the acid component is equal to or greater than 1 mass ppt and equal to or smaller than 15 mass ppm with respect to the total mass of the chemical liquid. The content of the metal component is 0.001 to 100 mass ppt with respect to the total mass of the chemical liquid.

### CROSS-REFERENCE TO RELATED APPLICATIONS

This application is a Continuation of PCT International Application No. PCT/JP2019/027289 filed on Jul. 10, 2019, which claims priority under 35 U.S.C. § 119(a) to Japanese Patent Application No. 2018-133580 filed on Jul. 13, 2018. The above application is hereby expressly incorporated by reference, in its entirety, into the present application.

### BACKGROUND OF THE INVENTION

### 1. Field of the Invention

The present invention relates to a chemical liquid, a kit, a pattern forming method, a chemical liquid manufacturing method, and a chemical liquid storage body.

### 2. Description of the Related Art

In a case where semiconductor devices are manufactured by a wiring forming process including photolithography, as a prewet solution, a resist solution, a developer, a rinsing solution, a peeling solution, a chemical mechanical polishing (CMP) slurry, a washing solution used after CMP, and the like, a chemical liquid containing water and/or an organic solvent is used.

In some cases, various impurities contained in the chemical liquid cause defects in semiconductor devices. Such defects sometimes cause the reduction in manufacturing yield of semiconductor devices and an electrical abnormality such as a short circuit.

For example, JP2015-030700A discloses a method for obtaining an ester-based solvent with reduced acid component content and alkali metal content by devising a distillation method or the like. Furthermore, JP2002-316967A discloses a method for manufacturing butyl acetate with a reduced sulfuric acid content by distillation and a treatment using an anion exchange resin or the like.

### SUMMARY OF THE INVENTION

After being manufactured, the chemical liquid is stored in a container, preserved for a certain period of time in the form of a chemical liquid storage body, then taken out, and used.

The inventors of the present invention manufactured a chemical liquid with reference to the methods described in JP2015-030700A and JP2002-316967A, preserved the chemical liquid for a long period of time in the form of a chemical liquid storage body including a container storing the chemical liquid, then took the chemical liquid out of the chemical liquid storage body, and used the chemical liquid in a semiconductor device manufacturing process. As a result, it has been revealed that sometimes defects occur in a base material (for example, a wafer).

An object of the present invention is to provide a chemical liquid that exhibits excellent defect inhibition performance even after long-term preservation, a kit, a pattern forming method, a chemical liquid manufacturing method, and a chemical liquid storage body.

In order to achieve the above object, the inventors of the present invention conducted intensive studies. As a result, the inventors have found that in a case where a chemical liquid is used in which a mass ratio of a content of an acid component to a content of a metal component is within a predetermined range, the content of the acid component with respect to the total mass of the chemical liquid is within a predetermined range, and the content of the metal component with respect to the total mass of the chemical liquid is within a predetermined range, a chemical liquid exhibiting excellent defect inhibition performance even after long-term preservation is obtained. Based on this finding, the inventors have accomplished the present invention.

That is, the inventors of the present invention have found that the above object can be achieved by the following constitutions.

[1] A chemical liquid containing an organic solvent, an acid component, and a metal component,

in which a content of the acid component is equal to or greater than 1 mass ppt and equal to or smaller than 15 mass ppm with respect to a total mass of the chemical liquid, and

a content of the metal component is 0.001 to 100 mass ppt with respect to the total mass of the chemical liquid.

[2] The chemical liquid described in [1], in which a mass ratio of the content of the acid component to the content of the metal component is 10⁻² to 10⁶.

[3] The chemical liquid described in [1] or [2], in which the acid component includes an organic acid, and

a content of the organic acid is equal to or smaller than 1 mass ppm with respect to the total mass of the chemical liquid.

[4] The chemical liquid described in [3], in which the organic acid includes an organic acid having a boiling point equal to or higher than a boiling point of the organic solvent, and a content of the organic acid having a boiling point equal to or higher than a boiling point of the organic solvent is equal to or smaller than 20% by mass with respect to a total mass of the organic acid.

[5] The chemical liquid described in any one of [1] to [4], in which the acid component includes an inorganic acid,

and a content of the inorganic acid is equal to or smaller than 1 mass ppb with respect to the total mass of the chemical liquid.

[6] The chemical liquid described in any one of [1] to [5], in which the metal component includes metal-containing particles containing metal atoms, and

a content of the metal-containing particles is 0.00001 to 10 mass ppt with respect to the total mass of the chemical liquid.

[7] The chemical liquid described in [6], in which the metal-containing particles include metal nanoparticles having a particle size of 0.5 to 17 nm, and the number of the metal nanoparticles contained in a unit volume of the chemical liquid is 1.0×10⁻² to 1.0×10⁶ particles/cm³.

[8] The chemical liquid described in any one of [1] to [7], in which the metal component includes metal ions, and

a content of the metal ions is 0.01 to 100 mass ppt with respect to the total mass of the chemical liquid.

[9] The chemical liquid described in any one of [1] to [8], in which the metal component includes metal-containing particles and metal ions, and

a mass ratio of a content of the metal-containing particles to a content of the metal ions is 0.00001 to 1.

[10] The chemical liquid described in any one of [1] to [9], further containing water,

in which a content of the water is equal to or smaller than 1 mass ppm with respect to the total mass of the chemical liquid.

[11] The chemical liquid described in any one of [1] to [10], further containing at least one kind of organic compound selected from the group consisting of a compound having an amide structure, a compound having a sulfonamide structure, a compound having a phosphonamide structure, a compound having an imide structure, a compound having a urea structure, a compound having a urethane structure, and an organic acid ester,

in which a content of the organic compound is equal to or smaller than 1 mass ppm with respect to the total mass of the chemical liquid.

[12] The chemical liquid described in [11], in which the organic compound is an organic compound having a boiling point equal to or higher than 300° C.

[13] The chemical liquid described in [11] or [12], in which the organic acid ester includes at least one kind of compound selected from the group consisting of a phthalic acid ester and a citric acid ester.

[14] The chemical liquid described in any one of [1] to [13], in which the organic solvent includes an organic solvent having a boiling point equal to or lower than 250° C., and a content of the organic solvent having a boiling point equal to or lower than 250° C. is equal to or greater than 90% by mass with respect to a total mass of the organic solvent.

[15] The chemical liquid described in any one of [1] to [14], in which the organic solvent has an SP value equal to or smaller than 21.

[16] The chemical liquid described in any one of [1] to [15], in which the organic solvent has an ester structure.

[17] The chemical liquid described in any one of [1] to [16], in which the organic solvent includes butyl acetate, the acid component includes acetic acid, and

a content of the acetic acid is 0.01 to 15 mass ppm with respect to the total mass of the chemical liquid.

[18] The chemical liquid described in any one of [1] to [17], in which the organic solvent includes butyl acetate, the acid component includes n-butanoic acid, and

a content of the n-butanoic acid is equal to or greater than 1 mass ppt and equal to or smaller than 1 mass ppm with respect to the total mass of the chemical liquid.

[19] A kit comprising a chemical liquid X which is the chemical liquid described in [17] or [18] and

a chemical liquid Y which is a chemical liquid containing an organic solvent,

in which the organic solvent contained in the chemical liquid Y includes at least one kind of organic solvent Y selected from the group consisting of butyl butyrate, isobutyl isobutyrate, pentyl propionate, isopentyl propionate, ethylcyclohexane, mesitylene, decane, undecane, 3,7-dimethyl-3-octanol, 2-ethyl-1-hexanol, 1-octanol, 2-octanol, ethyl acetoacetate, dimethyl malonate, methyl pyruvate, and dimethyl oxalate.

[20] The kit described in [19], in which the chemical liquid X is a developer, and the chemical liquid Y is a rinsing solution.

[21] The kit described in [19] or [20], in which the organic solvent Y includes an organic solvent Y1 having a Hansen solubility parameter distance of 3 to 20 MPa^{0.5} to eicosene, and

a content of the organic solvent Y1 is 20% to 80% by mass with respect to a total mass of the chemical liquid Y.

[22] A pattern forming method, including a resist film forming step of forming a resist film by using an actinic ray-sensitive or radiation-sensitive resin composition,

an exposure step of exposing the resist film,

a development step of developing the exposed resist film by using the chemical liquid X which is the chemical liquid described in [17] or [18], and

a rinsing step of performing washing by using the chemical liquid Y containing an organic solvent after the development step,

in which the organic solvent contained in the chemical liquid Y includes at least one kind of organic solvent Y selected from the group consisting of butyl butyrate, isobutyl isobutyrate, pentyl propionate, isopentyl propionate, ethylcyclohexane, mesitylene, decane, undecane, 3,7-dimethyl-3-octanol, 2-ethyl-1-hexanol, 1-octanol, 2-octanol, ethyl acetoacetate, dimethyl malonate, methyl pyruvate, and dimethyl oxalate.

[23] The pattern forming method described in [22], in which the organic solvent Y includes an organic solvent Y1 having a Hansen solubility parameter distance of 3 to 20 MPa^{0.5} to eicosene, and

a content of the organic solvent Y1 is 20% to 80% by mass with respect to a total mass of the chemical liquid Y.

[24] A chemical liquid manufacturing method for obtaining the chemical liquid described in any one of [1] to [18] by purifying a substance to be purified containing an organic solvent,

the method including a filtration step of filtering the substance to be purified, an ion removing step of performing an ion exchange process or ion adsorption by a chelating group on the substance to be purified, and a distillation step of distilling the substance to be purified.

[25] The chemical liquid manufacturing method described in [24], in which a cation exchange resin is used in the ion exchange process.

[26] The chemical liquid manufacturing method described in [24], in which a cation exchange resin and an anion exchange resin are used in the ion exchange process.

[27] A chemical liquid storage body including a container and the chemical liquid described in any one of [1] to [18] that is stored in the container.

As will be described below, according to an aspect of the present invention, it is possible to provide a chemical liquid exhibiting excellent defect inhibition performance even after long-term preservation, a chemical liquid manufacturing method, and a chemical liquid storage body.

### DESCRIPTION OF THE PREFERRED EMBODIMENTS

Hereinafter, the present invention will be described.

The following constituents will be described based on typical embodiments of the present invention in some cases, but the present invention is not limited to the embodiments.

In the present specification, a range of numerical values described using “to” means a range including the numerical values listed before and after “to” as a lower limit and an upper limit respectively.

In the present invention, “ppm” means “parts-per-million (10⁻⁶)”, “ppb” means “parts-per-billion (10⁻⁹)”, “ppt” means “parts-per-trillion (10⁻¹²)”, and “ppq” means “parts-per-quadrillion (10⁻¹⁵)”.

In the present invention, regarding the description of a group (atomic group), in a case where whether the group is substituted or unsubstituted is not described, as long as the effects of the present invention are not impaired, the group includes a group which does not have a substituent and a group which has a substituent. For example, “hydrocarbon group” includes not only a hydrocarbon group which does not have a substituent (unsubstituted hydrocarbon group) but also a hydrocarbon group which has a substituent (substituted hydrocarbon group). The same is true of each compound.

Furthermore, in the present invention, “radiation” means, for example, far ultraviolet, extreme ultraviolet (EUV), X-rays, electron beams, and the like. In addition, in the present invention, light means actinic rays or radiation. In the present invention, unless otherwise specified, “exposure” includes not only exposure by far ultraviolet, X-rays, EUV, and the like, but also lithography by particle beams such as electron beams or ion beams.

In addition, in the present invention, “boiling point” means a normal boiling point.

[Chemical Liquid]

The chemical liquid according to an embodiment of the present invention (hereinafter, also called “the present chemical liquid”) is a chemical liquid containing an organic solvent, an acid component, and a metal component.

In the present chemical liquid, the content of the acid component is equal to or greater than 1 mass ppt and equal to or smaller than 15 mass ppm with respect to the total mass of the present chemical liquid.

In the present chemical liquid, the content of the metal component is 0.001 to 100 mass ppt with respect to the total mass of the present chemical liquid.

The mechanism through which the above object is achieved by the present chemical liquid is unclear. According to the inventors of the present invention, the mechanism is assumed to be as below. The following mechanism is speculative, and in a case where the effects of the present invention are obtained by another mechanism, such a mechanism is also included in the scope of the present invention.

The metal component contained in the chemical liquid tends to be present as metal ions in the form of ions and metal-containing particles in the form of particles.

In a case where the metal ions form a complex with the acid component (particularly, organic acid) in the chemical liquid and/or in a case where one or more metal ions and one or more acid components form a composite structure by the interaction between the metal ions and the acid components, the interaction between the complex or composite structure and the surface of a substrate (for example, a wafer) tends to be enhanced. As a result, the complex and the composite structure are further stabilized by adhering to the substrate surface than by being solvated in the chemical liquid, which leads to a problem in that the complex and the composite structure tend to remain as residues on a wafer surface after the chemical liquid is used for treating the wafer.

Furthermore, in a case where the complex and the composite structure remain on the wafer surface, the complex and the composite structure act as an etching mask during the dry etching performed on the wafer, which leads to a problem in that the complex and the composite structure remain on the wafer surface as bigger conical defects (cone-shaped defects) after the dry etching.

One of the examples of the conventional method of inspecting defects on the wafer surface is a method of coating a wafer with the chemical liquid and then measuring the number of defects remaining on the wafer surface. However, in recent years, as the defect inspection accuracy has been improved, the defects that were undetectable by the conventional method have become detectable in the form of amplified conical defects. That is, there is a problem in that the micro-sized adherents that were conventionally undetectable are detected as defects.

It is considered that the above problem may markedly occur particularly in a case where the chemical liquid is preserved in a container. For example, in a case where the chemical liquid is preserved in a container for a long period of time, sometimes the metal component is eluted into the chemical liquid by the permeation of a trace of acid component (particularly, an organic acid) in the chemical liquid into a resin member constituting a liquid contact surface of the container, the infiltration of the acid component (particularly, an organic acid) in the chemical liquid into minute voids of the resin member, the interaction between the acid component (particularly, an organic acid) in the chemical liquid and the metal component incorporated into the resin member in the process of manufacturing the resin member, or a combination of these. That is, it is considered that in a case where the chemical liquid is preserved in a container for a long period of time, the metal component present within the liquid contact surface of the container may be eluted into the chemical liquid, and hence defects may be easily detected.

Presumably, in a case where the content of the acid component and the metal component with respect to the chemical liquid is set to be equal to or smaller than the upper limit described above so as to solve the above problem, even though the chemical liquid storage body is preserved for a long period of time, the formation of the complex and the composite structure could be inhibited. It is considered that, as a result, the chemical liquid may exhibit excellent defect inhibition performance even after long-term preservation.

Furthermore, the inventors of the present invention have found that in a case where the content of the acid component in the chemical liquid is smaller than the lower limit described above, after the chemical liquid is preserved for a long period of time, the defect inhibition performance of the chemical liquid deteriorates. The reason is unclear but is assumed to be as below.

The chemical liquid contains traces of basic impurities in some cases. Examples of the basic impurities include amine components having migrated from the environment (so-called contamination), decomposition products of plasticizers, impurities existing in the process of synthesizing a resin constituting the container in the chemical liquid storage body, and the like.

In a case where the chemical liquid contains traces of basic impurities, by these impurities and traces of water present in the chemical liquid, sometimes the decomposition reaction of the resin member constituting the liquid contact surface of the container in the chemical liquid storage body slowly proceeds. It is considered that as the liquid contact surface deteriorates due to the decomposition of the resin member, the decomposition products of the resin member, the metal component incorporated into the resin member in the process of manufacturing the resin member, and the like may be eluted into the chemical liquid and accumulate in the chemical liquid with the passage of time, and hence defects may be easily detected in a case where the chemical liquid is preserved in the container for a long period of time.

It is considered that in a case where the content of the acid component in the chemical liquid is set to be equal to or greater than the lower limit described above so as to solve the above problem, it may be possible to inhibit the basic impurities-induced decomposition reaction of the material constituting the liquid contact surface of the container. Presumably, as a result, it may be possible to inhibit the occurrence of defects in a case where the chemical liquid is preserved in the container for a long period of time.

[Organic Solvent]

The present chemical liquid contains an organic solvent. The content of the organic solvent in the present chemical liquid is not particularly limited. Generally, the content of the organic solvent with respect to the total mass of the present chemical liquid is preferably equal to or greater than 98.0% by mass, more preferably equal to or greater than 99.0% by mass, even more preferably equal to or greater than 99.9% by mass, and particularly preferably equal to or greater than 99.99% by mass. The upper limit thereof is not particularly limited, but is less than 100% by mass in many cases.

One kind of organic solvent may be used singly, or two or more kinds of organic solvents may be used in combination. In a case where two or more kinds of organic solvents are used in combination, the total content thereof is within the above range.

In the present specification, “organic solvent” means a liquid organic compound contained in the present chemical liquid at a content greater than 10,000 mass ppm per component with respect to the total mass of the present chemical liquid. That is, in the present specification, a liquid organic compound contained in an amount greater than 10,000 mass ppm with respect to the total mass of the present chemical liquid corresponds to an organic solvent.

In the present specification, “liquid” means that the compound stays in liquid form at 25° C. under atmospheric pressure.

The type of the organic solvent is not particularly limited, and known organic solvents can be used. Examples of the organic solvent include alkylene glycol monoalkyl ether carboxylate, alkylene glycol monoalkyl ether, a carboxylic acid ester (preferably an acetic acid alkyl ester or a lactic acid alkyl ester), alkoxyalkyl propionate, cyclic lactone (preferably having 4 to 10 carbon atoms), a monoketone compound which may have a ring (preferably having 4 to 10 carbon atoms), alkylene carbonate, alkoxyalkyl acetate, alkyl pyruvate, and the like.

Furthermore, as the organic solvent, those described in JP2016-057614A, JP2014-219664A, JP2016-138219A, and JP2015-135379A may be used.

As the organic solvent, at least one kind of compound is preferable which is selected from the group consisting of propylene glycol monomethyl ether, propylene glycol monoethyl ether (PGME), propylene glycol monopropyl ether, propylene glycol monomethyl ether acetate (PGMEA), ethyl lactate (EL), methyl methoxypropionate, cyclopentanone, cyclohexanone (CHN), γ-butyrolactone, diisoamyl ether, butyl acetate (nBA), isoamyl acetate (iAA), isopropanol, 4-methyl-2-pentanol (MIBC), dimethyl sulfoxide, n-methyl-2-pyrrolidone, diethylene glycol, ethylene glycol, dipropylene glycol, propylene glycol, ethylene carbonate, propylene carbonate (PC), sulfolane, cycloheptanone, 1-hexanol, decane, 2-heptanone, butyl butyrate, isobutyl isobutyrate, pentyl propionate, isopentyl propionate, ethylcyclohexane, mesitylene, decane, undecane, 3,7-dimethyl-3-octanol, 2-ethyl-1-hexanol, 1-octanol, 2-octanol, ethyl acetoacetate, dimethyl malonate, methyl pyruvate, and dimethyl oxalate.

One kind of organic solvent may be used singly, or two or more kinds of organic solvents may be used in combination.

The type and content of the organic solvent in the chemical liquid can be measured using a gas chromatography mass spectrometry.

It is preferable that the organic solvent has an ester structure because then the effects of the present invention (specifically, excellent defect inhibition performance exhibited even after long-term preservation, the same is true of the following description) are exhibited further. Examples of the organic solvent having an ester structure include an aliphatic carboxylic acid alkyl ester, an alicyclic carboxylic acid alkyl ester, and a substituted aliphatic carboxylic acid alkyl ester (that is, an aliphatic carboxylic acid alkyl ester having a substituent in an aliphatic portion). The alkyl group in the alkyl ester portion may have a substituent. Examples of the substituent include a hydroxy group, an ether bond, a thiol group, a sulfide bond, an amino group, an ester bond, an aromatic group (for example, a phenyl group), and the like. The alkyl group in the alkyl ester portion may be linear or branched or may form one ring or two or more rings.

Specific examples of the organic solvent having an ester structure include alkylene glycol monoalkyl ether carboxylate, an acetic acid alkyl ester, a lactic acid alkyl ester, alkoxyalkyl propionate, and a cyclic lactone. In view of making the effects of the present invention further exhibited, at least one kind of compound is preferable which is selected from the group consisting of propylene glycol monomethyl ether acetate (PGMEA), ethyl lactate (EL), butyl acetate (nBA) and isoamyl acetate (iAA).

The SP (Solubility Parameter) value of the organic solvent is preferably equal to or smaller than 21, more preferably equal to or smaller than 20, and particularly preferably equal to or smaller than 19.

In a system in which the SP value of the organic solvent is small (hydrophobic system), the action of solvation in the organic solvent weakens, and hence the interaction between an acid component (particularly, an organic acid) and a metal component is relatively enhanced, which leads to a problem in that defects easily occur due to the formation of a complex. In a case where the present chemical liquid with a reduced acid component (particularly, an organic acid) content is used to solve the above problem, the formation of a complex can be inhibited. Accordingly, even though organic solvent having a small SP value is used, the effect of the defect inhibition performance is sufficiently exhibited.

In view of making the effects of the present invention further exhibited, the lower limit of the SP value of the organic solvent is preferably equal to or greater than 14.5, and more preferably equal to or greater than 15.0.

The SP value is calculated using the Fedors method described in “Properties of Polymers, 2nd edition, published in 1976”. Unless otherwise specified, the unit of SP value is MPa^{1/2}.

In view of making the effects of the present invention further exhibited, it is preferable that the organic solvent includes an organic solvent having a boiling point equal to or lower than 250° C., and the content of this organic solvent is equal to or greater than 90% by mass with respect to the total mass of the organic solvents.

In view of making the effects of the present invention further exhibited, the content of the organic solvent having a boiling point equal to or lower than 250° C. with respect to the total mass of the organic solvents is preferably equal to or greater than 90% by mass, more preferably equal to or greater than 95% by mass, even more preferably equal to or greater than 99% by mass, and particularly preferably 100% by mass.

The boiling point of the organic solvent is preferably equal to or lower than 250° C., and more preferably equal to or lower than 170° C.

In a case where the boiling point of the organic solvent is equal to or higher than 170° C., the drying speed of the chemical liquid with which a substrate is coated is reduced. However, particles formed of the metal component, the acid component, and the like are easily removed because they are evaporated from the substrate together with the solvent before the drying of a liquid film in spin coating. On the other hand, in a case where the boiling point of the organic solvent is equal to or lower than 170° C., there is a problem in that the particles easily remain on the substrate. In a case where the present chemical liquid is used to solve the problem, the formation of particles can be inhibited. Therefore, even though an organic solvent having a low boiling point is used, the effect of the defect inhibition performance is sufficiently exhibited.

Therefore, in a case where the present chemical liquid is used, the effect of defect inhibition performance is sufficiently exhibited, even though an organic solvent (for example, propylene glycol monomethyl ether acetate, butyl acetate, or isoamyl acetate) having a boiling point equal to or lower than 170° C. and an SP value equal to or smaller than 21 is used.

The lower limit of the boiling point of the organic solvent is not particularly limited, but is preferably equal to or higher than 80° C., and more preferably equal to or higher than 90° C.

[Acid Component]

The present chemical liquid contains an acid component.

The acid component may be intentionally added in the chemical liquid manufacturing process, may be contained in a substance to be purified from the first, or may migrate from a chemical liquid manufacturing device or the like in the chemical liquid manufacturing process (so-called contamination).

The content of the acid component with respect to the total mass of the present chemical liquid is equal to or greater than 1 mass ppt and equal to or smaller than 1 mass ppm, preferably equal to or smaller than 1 mass ppm, and more preferably equal to or smaller than 0.1 mass ppm. Furthermore, the content of the acid component is preferably equal to or greater than 10 mass ppt, and more preferably equal to or greater than 30 mass ppt.

The content of the acid component is not particularly limited, and may be appropriately set such that the pH falls into a desired range.

One kind of acid component may be used singly, or two or more kinds of acid components may be used in combination. In a case where the chemical liquid contains two or more kinds of acid components, the total content thereof is within the above range.

The acid component is not particularly limited, and examples thereof include an organic acid and an inorganic acid. The acid component may be present as ions by being ionized in the chemical liquid.

<Organic Acid>

Examples of the organic acid include organic carboxylic acid, organic sulfonic acid, organic phosphoric acid, organic phosphonic acid, and the like. Among these, organic carboxylic acid is preferable.

Examples of the organic carboxylic acid include formic acid, acetic acid, propionic acid, n-butanoic acid, pentanoic acid, lactic acid, adipic acid, maleic acid, fumaric acid, 2-methylbutyric acid, n-hexanoic acid, 3,3-dimethylbutyric acid, 2-ethylbutyric acid, 4-methylpentanoic acid, n-heptanoic acid, 2-methylhexanoic acid, n-octanoic acid, 2-ethylhexanoic acid, benzoic acid, glycolic acid, salicylic acid, glyceric acid, oxalic acid, malonic acid, succinic acid, glutaric acid, pimelic acid, phthalic acid, malic acid, tartaric acid, citric acid, hydroxyethyliminodiacetic acid, iminodiacetic acid, and the like.

Examples of the organic sulfonic acid include methanesulfonic acid, ethanesulfonic acid, trifluoromethanesulfonic acid, benzenesulfonic acid, p-toluenesulfonic acid, and the like.

Examples of the organic phosphoric acid include monooctyl or dioctyl phosphate, monododecyl or didodecyl phosphate, monooctadecyl or dioctadecyl phosphate, mono-(nonylphenyl) or di-(nonylphenyl) phosphate, and the like.

Examples of the organic phosphonic acid include 1-hydroxyethane-1,1-diphosphonic acid, aminotri(methylenephosphonic acid), ethylenediaminetetra(methylenephosphonic acid), and the like.

pKa of the organic acid is preferably equal to or lower than 5 and more preferably equal to or lower than 4, because then the formation of a complex with a metal component can be further inhibited.

The lower limit of pKa of the organic acid is preferably equal to or higher than −11 and more preferably equal to or higher than −9, because then the effects of the present invention are further exhibited.

The pKa (acid dissociation constant) mentioned herein means pKa in an aqueous solution and is described, for example, in Chemistry Guide (II) (4th revised edition, 1993, edited by The Chemical Society of Japan, Maruzen Publishing Co., Ltd). The lower the value of pKa, the stronger the acid. Specifically, pKa in an aqueous solution can be obtained by measuring an acid dissociation constant at 25° C. by using an infinitely diluted aqueous solution. Furthermore, by using the following software package 1, a value based on the Hammett substituent constant and the database of values in known documents can be determined by calculation. All of the values of pKa described in the present specification are values determined by calculation by using the software package.

(Software Package 1) Advanced Chemistry Development (ACD/Labs) Software V8.14 for Solaris (1994-2007 ACD/Labs)

In view of further improving the defect inhibition performance, the boiling point of the organic acid is preferably equal to or lower than 300° C., more preferably equal to or lower than 250° C., and particularly preferably equal to or lower than 200° C.

The lower limit of the boiling point of the organic acid is not particularly limited, but is preferably equal to or higher than 100° C. and more preferably equal to or higher than 110° C.

In a case where the acid component includes an organic acid, in view of further improving the defect inhibition performance, the content of the organic acid with respect to the total mass of the present chemical liquid is preferably equal to or smaller than 1 mass ppm, more preferably equal to or smaller than 0.5 mass ppm, and particularly preferably equal to or smaller than 0.1 mass ppm.

In a case where the acid component includes an organic acid, in view of making the effects of the present invention further exhibited, the lower limit of the content of the organic acid with respect to the total mass of the present chemical liquid is preferably equal to or greater than 5 mass ppt, and more preferably equal to or greater than 10 mass ppt.

One kind of organic acid may be used singly, or two or more kinds of organic acids may be used in combination. In a case where the chemical liquid contains two or more kinds of organic acids, the total content thereof is preferably within the above range.

In view of further improving the defect inhibition performance, the content of an organic acid, which is included in the above organic acid and has a boiling point equal to or higher than the boiling point of the organic solvent, with respect to the total mass of the organic acids is preferably equal to or smaller than 20% by mass, more preferably equal to or smaller than 15% by mass, and particularly preferably equal to or smaller than 10% by mass.

In view of making the effects of the present invention further exhibited, the lower limit of the content of the organic acid, which has a boiling point equal to or higher than the boiling point of the organic solvent, with respect to the total mass of the organic acids is preferably equal to or greater than 0% by mass, and more preferably equal to or greater than 0.01% by mass.

In a case where the organic solvent includes butyl acetate, it is preferable that the acid component includes acetic acid. In this case, in view of further improving the defect inhibition performance, the content of the acetic acid with respect to the total mass of the present chemical liquid is preferably 0.001 to 15 mass ppm, more preferably 0.001 to 10 mass ppm, and particularly preferably 0.001 to 5 mass ppm.

In a case where the organic solvent includes butyl acetate, it is preferable that the acid component includes n-butanoic acid. In this case, the content of the n-butanoic acid with respect to the total mass of the present chemical liquid is preferably equal to or greater than 1 mass ppt and equal to or smaller than 1 mass ppm, more preferably equal to or greater than 1 mass ppt and equal to or smaller than 0.5 mass ppm, and particularly preferably equal to or greater than 1 mass ppt and equal to or smaller than 0.1 mass ppm.

In a case where the organic solvent includes butyl acetate, in view of further improving the defect inhibition performance, it is preferable that the acid component includes both the acetic acid and n-butanoic acid. In this case, the suitable range of the content of each component is as described above.

<Inorganic Acid>

Examples of the inorganic acid include boric acid, nitric acid, hydrochloric acid, sulfuric acid, and phosphoric acid.

In a case where the acid component includes an inorganic acid, in view of further improving the defect inhibition performance, the content of the inorganic acid with respect to the total mass of the present chemical liquid is preferably equal to or smaller than 120 mass ppb, more preferably equal to or smaller than 1 mass ppb, and particularly preferably equal to or smaller than 0.6 mass ppb.

In view of making the effects of the present invention further exhibited, the lower limit of the content of the inorganic acid with respect to the total mass of the present chemical liquid is preferably equal to or greater than 0 mass ppb, and more preferably equal to or greater than 0.001 mass ppb.

[Metal Component]

The present chemical liquid contains a metal component. Examples of the metal component include metal-containing particles and metal ions. For example, the content of the metal component means the total content of metal-containing particles and metal ions.

Although a suitable aspect of the chemical liquid manufacturing method will be described later, the chemical liquid can be generally manufactured by purifying a substance to be purified containing the solvent and the organic compound described above. The metal component may be intentionally added in the chemical liquid manufacturing process, may be contained in the substance to be purified from the first, or may migrate from a chemical liquid manufacturing device or the like (so-called contamination) in the chemical liquid manufacturing process.

The content of the metal component is 0.001 to 100 mass ppt with respect to the total mass of the present chemical liquid. In view of making the effects of the present invention further exhibited, the content of the metal component is preferably 0.001 to 10 mass ppt, and more preferably 0.001 to 5 mass ppt.

The content of the metal component is measured by ICP-MS which will be described later.

In view of further improving the defect inhibition performance, in the present chemical liquid, the mass ratio of the content of the acid component to the content of the metal component (acid component/metal component) is preferably 10⁻² to 10⁶, more preferably and is preferably 1 to 10⁶, even more preferably 10 to 10⁶, particularly preferably 10² to 10⁶, and most preferably 10³ to 10⁶.

<Metal-Containing Particles>

The present chemical liquid may contain metal-containing particles containing metal atoms.

The metal atoms are not particularly limited, and examples thereof include lead (Pb) atoms, sodium (Na) atoms, potassium (K) atoms, calcium (Ca) atoms, iron (Fe) atoms, copper (Cu) atoms, magnesium (Mg) atoms, manganese (Mn) atoms, lithium (Li) atoms, aluminum (Al) atoms, chromium (Cr) atoms, nickel (Ni) atoms, titanium (Ti) atoms, zinc (Zn) atoms, and zirconium (Zr) atoms. Among these, Fe atoms, Al atoms, Cr atoms, Ni atoms, Pb atoms, Zn atoms, Ti atoms, and the like are preferable.

Particularly, in a case where the content of the metal-containing particles containing Fe atoms, Al atoms, Pb atoms, Zn atoms, and Ti atoms in the chemical liquid is strictly controlled, it is easy to obtain higher defect inhibition performance. In a case where the content of the metal-containing particles containing Pb atoms and Ti atoms in the chemical liquid is strictly controlled, it is easy to obtain much higher defect inhibition performance.

That is, the metal atoms are preferably at least one kind of metal atoms selected from the group consisting of Fe atoms, Al atoms, Cr atoms, Ni atoms, Pb atoms, Zn atoms, and Ti atoms, more preferably at least one kind of metal atoms selected from the group consisting of Fe atoms, Al atoms, Pb atoms, Zn atoms, and Ti atoms, and even more preferably at least one kind of metal atoms selected from the group consisting of Pb atoms and Ti atoms. It is particularly preferable that the metal-containing particles contain both the Pb atoms and Ti atoms.

The metal-containing particles may contain one kind of the above metal atoms or two or more kinds of the above metal atoms in combination.

The particle size of the metal-containing particles is not particularly limited. For example, in a chemical liquid for manufacturing semiconductor devices, the content of particles having a particle size of about 0.1 to 100 nm in the chemical liquid is controlled in many cases.

Through studies, the inventors of the present invention have found that particularly in a chemical liquid used for a photoresist process of extreme ultraviolet (EUV) exposure, in a case where the content of metal-containing particles having a particle size of 0.5 to 17 nm (hereinafter, also called “metal nanoparticles”) in the chemical liquid is controlled, it is easy to obtain a chemical liquid having excellent defect inhibition performance. In the photoresist process of EUV exposure, a fine resist interval, a fine resist width, and a fine resist pitch are required in many cases. In these cases, the number of finer particles that was not considered as a critical issue in the conventional process needs to be controlled.

The number-based particle size distribution of the metal-containing particles is not particularly limited. However, in view of obtaining a chemical liquid having further improved effects of the present invention, it is preferable that the metal-containing particles have a maximum particle size in at least one range selected from the group consisting of a range of particle size less than 5 nm and a range of particle size larger than 17 nm.

In other words, it is preferable that the metal-containing particles do not have a maximum particle size in a range of particle size of 5 to 17 nm. In a case where the metal-containing particles do not have a maximum particle size in a range of particle size of 5 to 17 nm, the defect inhibition performance, particularly, the bridge defect inhibition performance of the chemical liquid is further improved. The bridge defect means a defect in the form of a crosslink between wiring patterns.

In addition, in view of obtaining a chemical liquid having further improved effects of the present invention, it is particularly preferable that the metal-containing particles have a maximum particle size in a range of particle size equal to or greater than 0.5 nm and less than 5 nm in the number-based particle size distribution. In a case where the metal-containing particles have a maximum particle size in the above range, the chemical liquid has further improved bridge defect inhibition performance.

The content of the metal-containing particles with respect to the total mass of the present chemical liquid is preferably 0.00001 to 10 mass ppt, more preferably 0.0001 to 5 mass ppt, and particularly preferably 0.0001 to 0.5 mass ppt. In a case where the content of the metal-containing particles is within the above range, a chemical liquid having excellent defect inhibition performance (particularly, excellent defect inhibition performance exhibited even after the long-term preservation of the chemical liquid storage body) is obtained.

The type and content of the metal-containing particles in the chemical liquid can be measured by single nano particle inductively coupled plasma mass spectrometry (SP-ICP-MS).

The device used in SP-ICP-MS is the same as the device used in general inductively coupled plasma mass spectrometry (ICP-MS). The only difference between SP-ICP-MS and ICP-MS is how to analyze data. With SP-ICP-MS, data can be analyzed using commercial software.

With ICP-MS, the content of metal component as a measurement target is measured regardless of the way the metal component is present. Accordingly, the total mass of metal-containing particles and metal ions as a measurement target is quantified as the content of the metal component.

With SP-ICP-MS, the content of metal-containing particles can be measured. Accordingly, by subtracting the content of the metal-containing particles from the content of the metal component in a sample, the content of metal ions in the sample can be calculated.

Examples of the device for SP-ICP-MS include Agilent 8800 triple quadrupole inductively coupled plasma mass spectrometry (ICP-MS, for semiconductor analysis, option #200) manufactured by Agilent Technologies, Inc.. By using this device, the content of the metal-containing particles can be measured by the method described in Examples. In addition to the device described above, it is possible to use NexION350S manufactured by PerkinElmer Inc. and Agilent 8900 manufactured by Agilent Technologies, Inc.

(Metal Nanoparticles)

Among the metal-containing particles, particles having a particle size of 0.5 to 17 nm are called metal nanoparticles.

The number of metal nanoparticles contained in a unit volume of the chemical liquid is preferably 1.0×10⁻² to 1.0×10⁶ particles/cm³. In view of making the effects of the present invention further exhibited, the number of metal nanoparticles contained in the chemical liquid is preferably equal to or greater than 1.0×10⁻¹ particles/cm³, and more preferably equal to or greater than 5.0×10⁻¹ particles/cm³. The number of metal nanoparticles contained in the chemical liquid is preferably equal to or smaller than 1.0×10⁵ particles/cm³, more preferably equal to or smaller than 1.0×10⁴ particles/cm³, even more preferably equal to or smaller than 1.0×10³ particles/cm³.

Particularly, in a case where the number of metal nanoparticles contained in a unit volume of the chemical liquid is 5.0×10⁻¹ to 1.0×10³ particles/cm³, the defect inhibition performance of the chemical liquid is further improved.

The content of the metal nanoparticles in the chemical liquid can be measured by the method described in Examples. The number of metal nanoparticles (number) per unit volume of the chemical liquid is rounded off such that the number includes two significant digits.

The metal atoms contained in the metal nanoparticles are not particularly limited and the same as the atoms described above as metal atoms contained in the metal-containing particles. Particularly, in view of obtaining a chemical liquid having further improved effects of the present invention, the metal atoms are preferably at least one kind of metal atoms selected from the group consisting of Pb atoms and Ti atoms. It is more preferable that the metal nanoparticles contain both the Pb atoms and Ti atoms. Typically, examples of the aspect in which the metal nanoparticles contain both the Pb atoms and Ti atoms include an aspect in which the chemical liquid contains both the Pb atom-containing metal nanoparticles and Ti atom-containing metal nanoparticles.

The ratio of the number of Pb atom-containing metal nanoparticles (hereinafter, also called “Pb nanoparticles”) contained in the chemical liquid to the number of Ti atom-containing metal nanoparticles (hereinafter, also called “Ti nanoparticles”) contained in the chemical liquid (Pb/Ti) is not particularly limited. Generally, Pb/Ti is preferably 1.0×10⁻⁴ to 3.0, more preferably 1.0×10⁻³ to 2.0, and particularly preferably 1.0×10⁻² to 1.5. In a case where Pb/Ti is 1.0×10⁻³ to 2.0, the chemical liquid has further improved effects of the present invention, particularly, further improved bridge defect inhibition performance.

The inventors of the present invention know that the Pb nanoparticles and the Ti nanoparticles are easily aggregated, for example, in a case where a wafer is coated with the chemical liquid or the like and easily cause defects (particularly cause bridge defects) during the development of a resist film.

In a case where Pb/Ti is 1.0×10⁻³ to 2.0, surprisingly, the occurrence of defects is more easily inhibited. In the present specification, Pb/Ti and A/(B+C) which will be described later are rounded off such that the numbers include two significant digits.

As long as the metal nanoparticles contain metal atoms, the form of the metal nanoparticles is not particularly limited. For example, the metal nanoparticles may be in the form of simple metal atoms, compounds containing metal atoms (hereinafter, also called “metal compound”), a complex of these, and the like. Furthermore, the metal nanoparticles may contain a plurality of metal atoms. In a case where the metal nanoparticles contain a plurality of metals, among the plurality of metals, metal atoms at the highest content (atm %) are regarded as a main component. Therefore, in a case where metal nanoparticles containing a plurality of metals are called Pb nanoparticles, “Pb nanoparticles” mean that Pb atoms are the main component among the plurality of metals.

The complex is not particularly limited, and examples thereof include a so-called core-shell type particle having a simple metal atom and a metal compound covering at least a portion of the simple metal atom, a solid solution particle including a metal atom and another atom, a eutectic particle including a metal atom and another atom, an aggregate particle of a simple metal atom and a metal compound, an aggregate particle of different kinds of metal compounds, a metal compound in which the composition thereof continuously or intermittently changes toward the center of the particle from the surface of the particle, and the like.

The atom other than the metal atom contained in the metal compound is not particularly limited, and examples thereof include a carbon atom, an oxygen atom, a nitrogen atom, a hydrogen atom, a sulfur atom, a phosphorus atom, and the like. Among these, an oxygen atom is preferable. The form of the metal compound containing an oxygen atom is not particularly limited. However, the metal compound is more preferably an oxide of a metal atom.

In view of obtaining a chemical liquid having further improved effects of the present invention, it is preferable that the metal nanoparticles include at least one kind of particle selected from the group consisting of a particle formed of a simple metal atom (particle A), a particle formed of an oxide of a metal atom (particle B), and a particle formed of a simple metal atom and an oxide of a metal atom (particle C).

There is no particular limitation on the relationship among the number of particles A, the number of particles B, and the number of particles C contained as metal nanoparticles in a unit volume of the chemical liquid. However, in view of obtaining a chemical liquid having further improved effects of the present invention, the ratio of the number of particles A contained in the chemical liquid to the total number of particles B and particles C contained in the chemical liquid (hereinafter, also described as “A/(B+C)”) is preferably equal to or lower than 1.5, more preferably lower than 1.0, even more preferably equal to or lower than 2.0×10⁻¹, and particularly preferably equal to or lower than 1.0×10⁻¹. A/(B+C) is preferably equal to or higher than 1.0×10⁻³, and more preferably equal to or higher than 1.0×10⁻².

In a case where A/(B+C) is lower than 1.0, the chemical liquid has further improved bridge defect inhibition performance, further improved pattern width uniformizing performance, and stain-like defect inhibition performance. The stain-like defect means a defect from which no metal atom is detected.

Furthermore, in a case where A/(B+C) is equal to or lower than 0.1, the chemical liquid has further improved defect inhibition performance.

<Metal Ions>

The present chemical liquid may contain metal ions.

Examples of the metal ions include ions of metal atoms such as Pb (lead), Na (sodium), K (potassium), Ca (calcium), Fe (iron), Cu (copper), Mg (magnesium), Mn (manganese), Li (lithium), Al (aluminum), Cr (chromium), Ni (nickel), Ti (titanium), Zn (zinc), and Zr (zirconium).

The content of the metal ions with respect to the total mass of the present chemical liquid is preferably 0.01 to 100 mass ppt, more preferably 0.01 to 10 mass ppt, and particularly preferably 0.01 to 5 mass ppt. In a case where the content of the metal ions is within the above range, a chemical liquid having excellent defect inhibition performance (particularly, excellent defect inhibition performance exhibited even after the long-term preservation of the chemical liquid storage body) is obtained.

As described above, the content of the metal ions in the chemical liquid is determined by subtracting the content of the metal-containing particles measured by SP-ICP-MS from the content of the metal component in the chemical liquid measured by ICP-MS.

In view of making the effects of the present invention further exhibited, the mass ratio of the content of the metal-containing particles to the content of the metal ions (metal-containing particles/metal ions) is preferably 0.00001 to 1, more preferably 0.0001 to 0.2, and particularly preferably 0.001 to 0.05.

[Other Components]

The chemical liquid may contain components other than the above. Examples of those other components include an organic compound other than an organic solvent (particularly, an organic compound having a boiling point equal to or higher than 300° C.), water, a resin, and the like.

<Organic Compound Other than Organic Solvent>

The chemical liquid may contain an organic compound other than an organic solvent (hereinafter, also called “specific organic compound”). In the present specification, the specific organic compound means an organic compound which is a compound different from the organic solvent contained in the chemical liquid and contained in the chemical liquid at a content equal to or smaller than 10,000 mass ppm with respect to the total mass of the present chemical liquid. That is, in the present specification, an organic compound contained in the present chemical liquid at a content equal to or smaller than 10,000 mass ppm with respect to the total mass of the present chemical liquid corresponds to a specific organic compound and does not correspond to an organic solvent.

In a case where the chemical liquid contains a plurality of kinds of organic compounds, and each of the organic compounds is contained in the chemical liquid at a content equal to or smaller than 10,000 mass ppm as described above, each of the specific organic compounds corresponds to a specific organic compound.

The specific organic compound may be added to the chemical liquid or may be unintentionally mixed with the chemical liquid the process of manufacturing the chemical liquid. Examples of the case where the specific organic compound is unintentionally mixed with the chemical liquid in the process of manufacturing the chemical liquid include, but are not limited to, a case where the specific organic compound is contained in raw materials (for example, an organic solvent) used for manufacturing the chemical liquid, a case where the specific organic compound is mixed with the chemical liquid in the process of manufacturing the chemical liquid (for example, contamination), and the like.

The content of the specific organic compound in the present chemical liquid can be measured using gas chromatography mass spectrometry (GCMS).

The number of carbon atoms in the specific organic compound is not particularly limited. However, in view of obtaining a chemical liquid having further improved effects of the present invention, the number of carbon atoms is preferably equal to or greater than 8, and more preferably equal to or greater than 12. The upper limit of the number of carbon atoms is not particularly limited, but is preferably equal to or smaller than 30 in general.

Examples of the specific organic compound include byproducts generated at the time of synthesizing the organic solvent and/or unreacted raw materials (hereinafter, also called “byproduct and the like”), and the like.

Examples of the byproduct and the like include compounds represented by Formulae I to V, and the like.

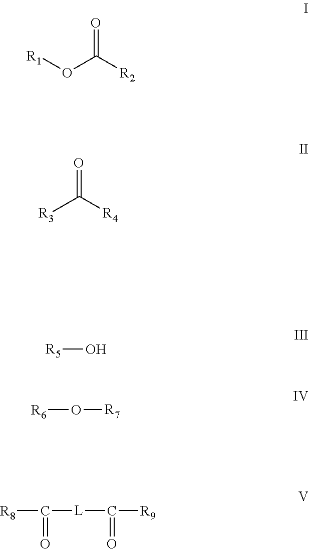

In Formula I, R₁ and R₂ each independently represent an alkyl group or a cycloalkyl group. Alternatively, R₁ and R₂ may be bonded to each other to form a ring.

As the alkyl group or the cycloalkyl group represented by R₁ and R₂, an alkyl group having 1 to 12 carbon atoms or a cycloalkyl group having 6 to 12 carbon atoms is preferable, and an alkyl group having 1 to 8 carbon atoms or a cycloalkyl group having 6 to 8 carbon atoms is more preferable.

The ring formed of R₁ and R₂ bonded to each other is a lactone ring, preferably a 4- to 9-membered lactone ring, and more preferably a 4- to 6-membered lactone ring.

It is preferable that R₁ and R₂ satisfy a relationship in which the number of carbon atoms in the compound represented by Formula I is equal to or greater than 8.

In Formula II, R₃ and R₄ each independently represent a hydrogen atom, an alkyl group, an alkenyl group, a cycloalkyl group, or a cycloalkenyl group. Alternatively, R₃ and R₄ may be bonded to each other to form a ring. Here, R₃ and R₄ do not simultaneously represent a hydrogen atom.

As the alkyl group represented by R₃ and R₄, for example, an alkyl group having 1 to 12 carbon atoms is preferable, and an alkyl group having 1 to 8 carbon atoms is more preferable.

As the alkenyl group represented by R₃ and R₄, for example, an alkenyl group having 2 to 12 carbon atoms is preferable, and an alkenyl group having 2 to 8 carbon atoms is more preferable.

As the cycloalkyl group represented by R₃ and R₄, for example, a cycloalkyl group having 6 to 12 carbon atoms is preferable, and a cycloalkyl group having 6 to 8 carbon atoms is more preferable.

As the cycloalkenyl group represented by R₃ and R₄, for example, a cycloalkenyl group having 3 to 12 carbon atoms is preferable, and a cycloalkenyl group having 6 to 8 carbon atoms is more preferable.

The ring formed of R₃ and R₄ bonded to each other is a cyclic ketone structure, which may be a saturated cyclic ketone or an unsaturated cyclic ketone. The cyclic ketone is preferably a 6- to 10-membered ring, and more preferably a 6- to 8-membered ring.

It is preferable that R₃ and R₄ satisfy a relationship in which the number of carbon atoms in the compound represented by Formula II is equal to or greater than 8.

In Formula III, R₅ represents an alkyl group or a cycloalkyl group.

As the alkyl group represented by R₅, an alkyl group having 6 or more carbon atoms is preferable, an alkyl group having 6 to 12 carbon atoms is more preferable, and an alkyl group having 6 to 10 carbon atoms is even more preferable.

The alkyl group may have an ether bond in the chain thereof or may have a substituent such as a hydroxy group.

As the cycloalkyl group represented by R₅, a cycloalkyl group having 6 or more carbon atoms is preferable, a cycloalkyl group having 6 to 12 carbon atoms is more preferable, and a cycloalkyl group having 6 to 10 carbon atoms is even more preferable.

In Formula IV, R₆ and R₇ each independently represent an alkyl group or a cycloalkyl group. Alternatively, R₆ and R₇ may be bonded to each other to form a ring.

As the alkyl group represented by R₆ and R₇, an alkyl group having 1 to 12 carbon atoms is preferable, and an alkyl group having 1 to 8 carbon atoms is more preferable.

As the cycloalkyl group represented by R₆ and R₇, for example, a cycloalkyl group having 6 to 12 carbon atoms is preferable, and a cycloalkyl group having 6 to 8 carbon atoms is more preferable.

The ring formed of R₆ and R₇ bonded to each other is a cyclic ether structure. The cyclic ether structure is preferably a 4- to 8-membered ring, and more preferably a 5- to 7-membered ring.

It is preferable that R₆ and R₇ satisfy a relationship in which the number of carbon atoms in the compound represented by Formula IV becomes equal to or greater than 8.

In Formula V, R₈ and R₉ each independently represent an alkyl group or a cycloalkyl group. Alternatively, R₈ and R₉ may be bonded to each other to form a ring. L represents a single bond or an alkylene group.

As the alkyl group represented by R₈ and R₉, an alkyl group having 6 to 12 carbon atoms is preferable, and an alkyl group having 6 to 10 carbon atoms is more preferable.

As the cycloalkyl group represented by R₈ and R₉, for example, a cycloalkyl group having 6 to 12 carbon atoms is preferable, and a cycloalkyl group having 6 to 10 carbon atoms is more preferable.

The ring formed of R₈ and R₉ bonded to each other is a cyclic diketone structure. The cyclic diketone structure is preferably a 6- to 12-membered ring, and more preferably a 6- to 10-membered ring.

As the alkylene group represented by L, for example, an alkylene group having 1 to 12 carbon atoms is preferable, and an alkylene group having 1 to 10 carbon atoms is more preferable.

R₈, R₉, and L satisfy a relationship in which the number of carbon atoms in the compound represented by Formula V becomes equal to or greater than 8.

The specific organic compound is not particularly limited. However, in a case where the organic solvent is an amide compound, an imide compound, or a sulfoxide compound, in an aspect, examples of the specific organic compound include an amide compound, an imide compound, and a sulfoxide compound having 6 or more carbon atoms. Examples of the specific organic compound also include the following compounds.

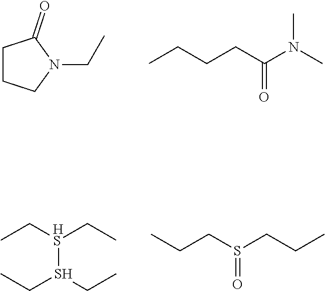

Examples of the specific organic compound also include antioxidants such as dibutylhydroxytoluene (BHT), distearylthiodipropionate (DSTP), 4,4¢-butylidenebis-(6-t-butyl-3-methylphenol), 2,2′-methylenebis-(4-ethyl-6-t-butylphenol), and the antioxidants described in JP2015-200775A; unreacted raw materials; structural isomers and byproducts produced at the time of manufacturing the organic solvent; substances eluted from members constituting an organic solvent manufacturing device and the like (for example, a plasticizer eluted from a rubber member such as an O-ring); and the like.

Examples of the specific organic compound include dioctyl phthalate (DOP), bis(2-ethylhexyl) phthalate (DEHP), bis(2-propylheptyl) phthalate (DPHP), dibutyl phthalate (DBP), benzyl butyl phthalate (BBzP), diisodecyl phthalate (DIDP), diisooctyl phthalate (DIOP), diethyl phthalate (DEP), diisobutyl phthalate (DIBP), dihexyl phthalate, diisononyl phthalate (DINP), tris(2-ethylhexyl) trimellitate (TEHTM), tris(n-octyl-n-decyl) trimellitate (ATM), bis(2-ethylhexyl) adipate (DEHA), monomethyl adipate (MMAD), dioctyl adipate (DOA), dibutyl sebacate (DBS), dibutyl maleate (DBM), diisobutyl maleate (DIBM), an azelaic acid ester, a benzoic acid ester, terephthalate (example: dioctyl terephthalate (DEHT)), a 1,2-cyclohexanedicarboxylic acid diisononyl ester (DINCH), epoxidized vegetable oil, sulfonamide (example: N-(2-hydroxypropyl)benzene sulfonamide (HP BSA), and N-(n-butyl)benzene sulfonamide (BBSA-NBBS)), an organic phosphoric acid ester (example: tricresyl phosphate (TCP), and tributyl phosphate (TBP)), acetylated monoglyceride, triethyl citrate (TEC), acetyl triethyl citrate (ATEC), tributyl citrate (TBC), acetyl tributyl citrate (ATBC), trioctyl citrate (TOC), acetyl trioctyl citrate (ATOC), trihexyl citrate (THC), acetyl trihexyl citrate (ATHC), epoxidized soybean oil, ethylene propylene rubber, polybutene, an addition polymer of 5-ethylidene-2-norbornene, and polymer plasticizers exemplified below.

Presumably, these specific organic compounds may be mixed into the substance to be purified or the chemical liquid from a filter, piping, a tank, an O-ring, a container, and the like that come into contact with the substance to be purified or the chemical liquid in a purification step. Particularly, compounds other than alkyl olefin are involved in the occurrence of a bridge defect.

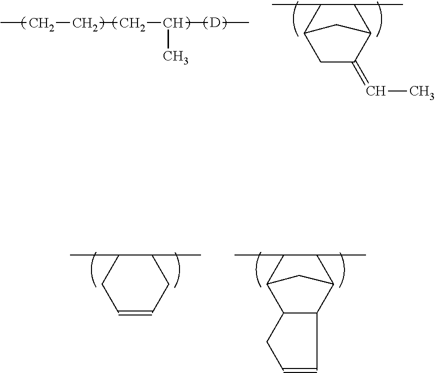

(Organic Compound Having Specific Polar Structure)

The present chemical liquid may contain the following organic compound having a specific polar structure among the specific organic compounds. It is preferable that the organic compound having a specific polar structure includes at least one kind of organic compound selected from the group consisting of a compound having an amide structure, a compound having a sulfonamide structure, a compound having a phosphonamide structure, a compound having an imide structure, a compound having a urea structure, a compound having a urethane structure, and an organic acid ester.

Examples of the compound having an amide structure include oleic acid amide, stearic acid amide, erucic acid amide, methylenebis stearic acid amide, methylenebis octadecanoic acid amide (707° C.), ethylenebis octadecanoic acid amide, and the like.

Examples of the compound having a sulfonamide structure include N-ethyl-o-toluenesulfonamide, N-ethyl-p-toluenesulfonamide, N-(2-hydroxypropyl)benzenesulfonamide, N-butylbenzenesulfonamide, and the like.

Examples of the compound having an imide structure include phthalimide (366° C.), hexahydrophthalimide, N-2-ethylhexylphthalimide, N-butylphthalimide, N-isopropylphthalimide, and the like.

Examples of the compound having a urea structure include an aliphatic diurea, an alicyclic diurea, and an aromatic diurea.

In view of making the effects of the present invention further exhibited, it is preferable that the organic acid ester includes at least one kind of compound selected from the group consisting of phthalic acid esters such as dioctyl phthalate (boiling point 385° C.), diisononyl phthalate (boiling point 403° C.), and dibutyl phthalate (boiling point 340° C.), and bis(2-ethylhexyl)terephthalate (boiling point 416° C./101.3 kPa).

The content of the organic compound having a specific polar structure is preferably equal to or smaller than 5 mass ppm with respect to the total mass of the present chemical liquid. In view of further improving the defect inhibition performance, the content of the organic compound having a specific polar structure is more preferably equal to or smaller than 1 mass ppm, even more preferably equal to or smaller than 0.1 mass ppm, and particularly preferably equal to or smaller than 0.01 mass ppm.

In view of making the effects of the present invention further exhibited, the lower limit of the content of the organic compound having a specific polar structure with respect to the total mass of the present chemical liquid is preferably equal to or greater than 0.0001 mass ppm, and more preferably equal to or greater than 0.001 mass ppm.

(Organic Compound Having Boiling Point Equal to or Higher than 300° C.)

The present chemical liquid may contain an organic compound having a boiling point equal to or higher than 300° C. (hereinafter, also called “high-boiling-point organic compound”) among the aforementioned organic compounds having a specific polar structure. In a case where the present chemical liquid contains a high-boiling-point organic compound, due to the high boiling point, the present chemical liquid is hardly volatilized during the photolithography process. Therefore, in order to obtain a chemical liquid having excellent defect inhibition performance, it is preferable to strictly control the content of the high-boiling-point organic compound in the chemical liquid, the form of the high-boiling-point compound present in the chemical liquid, and the like.

The content of the high-boiling-point organic compound with respect to the total mass of the present chemical liquid is preferably equal to or smaller than 5 mass ppm. In view of further improving the defect inhibition performance, the content of the high-boiling-point organic compound is more preferably equal to or smaller than 1 mass ppm, even more preferably equal to or smaller than 0.1 mass ppm, and particularly preferably equal to or smaller than 0.01 mass ppm.

In view of making the effects of the present invention further exhibited, the lower limit of the content of the high-boiling-point organic compound with respect to the total mass of the present chemical liquid is preferably equal to or greater than 0.0001 mass ppm, and more preferably equal to or greater than 0.001 mass ppm.

The inventors of the present invention have found that in a case where the chemical liquid contains the organic compound having a polar structure or the high-boiling-point organic compound, the organic compound or the high-boiling-point organic compound is present in the chemical liquid in various forms. For example, in the chemical liquid, the organic compound having a polar structure or the high-boiling-point organic compound is present in the form of particles generated by the aggregation of particles formed of metal atoms or metal compounds and particles of the organic compound having a polar structure or the high-boiling-point organic compound; particles including particles formed of metal atoms or metal compounds and the organic compound having a polar structure or the high-boiling-point organic compound that is disposed to cover at least a portion of the above particles; particles formed by coordinate bonds between a metal atom and the organic compound having a polar structure or the high-boiling-point organic compound; and the like.

Particularly, for example, in a case where the chemical liquid contains metal nanoparticles (particle U) containing the organic compound having a polar structure or the high-boiling-point organic compound, the defect inhibition performance of the chemical liquid is greatly affected. The inventors of the present invention have found that in a case where the number of particles U contained in a unit volume of the chemical liquid is controlled, the defect inhibition performance of the chemical liquid is significantly improved.

The reason is unclear but is assumed to be as below. The surface free energy of the particle U tends to be relatively lower than the surface free energy of metal nanoparticles (particle V) that do not contain the organic compound having a polar structure or the high-boiling-point organic compound. The particle U hardly remains on a substrate treated with the chemical liquid, and even though the particle U remains on the substrate, the particle U is easily removed in a case where it is brought again into contact with the chemical liquid. For example, in a case where the chemical liquid is used as a developer and a rinsing solution, the particle U is less likely to remain on the substrate during development and more easily removed by rinsing and the like. That is, as a result, both the high-boiling-point organic compound and particles containing metal atoms are more easily removed.

In addition, presumably, because a resist film is generally water-repellent in many cases, the particle U having lower surface energy may be less likely to remain on a substrate.

In view of obtaining a chemical liquid having further improved effects of the present invention, the ratio of the number of particles U contained in a unit volume of the chemical liquid to the number of particles V contained in a unit volume of the chemical liquid is preferably equal to or higher than 10 and equal to or lower than 1.0×10². The ratio is more preferably equal to or lower than 50, even more preferably equal to or lower than 35, and particularly preferably equal to or lower than 25.

<Water>

The present chemical liquid may contain water. The water is not particularly limited, and examples thereof include distilled water, deionized water, pure water, and the like.

Water may be added to the chemical liquid or may be unintentionally mixed into the chemical liquid in the process of manufacturing the chemical liquid. Examples of the case where water is unintentionally mixed with the chemical liquid in the process of manufacturing the chemical liquid include a case where water is contained in a raw material (for example, an organic solvent) used for manufacturing the chemical liquid, a case where water is mixed with the chemical liquid in the process of manufacturing the chemical liquid (for example, contamination), and the like. However, the present invention is not limited to these.

The content of water with respect to the total mass of the present chemical liquid is preferably equal to or smaller than 30 mass ppm, more preferably equal to or smaller than 1 mass ppm, even more preferably 0 to 0.6 mass ppm, and particularly preferably 0 to 0.3 mass ppm. In a case where the content of water is equal to or smaller than 1 mass ppm, the formation of a complex of a metal component and an acid component is inhibited. Accordingly, a chemical liquid having excellent defect inhibition performance (particularly, excellent defect inhibition performance exhibited even after the long-term preservation of the chemical liquid storage body) is obtained.

The content of water in the present chemical liquid means the content of water measured using a device which adopts the Karl Fischer titration method as the principle of measurement.

<Resin>

The present chemical liquid may contain a resin. As the resin, a resin P having a group which is decomposed by the action of an acid and generates a polar group is more preferable. As such a resin, a resin having a repeating unit represented by Formula (AI) that will be described later is more preferable, which is a resin whose solubility in a developer containing an organic solvent as a main component is reduced by the action of an acid. The resin having a repeating unit represented by Formula (AI), which will be described later, has a group that is decomposed by the action of an acid and generates an alkali-soluble group (hereinafter, also called “acid-decomposable group”).

Examples of the polar group include an alkali-soluble group. Examples of the alkali-soluble group include a carboxyl group, a fluorinated alcohol group (preferably a hexafluoroisopropanol group), a phenolic hydroxyl group, and a sulfo group.

In the acid-decomposable group, the polar group is protected with a group dissociated by an acid (acid-dissociable group). Examples of the acid-dissociable group include —C(R₃₆)(R₃₇)(R₃₈), —C(R₃₆)(R₃₇)(OR₃₉), —C(R₀₁)(R₀₂)(OR₃₉), and the like.

In the formulae, R₃₆ to R₃₉ each independently represent an alkyl group, a cycloalkyl group, an aryl group, an aralkyl group, or an alkenyl group. R₃₆ and R₃₇ may be bonded to each other to form a ring.

R₀₁ and R₀₂ each independently represent a hydrogen atom, an alkyl group, a cycloalkyl group, an aryl group, an aralkyl group, or an alkenyl group.

Hereinafter, the resin P whose solubility in a developer containing an organic solvent as a main component is reduced by the action of an acid will be specifically described.

(Formula (AI): Repeating Unit Having Acid-Decomposable Group)

It is preferable that the resin P contains a repeating unit represented by Formula (AI).

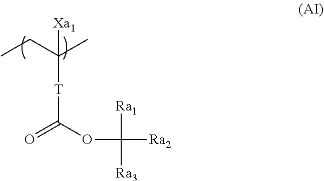

In Formula (AI),

Xa₁ represents a hydrogen atom or an alkyl group which may have a substituent.

T represents a single bond or a divalent linking group.

Ra₁ to Ra₃ each independently represent an alkyl group (linear or branched) or a cycloalkyl group (monocyclic or polycyclic).

Two out of Ra₁ to Ra₃ may be bonded to each other to form a cycloalkyl group (monocyclic or polycyclic).

Examples of the alkyl group which is represented by Xa₁ and may have a substituent include a methyl group and a group represented by —CH₂—R₁₁. R₁₁ represents a halogen atom (such as a fluorine atom), a hydroxyl group, or a monovalent organic group.

Xa₁ is preferably a hydrogen atom, a methyl group, a trifluoromethyl group, or a hydroxymethyl group.

Examples of the divalent linking group represented by T include an alkylene group, a —COO-Rt- group, a —O-Rt- group, and the like. In the formulae, Rt represents an alkylene group or a cycloalkylene group.

T is preferably a single bond or a —COO-Rt- group. Rt is preferably an alkylene group having 1 to 5 carbon atoms, and more preferably a —CH₂— group, a —(CH₂)₂— group, or a —(CH₂)₃— group.

The alkyl group represented by Ra₁ to Ra₃ preferably has 1 to 4 carbon atoms.

The cycloalkyl group represented by Ra₁ to Ra₃ is preferably a monocyclic cycloalkyl group such as a cyclopentyl group or a cyclohexyl group or a polycyclic cycloalkyl group such as a norbornyl group, a tetracyclodecanyl group, a tetracyclododecanyl group, or an adamantyl group.

The cycloalkyl group formed by the bonding of two groups out of Ra₁ to Ra₃ is preferably a monocyclic cycloalkyl group such as a cyclopentyl group or a cyclohexyl group or a polycyclic cycloalkyl group such as a norbornyl group, a tetracyclodecanyl group, a tetracyclododecanyl group, or an adamantyl group. The cycloalkyl group is more preferably a monocyclic cycloalkyl group having 5 or 6 carbon atoms.

In the cycloalkyl group formed by the bonding of two groups out of Ra₁ to Ra₃, for example, one methylene group constituting the ring may be substituted with a heteroatom such as an oxygen atom or a group having a heteroatom such as a carbonyl group.

As the repeating unit represented by Formula (AI), for example, an aspect is preferable in which Ra₁ is a methyl group or an ethyl group, and Ra₂ and Ra₃ are bonded to each other to form the aforementioned cycloalkyl group.

Each of the above groups may have a substituent. Examples of the substituent include an alkyl group (having 1 to 4 carbon atoms), a halogen atom, a hydroxyl group, an alkoxy group (having 1 to 4 carbon atoms), a carboxyl group, an alkoxycarbonyl group (having 2 to 6 carbon atoms), and the like. The number of carbon atoms in the substituent is preferably equal to or smaller than 8.

The content of the repeating unit represented by Formula (AI) with respect to all the repeating units in the resin P is preferably 20 to 90 mol %, more preferably 25 to 85 mol %, and even more preferably 30 to 80 mol %.

(Repeating Unit Having Lactone Structure)

It is preferable that the resin P contains a repeating unit Q having a lactone structure.

The repeating unit Q having a lactone structure preferably has a lactone structure on a side chain. The repeating unit Q is more preferably a repeating unit derived from a (meth)acrylic acid derivative monomer.

One kind of repeating unit Q having a lactone structure may be used singly, or two or more kinds of repeating units Q may be used in combination. It is preferable to use one kind of repeating unit Q.

The content of the repeating unit Q having a lactone structure with respect to all the repeating units in the resin P is preferably 3 to 80 mol %, and more preferably 3 to 60 mol %.

The lactone structure is preferably a 5- to 7-membered lactone structure, and more preferably a structure in which another ring structure is fused with a 5- to 7-membered lactone structure by forming a bicyclo structure or a spiro structure.

It is preferable that the lactone structure has a repeating unit having a lactone structure represented by any of Formulae (LC1-1) to (LC1-17). As the lactone structure, a lactone structure represented by Formula (LC1-1), Formula (LC1-4), Formula (LC1-5), or Formula (LC1-8) is preferable, and a lactone structure represented by Formula (LC1-4) is more preferable.

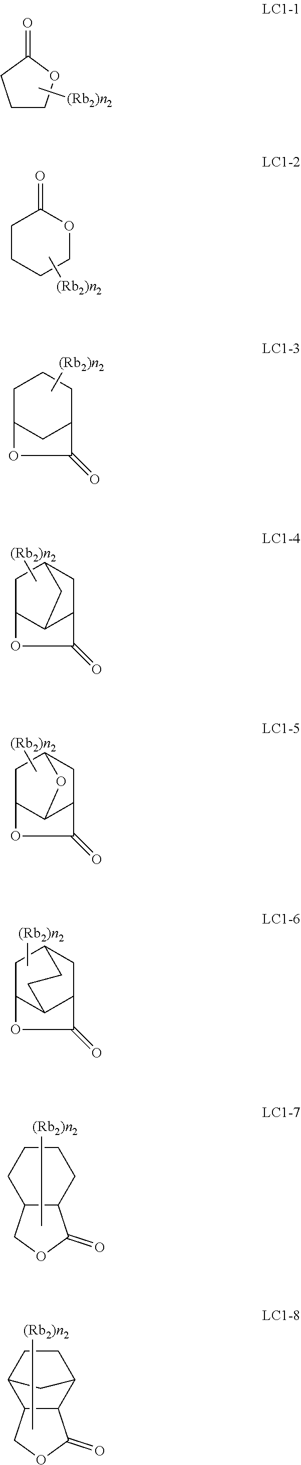

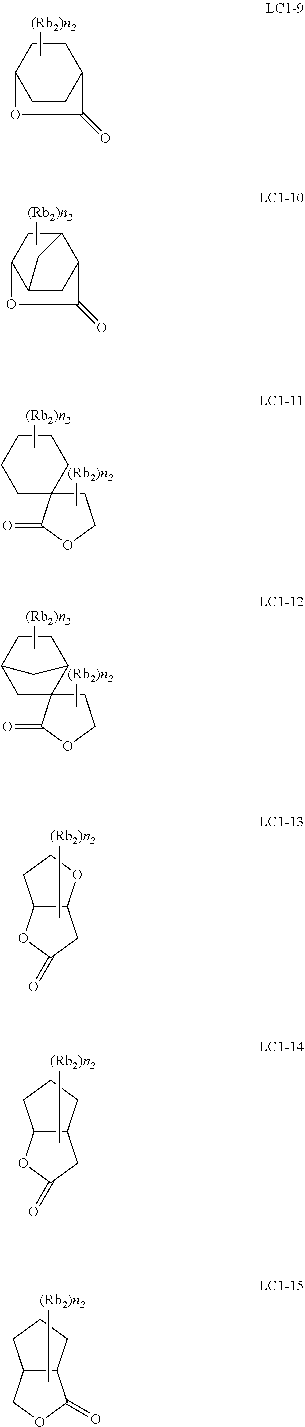

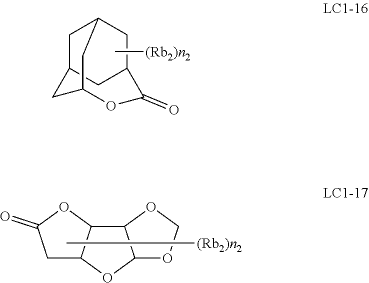

The lactone structure portion may have a substituent (Rb₂). As the substituent (Rb₂), for example, an alkyl group having 1 to 8 carbon atoms, a cycloalkyl group having 4 to 7 carbon atoms, an alkoxy group having 1 to 8 carbon atoms, an alkoxycarbonyl group having 2 to 8 carbon atoms, a carboxyl group, a halogen atom, a hydroxyl group, a cyano group, an acid-decomposable group, and the like are preferable. n₂ represents an integer of 0 to 4. In a case where n₂ is equal to or greater than 2, a plurality of substituents (Rb₂) may be the same as or different from each other, and a plurality of substituents (Rb₂) may be bonded to each other to form a ring.

(Repeating Unit Having Phenolic Hydroxyl Group)

The resin P may contain a repeating unit having a phenolic hydroxyl group.

Examples of the repeating unit having a phenolic hydroxyl group include a repeating unit represented by General Formula (I).

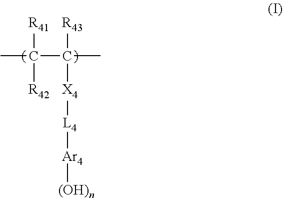

In the formula,

R₄₁, R₄₂, and R₄₃ each independently represent a hydrogen atom, an alkyl group, a halogen atom, a cyano group, or an alkoxycarbonyl group. Here, R₄₂ and Ar₄ may be bonded to each other to form a ring. In this case, R₄₂ represents a single bond or an alkylene group.

X₄ represents a single bond, —COO—, or —CONR₆₄—, and R₆₄ represents a hydrogen atom or an alkyl group.

L₄ represents a single bond or an alkylene group.

Ar₄ represents an (n+1)-valent aromatic ring group. In a case where Ar₄ is bonded to R₄₂ to form a ring, Ar₄ represents an (n+2)-valent aromatic ring group.

n represents an integer of 1 to 5.

The alkyl group represented by R₄₁, R₄₂, and R₄₃ in General Formula (I) is preferably an alkyl group having 20 or less carbon atoms such as a methyl group, an ethyl group, a propyl group, an isopropyl group, a n-butyl group, a sec-butyl group, a hexyl group, a 2-ethylhexyl group, an octyl group, or a dodecyl group which may have a substituent, more preferably an alkyl group having 8 or less carbon atoms, and even more preferably an alkyl group having 3 or less carbon atoms.

The cycloalkyl group represented by R₄₁, R₄₂, and R₄₃ in General Formula (I) may be monocyclic or polycyclic. The cycloalkyl group is preferably a monocyclic cycloalkyl group having 3 to 8 carbon atoms such as a cyclopropyl group, a cyclopentyl group, or a cyclohexyl group which may have a substituent.

Examples of the halogen atom represented by R₄₁, R₄₂, and R₄₃ in General Formula (I) include a fluorine atom, a chlorine atom, a bromine atom, and an iodine atom. Among these, a fluorine atom is preferable.

As the alkyl group contained in the alkoxycarbonyl group represented by R₄₁, R₄₂, and R₄₃ in General Formula (I), the same alkyl group as the alkyl group represented by R₄₁, R₄₂, and R₄₃ described above is preferable.

Examples of the substituent in each of the above groups include an alkyl group, a cycloalkyl group, an aryl group, an amino group, an amide group, a ureide group, a urethane group, a hydroxy group, a carboxyl group, a halogen atom, an alkoxy group, a thioether group, an acyl group, an acyloxy group, an alkoxycarbonyl group, a cyano group, a nitro group, and the like. The number of carbon atoms in the substituent is preferably equal to or smaller than 8.

Ar₄ represents an (n+1)-valent aromatic ring group. Examples of a divalent aromatic ring group obtained in a case where n is 1 include an arylene group having 6 to 18 carbon atoms such as a phenylene group, a tolylene group, a naphthylene group, or an anthracenylene group which may have a substituent and an aromatic ring group containing a hetero ring such as thiophene, furan, pyrrole, benzothiophene, benzofuran, benzopyrrole, triazine, imidazole, benzimidazole, triazole, thiadiazole, or thiazole.

Specific examples of the (n+1)-valent aromatic ring group obtained in a case where n is an integer equal to or greater than 2 include groups obtained by removing (n−1) pieces of any hydrogen atoms from the specific examples of the divalent aromatic ring group described above.

The (n+1)-valent aromatic ring group may further have a substituent.

Examples of the substituent that the alkyl group, the cycloalkyl group, the alkoxycarbonyl group, the alkylene group, and the (n+1)-valent aromatic ring group described above can have include the alkyl group exemplified above as R₄₁, R₄₂, and R₄₃ in General Formula (I); an alkoxy group such as a methoxy group, an ethoxy group, a hydroxyethoxy group, a propoxy group, a hydroxypropoxy group, or a butoxy group; and an aryl group such as a phenyl group.

Examples of the alkyl group represented by R₆₄ in —CONR₆₄— (R₆₄ represents a hydrogen atom or an alkyl group) represented by X₄ include an alkyl group having 20 or less carbon atoms such as a methyl group, an ethyl group, a propyl group, an isopropyl group, a n-butyl group, a sec-butyl group, a hexyl group, a 2-ethylhexyl group, an octyl group, or a dodecyl group which may have a substituent. Among these, an alkyl group having 8 or less carbon atoms is more preferable.

X₄ is preferably a single bond, —COO—, or —CONH—, and more preferably a single bond or —COO—.

The alkylene group represented by L₄ is preferably an alkylene group having 1 to 8 carbon atoms such as a methylene group, an ethylene group, a propylene group, a butylene group, a hexylene group, or an octylene group which may have a substituent.

Ar₄ is preferably an aromatic ring group having 6 to 18 carbon atoms that may have a substituent, and more preferably a benzene ring group, a naphthalene ring group, or a biphenylene ring group.

It is preferable that the repeating unit represented by General Formula (I) comprises a hydroxystyrene structure. That is, Ar₄ is preferably a benzene ring group.

The content of the repeating unit having a phenolic hydroxyl group with respect to all the repeating units in the resin P is preferably 0 to 50 mol %, more preferably 0 to 45 mol %, and even more preferably 0 to 40 mol %.

(Repeating Unit Containing Organic Group Having Polar Group)

The resin P may further contain a repeating unit containing an organic group having a polar group, particularly, a repeating unit having an alicyclic hydrocarbon structure substituted with a polar group. In a case where the resin P further contains such a repeating unit, the substrate adhesiveness and the affinity with a developer are improved.

As the alicyclic hydrocarbon structure substituted with a polar group, an adamantyl group, a diamantyl group, or a norbornane group is preferable. As the polar group, a hydroxyl group or a cyano group is preferable.

In a case where the resin P contains the repeating unit containing an organic group having a polar group, the content of the repeating unit with respect to all the repeating units in the resin P is preferably 1 to 50 mol %, more preferably 1 to 30 mol %, even more preferably 5 to 25 mol %, and particularly preferably 5 to 20 mol %.

(Repeating Unit Represented by General Formula (VI))

The resin P may contain a repeating unit represented by General Formula (VI).

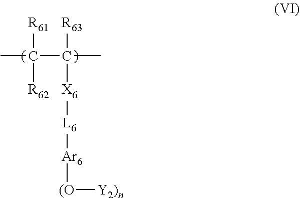

In General Formula (VI),

R₆₁, R₆₂, and R₆₃ each independently represent a hydrogen atom, an alkyl group, a cycloalkyl group, a halogen atom, a cyano group, or an alkoxycarbonyl group. Here, R₆₂ may be bonded to Ar₆ to form a ring, and in this case, R₆₂ represents a single bond or an alkylene group.

X₆ represents a single bond, —COO—, or —CONR₆₄—. R₆₄ represents a hydrogen atom or an alkyl group.

L₆ represents a single bond or an alkylene group.

Ar₆ represents an (n+1)-valent aromatic ring group. In a case where Ar₆ is bonded to R₆₂ to form a ring, Ar₆ represents an (n+2)-valent aromatic ring group.

In a case where n≥2, Y₂ each independently represents a hydrogen atom or a group which is dissociated by the action of an acid. Here, at least one of Y₂'s represents a group which is dissociated by the action of an acid.

n represents an integer of 1 to 4.

As the group Y₂ which is dissociated by the action of an acid, a structure represented by General Formula (VI-A) is preferable.

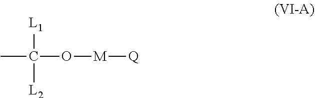

L₁ and L₂ each independently represent a hydrogen atom, an alkyl group, a cycloalkyl group, an aryl group, or a group obtained by combining an alkylene group and an aryl group.

M represents a single bond or a divalent linking group.

Q represents an alkyl group, a cycloalkyl group which may contain a heteroatom, an aryl group which may contain a heteroatom, an amino group, an ammonium group, a mercapto group, a cyano group, or an aldehyde group.

At least two out of Q, M, and L₁ may be bonded to each other to form a ring (preferably a 5- or 6-membered ring).

The repeating unit represented by General Formula (VI) is preferably a repeating unit represented by General Formula (3).

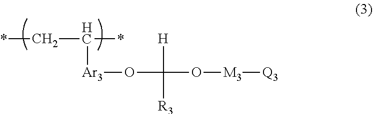

In General Formula (3),

Ar₃ represents an aromatic ring group.

R₃ represents a hydrogen atom, an alkyl group, a cycloalkyl group, an aryl group, an aralkyl group, an alkoxy group, an acyl group, or a heterocyclic group.

M₃ represents a single bond or a divalent linking group.

Q₃ represents an alkyl group, a cycloalkyl group, an aryl group, or a heterocyclic group.

At least two out of Q₃, M₃, and R₃ may be bonded to each other to form a ring.

The aromatic ring group represented by Ar₃ is the same as Ar₆ in General Formula (VI) in which n is 1. Ar₃ is preferably a phenylene group or a naphthylene group, and more preferably a phenylene group.

(Repeating Unit Having Silicon Atom on Side Chain)

The resin P may further contain a repeating unit having a silicon atom on a side chain. Examples of the repeating unit having a silicon atom on a side chain include a (meth)acrylate-based repeating unit having a silicon atom, a vinyl-based repeating unit having a silicon atom, and the like. Typically, the repeating unit having a silicon atom on a side chain is a repeating unit having a group having a silicon atom on a side chain. Examples of the group having a silicon atom include a trimethylsilyl group, a triethylsilyl group, a triphenylsilyl group, a tricyclohexylsilyl group, a tristrimethylsiloxysilyl group, a tristrimethylsilyl silyl group, a methyl bistrimethylsilyl silyl group, a methyl bistrimethylsiloxysilyl group, a dimethyltrimethylsilyl silyl group, a dimethyl trimethylsiloxysilyl group, cyclic or linear polysiloxane shown below, a cage-like, ladder-like, or random silsesquioxane structure, and the like. In the formulae, R and R¹ each independently represent a monovalent substituent. * represents a bond.

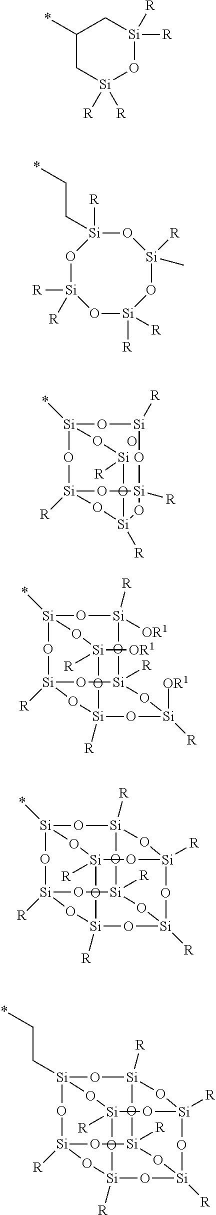

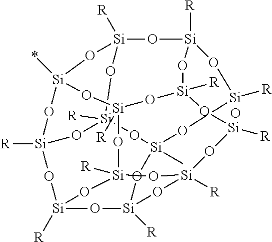

As the repeating unit having the aforementioned group, for example, a repeating unit derived from an acrylate or methacrylate compound having the aforementioned group or a repeating unit derived from a compound having the aforementioned group and a vinyl group is preferable.

In a case where the resin P has the repeating unit having a silicon atom on a side chain, the content of the repeating unit with respect to all the repeating units in the resin P is preferably 1 to 30 mol %, more preferably 5 to 25 mol %, and even more preferably 5 to 20 mol %.

The weight-average molecular weight of the resin P that is measured by gel permeation chromatography (GPC) and expressed in terms of polystyrene is preferably 1,000 to 200,000, more preferably 3,000 to 20,000, and even more preferably 5,000 to 15,000. In a case where the weight-average molecular weight is 1,000 to 200,000, it is possible to prevent the deterioration of heat resistance and dry etching resistance, to prevent the deterioration of developability, and to prevent film forming properties from deteriorating due to the increase in viscosity.

The dispersity (molecular weight distribution) is generally 1 to 5, preferably 1 to 3, more preferably 1.2 to 3.0, and even more preferably 1.2 to 2.0.

The content of the resin P in the total solid content of the present chemical liquid is preferably 50% to 99.9% by mass, and more preferably 60% to 99.0% by mass.

In the present chemical liquid, one kind of resin P may be used singly, or two or more kinds of resins P may be used in combination.

As other components (for example, an acid generator, a basic compound, a quencher, a hydrophobic resin, a surfactant, a solvent, and the like) to be incorporated into the present chemical liquid, any of known components can be used. Examples of the chemical liquid include components contained in the actinic ray-sensitive or radiation-sensitive resin compositions described in JP2013-195844A, JP2016-057645A, JP2015-207006A, WO2014/148241A, JP2016-188385A, and JP2017-219818A, and the like.

[Use of Chemical Liquid]

It is preferable that the present chemical liquid is used for manufacturing semiconductor devices. Particularly, it is more preferable that the present chemical liquid is used for forming a fine pattern at a node equal to or smaller than 10 nm (for example, a step including pattern formation using EUV).

The present chemical liquid is particularly preferably used as a chemical liquid (a prewet solution, a developer, a rinsing solution, a solvent of a resist solution, a peeling solution, or the like) used in a resist process in which either or both of a pattern width and a pattern interval are equal to or smaller than 17 nm (preferably equal to or smaller than 15 nm and more preferably equal to or smaller than 12 nm) and/or either or both of the obtained wiring widths and wiring interval are equal to or smaller than 17 nm. In other words, the present chemical liquid is particularly preferably used for manufacturing semiconductor devices manufactured using a resist film in which either or both of a pattern width and a pattern interval are equal to or smaller than 17 nm.

Specifically, in a semiconductor device manufacturing process including a lithography step, an etching step, an ion implantation step, a peeling step, and the like, after each step is finished or before the next step is started, the present chemical liquid is used for treating organic substances. To be concrete, the present chemical liquid is suitably used as a prewet solution, a developer, a rinsing solution, a peeling solution, or the like. For example, the present chemical liquid can be used for rinsing the edge line of semiconductor substrates before and after the coating with resist.

Furthermore, the present chemical liquid can also be used as a diluent for a resin contained in a resist solution and as a solvent contained in the resist solution. In addition, the present chemical liquid may be diluted with another organic solvent and/or water, and the like.

The present chemical liquid can also be used for other uses in addition to the manufacturing of semiconductor devices. The present chemical liquid can be used as a developer or a rinsing solution of polyimide, a resist for a sensor, a resist for a lens, and the like.

The present chemical liquid can also be used as a solvent for medical uses or for washing. Particularly, the present chemical liquid can be suitably used for washing containers, piping, substrates (for example, a wafer and glass), and the like.

The present chemical liquid is more effective particularly in a case where the present chemical liquid is used as a raw material of at least one kind of liquid selected from the group consisting of a developer, a rinsing solution, a wafer washing solution, a line washing solution, a prewet solution, a resist solution, a solution for forming an underlayer film, a solution for forming an overlayer film, and a solution for forming a hardcoat.

[Chemical Liquid Manufacturing Method]

As the method for manufacturing the present chemical liquid, known methods can be used without particular limitation. In view of making the effects of the present invention further exhibited, it is particularly preferable that the present chemical liquid is obtained by purifying a substance to be purified containing an organic solvent. Specifically, examples of suitable embodiments of the method for manufacturing the present chemical liquid include an embodiment including a filtration step of filtering a substance to be purified, an ion removing step of subjecting the substance to be purified to an ion exchange process or ion adsorption, and a distillation step of distilling the substance to be purified.

The substance to be purified may be prepared by means of purchasing or the like or may be obtained by reacting raw materials. It is preferable that the content of impurities in the substance to be purified is small. Examples of commercial products of such a substance to be purified include those called “high-purity grade product”.

As the method for obtaining a substance to be purified (typically, a substance to be purified containing an organic solvent) by reacting raw materials, a known method can be used without particular limitation. Examples thereof include a method for obtaining an organic solvent by reacting a single raw material or a plurality of raw materials in the presence of a catalyst.

More specifically, examples of the method include a method for obtaining butyl acetate by reacting acetic acid and n-butanol in the presence of sulfuric acid; a method for obtaining 1-hexanol by reacting ethylene, oxygen, and water in the presence of Al(C₂H₅)₃; a method for obtaining 4-methyl-2-pentanol by reacting cis-4-methyl-2-pentene in the presence of diisopinocampheylborane (Ipc2BH); a method for obtaining propylene glycol 1-monomethyl ether 2-acetate (PGMEA) by reacting propylene oxide, methanol, and acetic acid in the presence of sulfuric acid; a method for obtaining isopropyl alcohol (IPA) by reacting acetone and hydrogen in the presence of copper oxide-zinc oxide-aluminum oxide; a method for obtaining ethyl lactate by reacting lactic acid and ethanol; and the like.

<Filtration Step>

The filtration step is a step of filtering the aforementioned substance to be purified by using a filter. Examples of components to be removed by the filtration step include, but are not limited to, metal-containing particles that can be included in the metal component.

The method of filtering the substance to be purified by using a filter is not particularly limited. However, it is preferable to use a method of passing the substance to be purified through a filter unit (letting the substance to be purified run through a filter unit) including a housing and a filter cartridge stored in the housing under pressure or under no pressure.

(Pore Size of Filter)

The pore size of the filter is not particularly limited, and a filter having a pore size that is generally used for filtering the substance to be purified can be used. Particularly, in view of making it easier to control the number of particles (metal-containing particles and the like) contained in the chemical liquid within a desired range, the pore size of the filter is preferably equal to or smaller than 200 nm, more preferably equal to or smaller than 20 nm, even more preferably equal to or smaller than 10 nm, particularly preferably equal to or smaller than 5 nm, and most preferably equal to or smaller than 3 nm. The lower limit thereof is not particularly limited. From the viewpoint of productivity, the lower limit is preferably equal to or greater than 1 nm in general.

In the present specification, the pore size of a filter and pore size distribution mean a pore size and pore size distribution determined by the bubble point of isopropanol (IPA) or HFE-7200 (“NOVEC 7200”, manufactured by 3M Company, hydrofluoroether, C₄F₉OC₂H₅).

In view of making it easier to control the number of particles contained in the chemical liquid, it is preferable that the pore size of the filter is equal to or smaller than 5.0 nm. Hereinafter, a filter having a pore size equal to or smaller than 5 nm will be also called “microporous filter”.

The microporous filter may be used singly or used together with another filter having a different pore size. From the viewpoint of further improving productivity, it is particularly preferable to use the microporous filter with a filter having a larger pore size. In this case, in a case where the substance to be purified having been filtered through the filter with a larger pore size is passed through the microporous filter, the clogging of the microporous filter is prevented.

That is, regarding the pore size of the filter, in a case where one filter is used, the pore size is preferably equal to or smaller than 5.0 nm, and in a case where two or more filters are used, the pore size of a filter with the smallest pore size is preferably equal to or smaller than 5.0 nm.

The way the two or more kinds of filters having different pore sizes are used in order is not particularly limited. For example, a method may be used in which the filter units described above are arranged in order along a pipe line through which the substance to be purified is transferred. At this time, in a case where an attempt is made to set the flow rate of the substance to be purified per unit time to be constant throughout the entire pipe line, sometimes the pressure applied to a filter unit having a smaller pore size is higher than the pressure applied to a filter unit having a larger pore size. In this case, it is preferable to dispose a pressure control valve, a damper, or the like between the filter units such that constant pressure is applied to the filter unit having a smaller pore size, or to arrange filter units housing the same filters in a row along the pipe line such that the filtration area is enlarged. In a case where this method is used, it is possible to more stably control the number of particles in the chemical liquid.

(Material of Filter)

As the material of the filter, materials known as filter materials can be used without particular limitation. Specifically, examples of the material of the filter include a resin like polyamide such as nylon (for example, 6-nylon and 6,6-nylon); polyolefin such as polyethylene and polypropylene; polystyrene; polyimide; polyamide imide; poly(meth)acrylate; polyfluorocarbon such as polytetrafluoroethylene, perfluoroalkoxyalkane, a perfluoroethylene propene copolymer, an ethylene-tetrafluoroethylene copolymer, an ethylene-chlorotrifluoroethylene copolymer, polychlorotrifluoroethylene, polyvinylidene fluoride, and polyvinyl fluoride; polyvinyl alcohol; polyester; cellulose; cellulose acetate, and the like. Among these, at least one kind of resin selected from the group consisting of nylon (particularly preferably 6,6-nylon), polyolefin (particularly preferably polyethylene), poly(meth)acrylate, and polyfluorocarbon (particularly preferably polytetrafluoroethylene (PTFE) and perfluoroalkoxyalkane (PFA)) is preferable, because this resin has higher solvent resistance and makes it possible to obtain a chemical liquid having further improved defect inhibition performance. One kind of each of these polymers can be used singly, or two or more kinds of these polymers can be used in combination.

In addition to the resin, diatomite, glass, and the like may be used.

Furthermore, a polymer (such as nylon-grafted UPE) obtained by bonding polyamide (for example, nylon such as nylon-6 or nylon-6,6) to polyolefin (such as UPE which will be described later) by graft copolymerization may be used as the material of the filter.

Furthermore, the filter may be a filter having undergone a surface treatment. As the surface treatment method, known methods can be used without particular limitation. Examples of the surface treatment method include a chemical modification treatment, a plasma treatment, a hydrophobization treatment, coating, a gas treatment, sintering, and the like.

The plasma treatment is preferable because the surface of the filter is hydrophilized by this treatment. Although the water contact angle on the surface of a filter medium hydrophilized by the plasma treatment is not particularly limited, a static contact angle measured at 25° C. by using a contact angle meter is preferably equal to or smaller than 60°, more preferably equal to or smaller than 50°, and even more preferably equal to or smaller than 30°.

As the chemical modification treatment, a method of introducing ion exchange groups into a base material is preferable.

That is, the filter is preferably obtained by using various materials exemplified above as a base material and introducing ion exchange groups into the base material. Typically, it is preferable that the filter includes a layer, which includes a base material containing ion exchange groups, on a surface of the base material described above. Although the surface-modified base material is not particularly limited, as the filter, a filter obtained by introducing ion exchange groups into the aforementioned polymer is preferable because such a filter is easier to manufacture.

Examples of the ion exchange groups include cation exchange groups such as a sulfonic acid group, a carboxyl group, and a phosphoric acid group and anion exchange groups such as a quaternary ammonium group. The method of introducing ion exchange groups into the polymer is not particularly limited, and examples thereof include a method of reacting a compound containing ion exchange groups and polymerizable groups with the polymer such that the compound is, typically, grafted on the polymer.

The method of introducing the ion exchange groups is not particularly limited. In a case where the fiber of the resin is irradiated with ionizing radiation (such as α-rays, β-rays, γ-rays, X-rays, or electron beams), active portions (radicals) are generated in the resin. The irradiated resin is immersed in a monomer-containing solution such that the monomer is graft-polymerized with the base material. As a result, a polymer is generated in which the monomer is bonded to polyolefin fiber as a side chain by graft polymerization. By bringing the resin containing the generated polymer as a side chain into contact with a compound containing an anion exchange group or a cation exchange group so as to cause a reaction, an end product is obtained in which the ion exchange group is introduced into the polymer of the graft-polymerized side chain.

Furthermore, the filter may be constituted with woven cloth in which ion exchange groups are formed by a radiation graft polymerization method or constituted with a combination of nonwoven cloth and glass wool, woven cloth, or nonwoven filter medium that is conventionally used.

In a case where the filter containing ion exchange groups is used, the content of metal atom-containing particles in the chemical liquid is more easily controlled within a desired range. The material of the filter containing ion exchange groups is not particularly limited, and examples thereof include polyfluorocarbon, a material obtained by introducing ion exchange groups into polyolefin, and the like. Among these, the material obtained by introducing ion exchange groups into polyfluorocarbon is more preferable.

The pore size of the filter containing ion exchange groups is not particularly limited, but is preferably 1 to 30 nm and more preferably 5 to 20 nm. The filter containing ion exchange groups may also be used as the aforementioned filter having the smallest pore size or used as a filter different from the filter having the smallest pore size. Particularly, in view of obtaining a chemical liquid exhibiting further improved effects of the present invention, it is preferable that the filter which contains ion exchange groups and the filter which does not contain ion exchange groups and has the smallest pore size are used in the filtration step.

The material of the aforementioned filter having the smallest pore size is not particularly limited. However, from the viewpoint of solvent resistance and the like, as such a material, generally, at least one kind of material selected from the group consisting of polyfluorocarbon and polyolefin is preferable, and polyolefin is more preferable.

Therefore, as the filter used in the filtration step, two or more kinds of filters made of different materials may be used. For example, two or more kinds of filters may be used which are selected from the group consisting of filters made of polyolefin, polyfluorocarbon, polyamide, or a material obtained by introducing ion exchange groups into these materials.

(Pore Structure of Filter)

The pore structure of the filter is not particularly limited, and may be appropriately selected according to the components in the substance to be purified. In the present specification, the pore structure of the filter means a pore size distribution, a positional distribution of pores in the filter, a pore shape, and the like. Typically, the pore structure can be controlled by the filter manufacturing method.

For example, in a case where powder of a resin or the like is sintered to form a filter, a porous membrane is obtained. Furthermore, in a case where a method such as electrospinning, electroblowing, or melt blowing is used to form a filter, a fiber membrane is obtained. These have different pore structures.

“Porous membrane” means a membrane which retains components in a substance to be purified, such as gel, particles, colloids, cells, and polyoligomers, but allows the components substantially smaller than the pores of the membrane to pass through the membrane. The retention of components in the substance to be purified by the porous membrane depends on operating conditions, for example, the surface velocity, the use of a surfactant, the pH, and a combination of these in some cases. Furthermore, the retention of components can depend on the pore size and structure of the porous membrane, and the size and structure of particles supposed to be removed (such as whether the particles are hard particles or gel).

In a case where the substance to be purified contains negatively charged particles, a filter made of polyamide functions as a non-sieving membrane so as to remove such particles. Typical non-sieving membranes include, but are not limited to, nylon membranes such as a nylon-6 membrane and a nylon-6,6 membrane.

“Non-sieving” retention mechanism used in the present specification refers to retention resulting from the mechanism such as blocking, diffusion, and adsorption irrelevant to the pressure drop or pore size of the filter.

The non-sieving retention includes a retention mechanism such as blocking, diffusion, and adsorption for removing particles supposed to be removed from the substance to be purified irrespective of the pressure drop or pore size of the filter. The adsorption of particles onto the filter surface can be mediated, for example, by the intermolecular van der Waals force and electrostatic force. In a case where the particles moving in the non-sieving membrane layer having a meandering path cannot sufficiently rapidly change direction so as not to come into contact with the non-sieving membrane, a blocking effect is exerted. The transport of particles by diffusion is mainly caused by the random motion or the Brownian motion of small particles that results in a certain probability that the particles may collide with the filter medium. In a case where there is no repulsive force between the particles and the filter, the non-sieving retention mechanism can be activated.

An ultra-high-molecular-weight polyethylene (UPE) filter is typically a sieving membrane. A sieving membrane means a membrane that traps particles mainly through a sieving retention mechanism or a membrane that is optimized for trapping particles through a sieving retention mechanism.

Typical examples of the sieving membrane include, but are not limited to, a polytetrafluoroethylene (PTFE) membrane and a UPE membrane.

“Sieving retention mechanism” refers to the retention caused in a case where the particles to be removed are larger than the pore size of the porous membrane. Sieving retentivity can be improved by forming a filter cake (aggregate of particles to be removed on the surface of the membrane). The filter cake effectively functions as a secondary filter.

The material of the fiber membrane is not particularly limited as long as it is a polymer capable of forming the fiber membrane. Examples of the polymer include polyamide and the like. Examples of the polyamide include nylon 6, nylon 6,6, and the like. The polymer forming the fiber membrane may be poly(ethersulfone). In a case where the fiber membrane is on the primary side of the porous membrane, it is preferable that the surface energy of the fiber membrane is higher than the surface energy of the polymer which is the material of the porous membrane on a secondary side. For example, in some cases, nylon as a material of the fiber membrane and polyethylene (UPE) as the porous membrane are combined.

As the fiber membrane manufacturing method, known methods can be used without particular limitation. Examples of the fiber membrane manufacturing method include electrospinning, electroblowing, melt blowing, and the like.

The pore structure of the porous membrane (for example, a porous membrane including UPE, PTFE, and the like) is not particularly limited. The pores have, for example, a lace shape, a string shape, a node shape, and the like.

The size distribution of pores in the porous membrane and the positional distribution of pore size in the membrane are not particularly limited. The size distribution may be narrower, and the positional distribution of pore size in the membrane may be symmetric. Furthermore, the size distribution may be wider, and the positional distribution of pore size in the membrane may be asymmetric (this membrane is also called “asymmetric porous membrane”). In the asymmetric porous membrane, the size of the holes changes in the membrane. Typically, the pore size increases toward the other surface of the membrane from one surface of the membrane. In this case, the surface with many pores having a large pore size is called “open side”, and the surface with many pores having a small pore size is also called “tight side”.

Examples of the asymmetric porous membrane include a membrane in which the pore size is minimized at a position in the thickness direction of the membrane (this is also called “hourglass shape”).

In a case where the asymmetric porous membrane is used such that large holes are on the primary side, in other words, in a case where the primary side is used as the open side, a pre-filtration effect can be exerted.

The porous membrane layer may contain a thermoplastic polymer such as polyethersulfone (PESU), perfluoroalkoxyalkane (PFA, a copolymer of polytetrafluoroethylene and perfluoroalkoxyalkane), polyamide, or polyolefin, or may contain polytetrafluoroethylene and the like.

Among these, ultra-high-molecular-weight polyethylene is preferable as the material of the porous membrane. The ultra-high-molecular-weight polyethylene means thermoplastic polyethylene having a very long chain. The molecular weight thereof is equal to or greater than 1,000,000. Typically, the molecular weight thereof is preferably 2,000,000 to 6,000,000.

As filters used in the filtration step, two or more kinds of filters having different pore structures may be used, or a porous membrane filter and a fiber membrane filter may be used in combination. Specifically, for example, a method may be used in which a nylon fiber membrane filter and a UPE porous membrane filter are used.

It is preferable that the filters are used after being thoroughly washed before use.

In a case where an unwashed filter (or a filter that has not been thoroughly washed) is used, the impurities contained in the filter are easily mixed into the chemical liquid.

Examples of the impurities contained in the filter include the organic compounds described above. In a case where an unwashed filter (or a filter that has not been thoroughly washed) is used to perform the filtration step, sometimes the content of the organic compounds in the chemical liquid exceeds the range acceptable for the chemical liquid according to the embodiment of the present invention.

For example, in a case where polyolefin such as UPE and polyfluorocarbon such as PTFE are used in a filter, the filter tends to contain an alkane having 12 to 50 carbon atoms as an impurity.

Furthermore, in a case where polyamide such as nylon, polyimide, and a polymer obtained by bonding polyamide (such as nylon) to polyolefin (such as UPE) by graft copolymerization are used in a filter, the filter tends to contain an alkene having 12 to 50 carbon atoms as an impurity.

The filter may be washed, for example, by a method of immersing the filter in an organic solvent with a small impurity content (for example, an organic solvent purified by distillation (such as PGMEA)) for 1 week or longer. In this case, the liquid temperature of the organic solvent is preferably 30° C. to 90° C.

To what extent the filter will be washed may be adjusted, such that the chemical liquid obtained after the substance to be purified is filtered using the filter contains organic compounds derived from the filter in a desired amount.

The filtration step may be a multi-stage filtration step in which the substance to be purified is passed through two or more kinds of filters that differ from each other in terms of at least one kind of aspect selected from the group consisting of filter material, pore size, and pore structure.

Furthermore, the substance to be purified may be passed through the same filter multiple times or passed through a plurality of filters of the same type.

The material of a liquid contact portion of the purification device used in the filtration step is not particularly limited (the liquid contact portion means an inner wall surface or the like that is likely to come into contact with the substance to be purified and the chemical liquid). However, it is preferable that the liquid contact portion is formed of at least one kind of material selected from the group consisting of a nonmetallic material (such as a fluororesin) and an electropolished metallic material (such as stainless steel) (hereinafter, these materials will be collectively called “anticorrosive material”). For example, in a case where a liquid contact portion of a manufacturing tank is formed of an anticorrosive material, the manufacturing tank itself is formed of the anticorrosive material, or the inner wall surface or the like of the manufacturing tank is coated with the anticorrosive material.

As the nonmetallic material, known materials can be used without particular limitation.

Examples of the nonmetallic material include at least one kind of material selected from the group consisting of a polyethylene resin, a polypropylene resin, a polyethylene-polypropylene resin, and a fluororesin (for example, polytetrafluoroethylene, a polytetrafluoroethylene-perfluoroalkyl vinyl ether copolymer resin, a polytetrafluoroethylene-hexafluoropropylene copolymer resin, a polytetrafluoroethylene-ethylene copolymer resin, a chlorotrifluoroethylene-ethylene copolymer resin, a vinylidene fluoride resin, a chlorotrifluoroethylene copolymer resin, a vinyl fluoride resin, and the like). However, the present invention is not limited to these.

As the metallic material, known materials can be used without particular limitation.

Examples of the metallic material include a metallic material in which the total content of chromium and nickel is greater than 25% by mass with respect to the total mass of the metallic material. The total content of chromium and nickel is more preferably equal to or greater than 30% by mass. The upper limit of the total content of chromium and nickel in the metallic material is not particularly limited, but is preferably equal to or smaller than 90% by mass in general.

Examples of the metallic material include stainless steel, a nickel-chromium alloy, and the like.

As the stainless steel, known stainless steel can be used without particular limitation. Among these, an alloy with a nickel content equal to or greater than 8% by mass is preferable, and austenite-based stainless steel with a nickel content equal to or greater than 8% by mass is more preferable. Examples of the austenite-based stainless steel include Steel Use Stainless (SUS) 304 (Ni content: 8% by mass, Cr content: 18% by mass), SUS304L (Ni content: 9% by mass, Cr content: 18% by mass), SUS316 (Ni content: 10% by mass, Cr content: 16% by mass), SUS316L (Ni content: 12% by mass, Cr content: 16% by mass), and the like.

As the nickel-chromium alloy, known nickel-chromium alloys can be used without particular limitation. Among these, a nickel-chromium alloy is preferable in which the nickel content is 40% to 75% by mass and the chromium content is 1% to 30% by mass.

Examples of the nickel-chromium alloy include HASTELLOY (trade name, the same is true of the following description), MONEL (trade name, the same is true of the following description), INCONEL (trade name, the same is true of the following description), and the like. More specifically, examples thereof include HASTELLOY C-276 (Ni content: 63% by mass, Cr content: 16% by mass), HASTELLOY C (Ni content: 60% by mass, Cr content: 17% by mass), HASTELLOY C-22 (Ni content: 61% by mass, Cr content: 22% by mass), and the like.

Furthermore, if necessary, the nickel-chromium alloy may further contain boron, silicon, tungsten, molybdenum, copper, cobalt, and the like in addition to the aforementioned alloy.

As the method of electropolishing the metallic material, known methods can be used without particular limitation. For example, it is possible to use the methods described in paragraphs “0011” to “0014” in JP2015-227501A, paragraphs “0036” to “0042” in JP2008-264929A, and the like.

Presumably, in a case where the metallic material is electropolished, the chromium content in a passive layer on the surface thereof may become higher than the chromium content in the parent phase. Therefore, presumably, in a case where a purification device having a liquid contact portion formed of the electropolished metallic material is used, metal-containing particles may be hardly eluted into the substance to be purified.

The metallic material may have undergone buffing. As the buffing method, known methods can be used without particular limitation. The size of abrasive grains used for finishing the buffing is not particularly limited, but is preferably equal to or smaller than #400 because such grains make it easy to further reduce the surface asperity of the metallic material. The buffing is preferably performed before the electropolishing.

<Ion Removing Step>

The ion removing step is a step of performing an ion exchange process or ion adsorption by a chelating group on the substance to be purified containing an organic solvent. Examples of components to be removed by the ion removing step include, but are not limited to, acid components and metal ions included in metal components.

As the method of performing the ion exchange process, known methods can be used without particular limitation. Typically, examples thereof include a method of passing the substance to be purified through a packed portion packed with an ion exchange resin.

In the Ion removing step, the substance to be purified may be passed through the same ion exchange resin multiple times, or the substance to be purified may be passed through different ion exchange resins.

Examples of the ion exchange resin include a cation exchange resin and an anion exchange resin. It is preferable to use at least a cation exchange resin, because then the content of the metal component is controlled and the mass ratio of the content of the acid component to the content of the metal component easily falls into the range described above. It is more preferable to use a cation exchange resin and an anion exchange resin together, because then the content of the acid component can be controlled.

In a case where both the cation exchange resin and anion exchange resin are used, the substance to be purified may be passed through a packed portion packed with a mixed resin including these resins or passed through a plurality of packed portions filled with each resin.

As the cation exchange resin, known cation exchange resins can be used. Particularly, a gel-type cation exchange resin is preferable.

Specific examples of the cation exchange resin include a sulfonic acid-type cation exchange resin and a carboxylic acid-type cation exchange resin.

As the cation exchange resin, commercial products can be used. Examples thereof include AMBERLITE IR-124, AMBERLITE IR-120B, AMBERLITE IR-200CT, ORLITE DS-1, and ORLITE DS-4 (manufactured by ORGANO CORPORATION), DUOLITE C20J, DUOLITE C20LF, DUOLITE C255LFH, and DUOLITE C-433LF (manufactured by Sumika Chemtex Co., Ltd.), DIAION SK-110, DIAION SK1B, and DIAION SK1BH (manufactured by Mitsubishi Chemical Corporation.), PUROLITE 5957 and PUROLITE 5985 (manufactured by Purolite), and the like.

As the anion exchange resin, known anion exchange resins can be used. Particularly, a gel-type anion exchange resin is preferably used.

Examples of acid component present as ions in the substance to be purified include an inorganic acid derived from a catalyst during the manufacturing of the substance to be purified, an organic acid (for example, a raw material of the reaction, an Isomer, or a byproduct) generated after a reaction during the manufacturing of the substance to be purified, and the like. Based on the Hard and Soft Acids and Bases (HSAB) theory, such an acid component is classified as a hard to moderately hard acid. Therefore, in order that such an acid component is more efficiently removed by the interaction with an anion exchange resin, it is preferable to use an anion exchange resin containing a hard to moderately hard base.

As the anion exchange resin containing a hard to moderately hard base, at least one kind of anion exchange resin is preferable which is selected from the group consisting of a strongly basic type I anion exchange resin having a trimethylammonium group, a slightly weak strong basic type II anion exchange resin having a dimethylethanol ammonium group, and a weakly basic anion exchange resin such as dimethylamine or diethylenetriamine.

Among the acid components, for example, an organic acid is a hard acid. Furthermore, among inorganic acids, a sulfate ion is a moderately hard acid. Therefore, in a case where the strongly basic or slightly weak strong basic anion exchange resin described above and a moderately hard weakly basic anion exchange resin are used in combination, it is easy to reduce the content of the acid component to a suitable range.

As the anion exchange resin, commercial products can be used. Examples thereof include AMBERLITE IRA-400J, AMBERLITE IRA-410J, AMBERLITE IRA-900J, AMBERLITE IRA67, ORLITE DS-2, ORLITE DS-5, and ORLITE DS-6 (manufactured by ORGANO CORPORATION), DUOLITE A113LF, DUOLITE A116, and DUOLITE A-375LF (manufactured by Sumika Chemtex Co., Ltd.), DIAION SA12A, DIAION SA10AO, DIAION SA10AOH, DIAION SA20A, and DIAION WA10 (manufactured by Mitsubishi Chemical Corporation.), and the like.

Among these, examples of anion exchange resins containing the aforementioned hard to moderately hard base include ORLITE DS-6 and ORLITE DS-4 (manufactured by ORGANO CORPORATION), DIAION SA12A, DIAION SA10AO, DIAION SA10AOH, and DIAION SA20A, and DIAION WA10 (manufactured by Mitsubishi Chemical Corporation.), PUROLITE A400, PUROLITE A500, and PUROLITE A850, (manufactured by Purolite), and the like.

Ion adsorption by a chelating group can be performed using, for example, a chelating resin having a chelating group. In capturing ions, the chelating resin does not release ions as alternatives. Furthermore, the chelating resin does not use a strongly acidic or strongly basic functional group which is chemically extremely active. Accordingly, by the chelating resin, an organic solvent to be purified by a hydrolysis and condensation reaction can be inhibited from undergoing a side reaction. Therefore, purification can be performed with higher efficiency.

Examples of the chelating resin include resins having a chelating ability or chelating groups such as an amidoxime group, a thiourea group, a thiouronium group, iminodiacetic acid, amidophosphoric acid, phosphonic acid, aminophosphoric acid, aminocarboxylic acid, N-methylglucamine, an alkylamino group, a pyridine ring, cyclic cyanine, a phthalocyanine ring, and a cyclic ether.

As the chelating resin, commercial products can be used. Examples thereof include DUOLITE ES371N, DUOLITE C467, DUOLITE C747UPS, SUMICHELATE MC760, SUMICHELATE MC230, SUMICHELATE MC300, SUMICHELATE MC850, SUMICHELATE MC640, and SUMICHELATE MC900 (manufactured by Sumika Chemtex Co., Ltd.), PUROLITE 5106, PUROLITE 5910, PUROLITE 5914, PUROLITE 5920, PUROLITE 5930, PUROLITE 5950, PUROLITE 5957, and PUROLITE 5985 (manufactured by Purolite), and the like.

As the method of performing ion adsorption, known methods can be used without particular limitation. Typically, examples thereof include a method of passing the substance to be purified through a packed portion packed with a chelating resin.

In the Ion removing step, the substance to be purified may be passed through the same chelating resin multiple times, or the substance to be purified may be passed through different chelating resins.

The packed portion generally includes a container and the aforementioned ion exchange resin filled into the container.

Examples of the container include a column, a cartridge, a packed column, and the like. Containers other than those exemplified above may also be used as long as the substance to be purified can pass through the containers packed with the ion exchange resin described above.

<Distillation Step>

The distillation step is a step of distilling the substance to be purified containing an organic solvent so as to obtain a substance to be purified having undergone distillation. Examples of components to be removed by the distillation step include, but are not limited to, acid components, other organic compounds, and water.

As the method of distilling the substance to be purified, known methods can be used without particular limitation. Typically, examples thereof include a method of disposing a distillation column on a primary side of the purification device used in the filtration step and introducing the distilled substance to be purified into a manufacturing tank.

At this time, the liquid contact portion of the distillation column is not particularly limited, but is preferably formed of the anticorrosive material described above.

In the distillation step, the substance to be purified may be passed through the same distillation column multiple times, or the substance to be purified may be passed through different distillation columns.

In a case where the substance to be purified is passed through different distillation columns, for example, a method may be used in which a rough distillation treatment is performed to remove low-boiling-point acid components and the like by passing the substance to be purified through a distillation column and then a fractionation treatment is performed to remove acid components, other organic compounds, and the like by passing the substance to be purified through a distillation column different from the distillation column used in the rough distillation treatment. Examples of the distillation column used in the rough distillation treatment include a plate distillation column. Examples of the distillation column used in the fractionation treatment include a distillation column including at least one of the plate distillation column or the pressure-reducing plate distillation column.

Furthermore, in order to satisfy both the thermal stability and purification accuracy during distillation, distillation under reduced pressure can also be selected.

<Other Steps>

The chemical liquid manufacturing method may further have other steps in addition to the above. Examples of steps other than the filtration step include a reaction step, an electricity removing step, and the like.

(Reaction Step)

The reaction step is a step of reacting raw materials so as to generate a substance to be purified containing an organic solvent as a reactant. As the method of generating the substance to be purified, known methods can be used without particular limitation. Typically, examples thereof include a method of disposing a reactor on a primary side of the manufacturing tank (or the distillation column) of the purification device used in the filtration step and introducing the reactant into the manufacturing tank (or the distillation column).

The liquid contact portion of the manufacturing tank is not particularly limited, but is preferably formed of the anticorrosive material described above.

(Electricity Removing Step)

The electricity removing step is a step of removing electricity from the substance to be purified such that the charge potential of the substance to be purified is reduced.

As the electricity removing method, known electricity removing methods can be used without particular limitation. Examples of the electricity removing method include a method of bringing the substance to be purified into contact with a conductive material.

The contact time for which the substance to be purified is brought into contact with a conductive material is preferably 0.001 to 60 seconds, more preferably 0.001 to 1 second, and particularly preferably 0.01 to 0.1 seconds. Examples of the conductive material include stainless steel, gold, platinum, diamond, glassy carbon, and the like.

Examples of the method of bringing the substance to be purified into contact with a conductive material include a method of disposing a grounded mesh formed of a conductive material in the interior of a pipe line and passing the substance to be purified through the mesh, and the like.

During the purification of the substance to be purified, it is preferable that all of the opening of a container, washing of a container and a device, storage of a solution, analysis, and the like that are included in the purification are performed in a clean room. It is preferable that the clean room has a cleanliness equal to or higher than class 4 specified in the international standard ISO14644-1:2015 established by International Organization for Standardization. Specifically, the clean room preferably meets any of ISO class 1, ISO class 2, ISO class 3, or ISO class 4, more preferably meets ISO class 1 or ISO class 2, and particularly preferably meets ISO class 1.

The storage temperature of the chemical liquid is not particularly limited. However, in view of further preventing the elution of traces of impurities and the like contained in the chemical liquid and consequently obtaining further improved effects of the present invention, the storage temperature is preferably equal to or higher than 4° C.

[Chemical Liquid Storage Body]

The present chemical liquid may be stored in a container and kept as it is until use. Such a container and the present chemical liquid stored in the container are collectively called chemical liquid storage body. The present chemical liquid is used after being taken out of the kept chemical liquid storage body.

As the container storing the present chemical liquid, a container for manufacturing semiconductor devices is preferable which has a high internal cleanliness and hardly causes elution of impurities.

Examples of the usable container specifically include a “CLEAN BOTTLE” series manufactured by AICELLO CORPORATION, “PURE BOTTLE” manufactured by KODAMA PLASTICS Co., Ltd., and the like, but the container is not limited to these.

As the container, for the purpose of preventing mixing of impurities into the chemical liquid (contamination), it is also preferable to use a multilayer bottle in which the inner wall of the container has a 6-layer structure formed of 6 kinds of resins or a multilayer bottle having a 7-layer structure formed of 6 kinds of resins. Examples of these containers include the containers described in JP2015-123351A.

At least a part of the liquid contact portion of the container may be the aforementioned anticorrosive material (preferably electropolished stainless steel or a fluororesin) or glass. In view of obtaining further improved effects of the present invention, it is preferable that 90% or more of the area of the liquid contact portion is formed of the above material. It is more preferable that the entirety of the liquid contact portion is formed of the above material.

[Kit]

The kit according to an embodiment of the present invention comprises the following chemical liquid X and the following chemical liquid Y. In a case where the kit according to the embodiment of the present invention is used in a pattern forming method which will be described later (particularly, in a case where the chemical liquid X is used as a developer and the chemical liquid Y is used as a rinsing solution), it is possible to obtain a pattern in which the occurrence of defects is inhibited due to the action of the chemical liquid X, and the obtained pattern has excellent resolution due to the synergy between the chemical liquid X and the chemical liquid Y.

Although the form of the kit is not particularly limited, for example, the kit has a container X, a chemical liquid storage body X having the chemical liquid X stored in the container X, a container Y, and a chemical liquid storage body Y having the chemical liquid Y stored in the container Y. As the container X and the container Y, it is preferable to use the container described above as the container in the chemical liquid storage body.

The chemical liquid X is the following chemical liquid X1 or chemical liquid X2. Among the present chemical liquids described above, a chemical liquid which contains an organic solvent including butyl acetate and an acid component including acetic acid and in which the content of the acetic acid is 0.01 to 15 mass ppm with respect to the total mass of the chemical liquid X1 is the chemical liquid X1. In addition, among the present chemical liquids described above, a chemical liquid which contains an organic solvent including butyl acetate and an acid component including n-butanoic acid and in which the content of the n-butanoic acid is equal to or greater than 1 mass ppt and equal to or smaller than 1 mass ppm with respect to the total mass of the chemical liquid X2 is the chemical liquid X2.

The chemical liquid Y contains an organic solvent. The organic solvent contained in the chemical liquid Y includes at least one kind of organic solvent Y selected from the group consisting of butyl butyrate, isobutyl isobutyrate, pentyl propionate, isopentyl propionate, ethylcyclohexane, mesitylene, decane, undecane, 3,7-dimethyl-3-octanol, 2-ethyl-1-hexanol, 1-octanol, 2-octanol, ethyl acetoacetate, dimethyl malonate, methyl pyruvate, and dimethyl oxalate. In a case where the chemical liquid Y is used as a rinsing solution in the pattern forming method which will be described later, due to the action of the organic solvent Y, the resolution of the obtained pattern can be improved.

The chemical liquid Y may be the present chemical liquid described above (that is, a chemical liquid containing an organic solvent, an acid component, and a metal component, in which the content of the acid component is equal to or greater than 1 mass ppt and equal to or smaller than 15 mass ppm with respect to the total mass of the chemical liquid, and the content of the metal component is 0.001 to 100 mass ppt with respect to the total mass of the chemical liquid), or may be a chemical liquid other than the present chemical liquid described above.

The chemical liquid other than the present chemical liquid described above means a chemical liquid which satisfies at least either a condition that the content of the acid component is less than 1 mass ppt or greater than 15 mass ppm with respect to the total mass of the chemical liquid or a condition that the content of the metal component is less than 0.001 mass ppt or greater than 100 mass ppt with respect to the total mass of the chemical liquid.

The content of the organic solvent Y in the chemical liquid Y with respect to the total mass of the chemical liquid Y is preferably equal to or greater than 20% by mass, more preferably equal to or greater than 30% by mass, even more preferably equal to or greater than 40% by mass, and particularly preferably 50% by mass. In a more suitable aspect, the content of the organic solvent Y is preferably equal to or greater than 98.0% by mass, more preferably equal to or greater than 99.0% by mass, even more preferably equal to or greater than 99.9% by mass, and particularly preferably equal to or greater than 99.99% by mass. The upper limit thereof is not particularly limited, but is equal to or smaller than 100% by mass.

The suitable range of the content of the organic solvent Y with respect to the total mass of the organic solvents contained in the chemical liquid Y is the same as the content of the organic solvent Y in the chemical liquid Y described above.

One kind of organic solvent Y may be used singly, or two or more kinds of organic solvents Y may be used in combination. In a case where two or more kinds of organic solvents Y are used in combination, the total content thereof is within the above range.

The chemical liquid Y may contain an organic solvent other than the organic solvent Y. Examples of the organic solvent other than the organic solvent Y include an organic solvent other than the organic solvent Y among the organic solvents exemplified above as the organic solvent of the present chemical liquid, ethanol, and the like.

In a case where the chemical liquid Y contains an organic solvent other than the organic solvent Y, the content of the organic solvent other than the organic solvent Y with respect to the total mass of the chemical liquid Y is preferably equal to or smaller than 60% by mass, more preferably equal to or smaller than 50% by mass, and even more preferably equal to or smaller than 10% by mass. In a case where the chemical liquid Y contains an organic solvent other than the organic solvent Y, the lower limit of the content of the organic solvent other than the organic solvent Y is greater than 0% by mass, preferably equal to or greater than 0.1% by mass, and more preferably equal to or greater than 1% by mass.

In a case where the chemical liquid Y contains an organic solvent other than the organic solvent Y, the suitable range of the content of the organic solvent other than the organic solvent Y with respect to the total mass of the organic solvents contained in the chemical liquid Y is the same as the content of the organic solvent other than the organic solvent Y in the chemical liquid Y described above.

The content of the organic solvents in the chemical liquid Y (that is, the total content of the organic solvent Y and the organic solvent other than the organic solvent Y) with respect to the total mass of the chemical liquid Y is preferably equal to or greater than 98.0% by mass, more preferably equal to or greater than 99.0% by mass, even more preferably equal to or greater than 99.9% by mass, and particularly preferably equal to or greater than 99.99% by mass. The upper limit thereof is not particularly limited, but is equal to or smaller than 100% by mass.

It is preferable that the organic solvent Y includes the organic solvent Y1 having a Hansen solubility parameter distance of 3 to 20 MPa^{0.5} (more preferably 5 to 20 MPa^{0.5}) to eicosene.

In a case where the chemical liquid Y contains two or more kinds of organic solvents Y, it is preferable that at least one kind of organic solvent Y is the organic solvent Y1.

In a case where the chemical liquid Y contains two or more kinds of organic solvents Y, it is preferable that a weighted average of the Hansen solubility parameters based on the molar ratio of the contents of the organic solvents satisfies the above range of the Hansen solubility parameter.

Among the organic solvents Y, as the organic solvent having a Hansen solubility parameter distance of 3 to 20 MPa^{0.5} to eicosene (that is, the organic solvent Y1), butyl butyrate (4.6), isobutyl isobutyrate (3.6), and dimethyl malonate (10.3) can be exemplified. The numerical values in the parenthesis for the compound show the Hansen solubility parameter distance to eicosene.

One of the examples of suitable aspects of the chemical liquid Y is an aspect in which the organic solvent Y is substantially composed only of the organic solvent Y1. “Organic solvent Y is substantially composed only of the organic solvent Y1” means that the content of the organic solvent Y1 is equal to or greater than 99% by mass (preferably equal to or greater than 99.9% by mass) with respect to the total mass of the organic solvent Y in the chemical liquid Y.

Furthermore, one of the examples of suitable aspects of the chemical liquid Y include an aspect in which the chemical liquid Y contains a mixed solvent including both the organic solvent Y and an organic solvent (for example, methanol or the like) other than the organic solvent Y, and the organic solvent Y is substantially composed only of the organic solvent Y1.

In this case, the content of the organic solvent Y1 is preferably 20% to 90% by mass with respect to the total mass of the chemical liquid Y. In view of further improving the resolution of a pattern, the content of the organic solvent Y1 is more preferably 20% to 80% by mass, and even more preferably 30% to 70% by mass.

In addition, the content of the organic solvent other than the organic solvent Y is preferably 10% to 80% by mass with respect to the total mass of the chemical liquid Y. In view of further improving the resolution of a pattern, the content of the organic solvent other than the organic solvent Y is more preferably 20% to 80% by mass, and even more preferably 30% to 70% by mass.

Furthermore, one of the examples of suitable aspects of the chemical liquid Y include an aspect in which the organic solvent in the chemical liquid is composed of the organic solvent Y, and the organic solvent Y is a mixed solvent including both the organic solvent Y1 and an organic solvent (hereinafter, also called “organic solvent Y2”) that does not satisfy the range of the Hansen solubility parameter described above.

In this case, the content of the organic solvent Y1 is preferably 20% to 90% by mass with respect to the total mass of the chemical liquid Y. In view of further improving the resolution of a pattern, the content of the organic solvent Y1 is more preferably 20% to 80% by mass, and even more preferably 30% to 70% by mass.

The content of the organic solvent Y2 is preferably 10% to 80% by mass with respect to the total mass of the chemical liquid Y. In view of further improving the resolution of a pattern, the content of the organic solvent Y2 is more preferably 20% to 80% by mass, and even more preferably 30% to 70% by mass.

Presumably, in a case where each of the content of the organic solvent Y1 and content of the organic solvent Y2 is within a certain range, the affinity of the chemical liquid Y with an organic material could be adjusted to a more appropriate range and the resolution of a pattern may be further improved, than in a case where the content of the organic solvent Y2 is excessively great or small.

The Hansen solubility parameter distance of the organic solvent Y2 to eicosene is equal to or greater than 0 MPa^{0.5} and less than 3 MPa^{0.5} (preferably greater than 0 MPa^{0.5} and less than 3 MPa^{0.5}) or greater than 20 MPa^{0.5} (preferably greater than 20 MPa^{0.5} and equal to or smaller than 50 MPa^{0.5}).

The Hansen solubility parameters in the present specification mean the Hansen solubility parameters described in “Hansen Solubility Parameters: A Users Handbook, Second Edition” (pp. 1-310, CRC Press, 2007), and the like. That is, the Hansen solubility parameters describe solubility by using multi-dimensional vectors (a dispersion element (δd), a dipole-dipole element (δp), and a hydrogen bond element (δh)). These three parameters can be considered as the coordinates of a point in a three-dimensional space called Hansen space.

The Hansen solubility parameter distance is a distance between two kinds of compounds in the Hansen space, and is calculated by the following equation.

(Ra)²=4(δd2−δd1)²+(δp2−δp1)²+(δh2−δh1)²

Ra: Hansen solubility parameter distance between first compound and second compound (unit: MPa^{0.5})

δd1: dispersion element of first compound (unit: MPa^{0.5})

δd2: dispersion element of second compound (unit: MPa^{0.5})

δp1: dipole-dipole element of first compound (unit: MPa^{0.5})

δp2: dipole-dipole element of second compound (unit: MPa^{0.5})

δh1: hydrogen bond element of first compound (unit: MPa^{0.5})

δh2: hydrogen bond element of second compound (unit: MPa^{0.5})

In the present specification, specifically, the Hansen solubility parameters of a compound are calculated using Hansen Solubility Parameter in Practice (HSPiP).

[Pattern Forming Method]

It is preferable that the present chemical liquid is used for forming a resist pattern (hereinafter, simply called “pattern”) used for manufacturing semiconductors. The pattern forming method in which the present chemical liquid is used is not particularly limited, and examples thereof include known pattern forming methods.

One of the examples of suitable aspects of the pattern forming method according to an embodiment of the present invention is an aspect in which the chemical liquid X described above in the section of kit is used as a developer, and the chemical liquid Y described above in the section of kit is used as a rinsing solution. Specifically, it is preferable that the pattern forming method includes the following steps.

(A) Resist film forming step of forming resist film by using actinic ray-sensitive or radiation-sensitive resin composition

(B) Exposure step of exposing resist film

(C) Development step of developing exposed resist film by using chemical liquid X

(D) Rinsing step of performing washing by using chemical liquid Y after development step

Hereinafter, the aspect of each of the above steps will be described. The chemical liquid X and the chemical liquid Y will not be described because they are the same as those described above.

[Resist Film Forming Step]

The resist film forming step is a step of forming a resist film by using an actinic ray-sensitive or radiation-sensitive resin composition.

Hereinafter, first, the form of the actinic ray-sensitive or radiation-sensitive resin composition will be described.

<Actinic Ray-Sensitive or Radiation-Sensitive Resin Composition>

As the actinic ray-sensitive or radiation-sensitive resin composition which can be used in the resist film forming step, known actinic ray-sensitive or radiation-sensitive resin compositions can be used without particular limitation.

It is preferable that the actinic ray-sensitive or radiation-sensitive resin composition (hereinafter, also called “resist composition”) contains a resin (hereinafter, also called “acid-decomposable resin” in the present specification), which contains a repeating unit containing a group generating a polar group (a carboxyl group, a phenolic hydroxyl group, or the like) by being decomposed by the action of an acid, and a compound (hereinafter, also called “photoacid generator” in the present specification) which generates an acid by the irradiation with actinic rays or radiation.

Particularly, in view of obtaining further improved effects of the present invention, the following resist compositions are preferable.
Resist composition containing resin represented by Formula (I) which will be described later
Resist composition containing acid-decomposable resin having phenolic hydroxyl group which will be described later
Resist composition containing hydrophobic resin, which will be described later, and acid-decomposable resin

Hereinafter, each of the components of the resist compositions will be described.

(Acid-Decomposable Resin)

In the acid-decomposable group, the polar group is protected with a group dissociated by an acid (acid-dissociable group). Examples of the acid-dissociable group include —C(R₃₆)(R₃₇)(R₃₈), —C(R₃₆)(R₃₇)(OR₃₉), —C(R₀₁)(R₀₂)(OR₃₉), and the like.

In the formulae, R₃₆ to R₃₉ each independently represent an alkyl group, a cycloalkyl group, an aryl group, an aralkyl group, or an alkenyl group. R₃₆ and R₃₇ may be bonded to each other to form a ring.

R₀₁ and R₀₂ each independently represent a hydrogen atom, an alkyl group, a cycloalkyl group, an aryl group, an aralkyl group, or an alkenyl group.

Examples of the acid-decomposable resin include a resin P having an acid-decomposable group represented by Formula (AI).

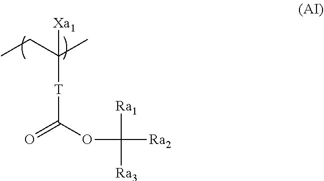

In Formula (AI),

Xa₁ represents a hydrogen atom or an alkyl group which may have a substituent.

T represents a single bond or a divalent linking group.

Ra₁ to Ra₃ each independently represent an alkyl group (linear or branched) or a cycloalkyl group (monocyclic or polycyclic).

Two out of Ra₁ to Ra₃ may be bonded to each other to form a cycloalkyl group (monocyclic or polycyclic).

Examples of the alkyl group which is represented by Xa₁ and may have a substituent include a methyl group and a group represented by —CH₂—R₁₁. R₁₁ represents a halogen atom (such as a fluorine atom), a hydroxyl group, or a monovalent organic group.

Xa₁ is preferably a hydrogen atom, a methyl group, a trifluoromethyl group, or a hydroxymethyl group.

Examples of the divalent linking group represented by T include an alkylene group, a —COO-Rt- group, a —O-Rt- group, and the like. In the formulae, Rt represents an alkylene group or a cycloalkylene group.

T is preferably a single bond or a —COO-Rt- group. Rt is preferably an alkylene group having 1 to 5 carbon atoms, and more preferably a —CH₂— group, a —(CH₂)₂— group, or a —(CH₂)₃— group.

The alkyl group represented by Ra₁ to Ra₃ preferably has 1 to 4 carbon atoms.

The cycloalkyl group represented by Ra₁ to Ra₃ is preferably a monocyclic cycloalkyl group such as a cyclopentyl group or a cyclohexyl group or a polycyclic cycloalkyl group such as a norbornyl group, a tetracyclodecanyl group, a tetracyclododecanyl group, or an adamantyl group.

The cycloalkyl group formed by the bonding of two groups out of Ra₁ to Ra₃ is preferably a monocyclic cycloalkyl group such as a cyclopentyl group or a cyclohexyl group or a polycyclic cycloalkyl group such as a norbornyl group, a tetracyclodecanyl group, a tetracyclododecanyl group, or an adamantyl group. The cycloalkyl group is more preferably a monocyclic cycloalkyl group having 5 or 6 carbon atoms.

In the cycloalkyl group formed by the bonding of two groups out of Ra₁ to Ra₃, for example, one methylene group constituting the ring may be substituted with a heteroatom such as an oxygen atom or a group having a heteroatom such as a carbonyl group.

As the repeating unit represented by Formula (AI), for example, an aspect is preferable in which Ra₁ is a methyl group or an ethyl group, and Ra₂ and Ra₃ are bonded to each other to form the aforementioned cycloalkyl group.

Each of the above groups may have a substituent. Examples of the substituent include an alkyl group (having 1 to 4 carbon atoms), a halogen atom, a hydroxyl group, an alkoxy group (having 1 to 4 carbon atoms), a carboxyl group, an alkoxycarbonyl group (having 2 to 6 carbon atoms), and the like. The number of carbon atoms in the substituent is preferably equal to or smaller than 8.

The total content of the repeating unit represented by Formula (AI) with respect to all the repeating units in the resin P is preferably 20 to 90 mol %, more preferably 25 to 85 mol %, and even more preferably 30 to 80 mol %.

Specific examples of the repeating unit represented by Formula (AI) will be shown below, but the present invention is not limited thereto.

In the specific examples, Rx and Xa₁ each independently represent a hydrogen atom, CH₃, CF₃, or CH₂OH. Rxa and Rxb each represent an alkyl group having 1 to 4 carbon atoms. Z represents a substituent containing a polar group. In a case where there is a plurality of Z's, Z's are independent from each other. p represents 0 or a positive integer. Examples of the substituent represented by Z containing a polar group include a hydroxyl group, a cyano group, an amino group, an alkylamide group, a sulfonamide group, and a linear or branched alkyl group or cycloalkyl group having these groups.

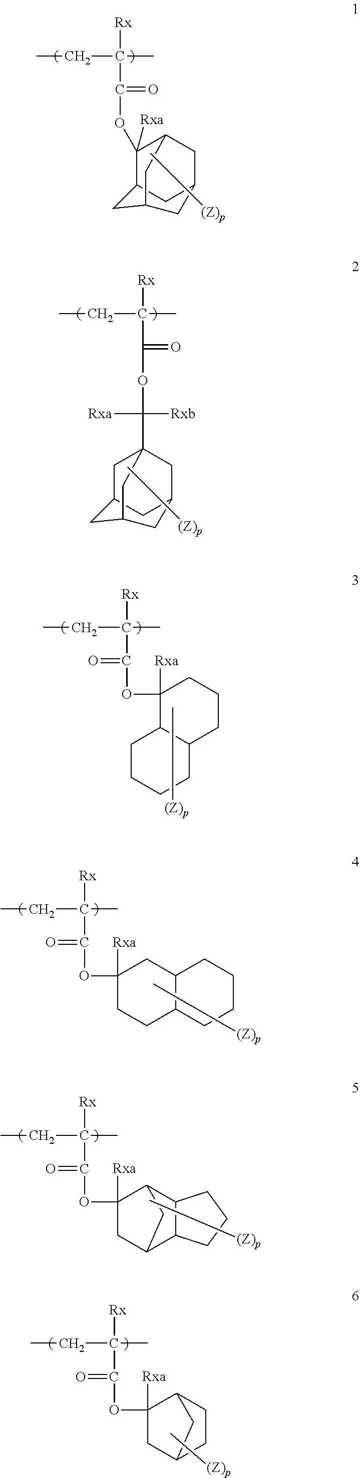

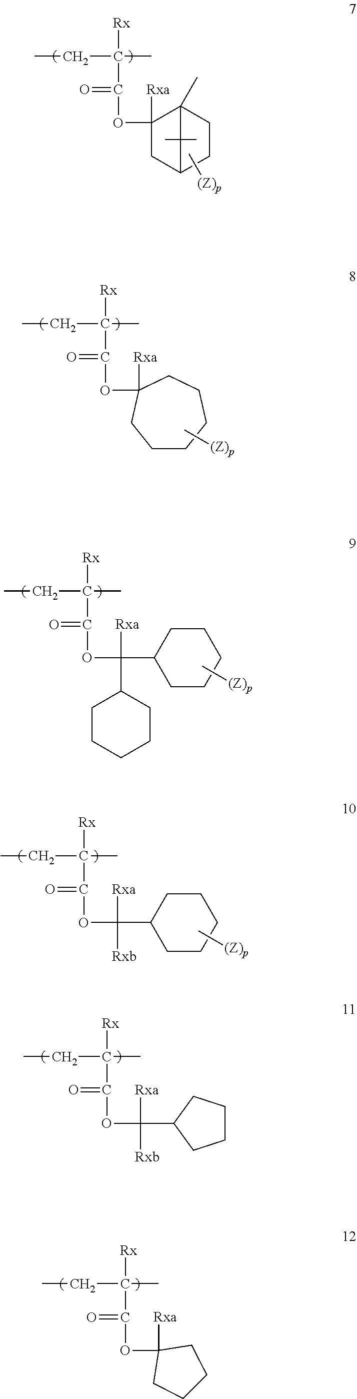

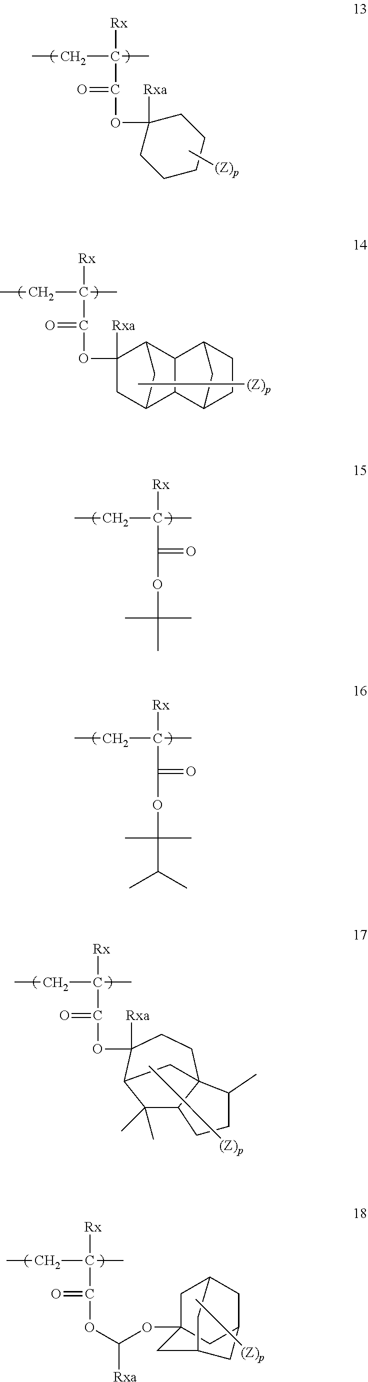

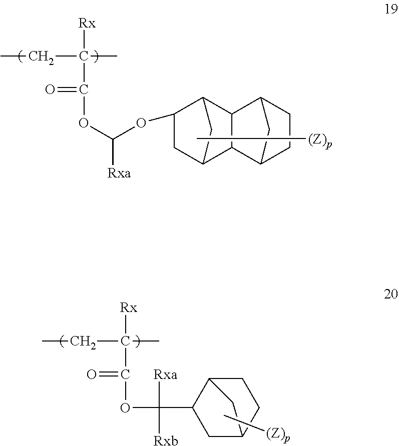

(Repeating Unit Having Lactone Structure)

It is preferable that the resin P contains a repeating unit Q having a lactone structure.

The repeating unit Q having a lactone structure preferably has a lactone structure on a side chain. For example, the repeating unit Q is more preferably a repeating unit derived from a (meth)acrylic acid derivative monomer.

One kind of repeating unit Q having a lactone structure may be used singly, or two or more kinds of repeating units Q may be used in combination. It is preferable to use one kind of repeating unit Q.

The content of the repeating unit Q having a lactone structure with respect to all the repeating units in the resin P is, for example, 3 to 80 mol %, and preferably 3 to 60 mol %.

The lactone structure is preferably a 5- to 7-membered lactone structure, and more preferably a structure in which another ring structure is fused with a 5- to 7-membered lactone structure by forming a bicyclo structure or a spiro structure.

It is preferable that the lactone structure has a repeating unit having a lactone structure represented by any of Formulae (LC1-1) to (LC1-17). As the lactone structure, a lactone structure represented by Formula (LC1-1), Formula (LC1-4), Formula (LC1-5), or Formula (LC1-8) is preferable, and a lactone structure represented by Formula (LC1-4) is more preferable.

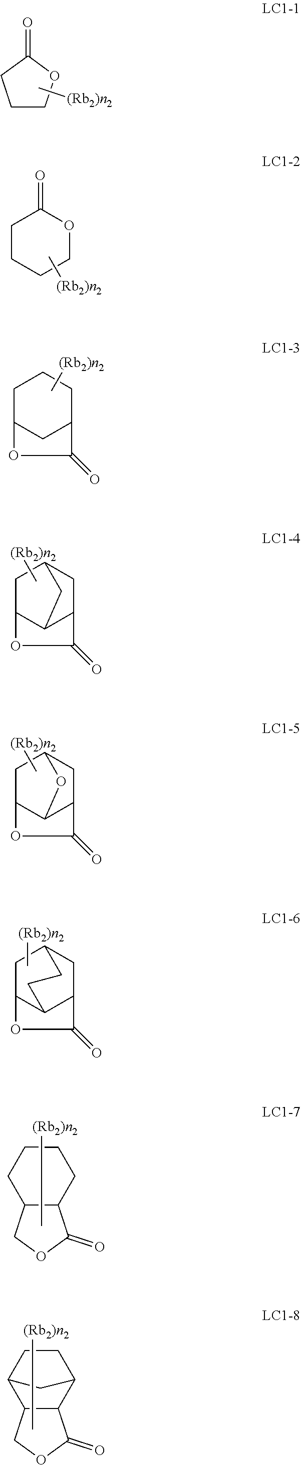

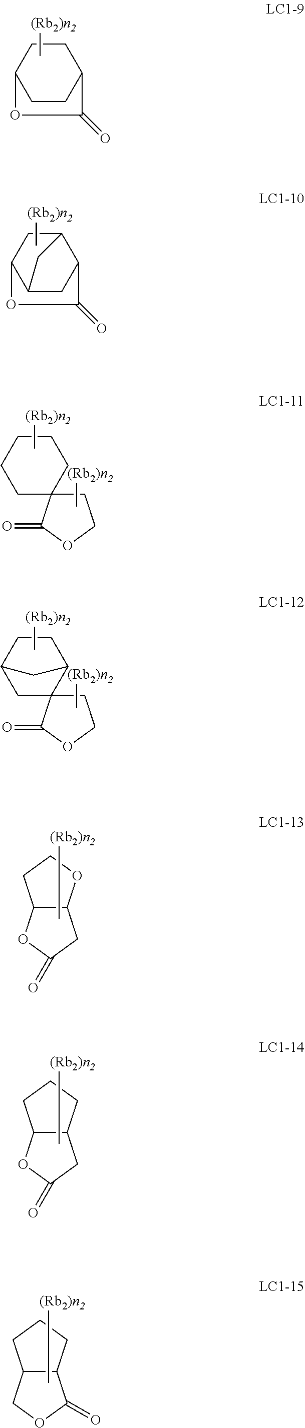

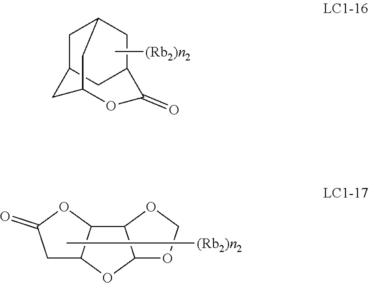

The lactone structure portion may have a substituent (Rb₂). As the substituent (Rb₂), for example, an alkyl group having 1 to 8 carbon atoms, a cycloalkyl group having 4 to 7 carbon atoms, an alkoxy group having 1 to 8 carbon atoms, an alkoxycarbonyl group having 2 to 8 carbon atoms, a carboxyl group, a halogen atom, a hydroxyl group, a cyano group, an acid-decomposable group, and the like are preferable. n₂ represents an integer of 0 to 4. In a case where n₂ is equal to or greater than 2, a plurality of substituents (Rb₂) may be the same as or different from each other, and a plurality of substituents (Rb₂) may be bonded to each other to form a ring.

The resin P is preferably a resin including a repeating unit selected from the group consisting of a repeating unit represented by Formula (a), a repeating unit represented by Formula (b), a repeating unit represented by Formula (c), a repeating unit represented by Formula (d), and a repeating unit represented by Formula (e) (hereinafter, this resin will be also called “resin represented by Formula (I)”).

The resin represented by Formula (I) is a resin whose solubility in a developer (chemical liquid which will be described later), which contains an organic solvent as a main component, is reduced by the action of an acid. The resin contains an acid-decomposable group. In the chemical liquid, the resin represented by Formula (I) is excellently dissolved. Therefore, the chemical liquid makes it easy to obtain a uniform resist film by using smaller amounts of the resist composition. Hereinafter, the resin represented by Formula (I) will be described.

Resin Represented by Formula (I)

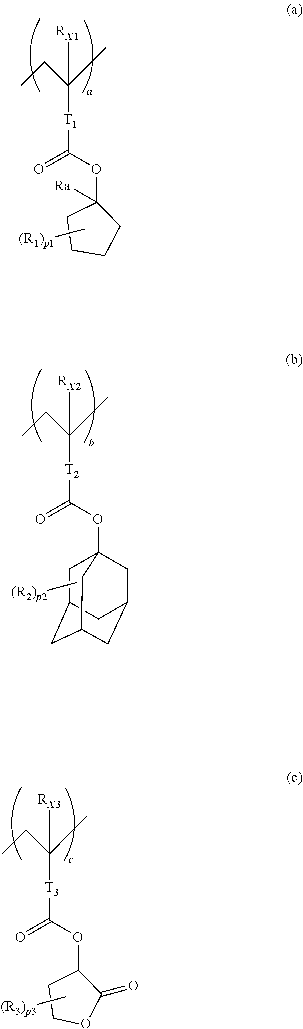

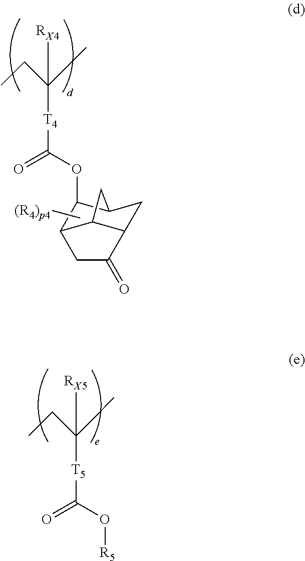

Formula (I) is constituted with a repeating unit (a) (repeating unit represented by Formula (a)), a repeating unit (b) (repeating unit represented by Formula (b)), a repeating unit (c) (repeating unit represented by Formula (c)), a repeating unit (d) (repeating unit represented by Formula (d)), and a repeating unit (e) (repeating unit represented by Formula (e)).

Rₓ₁ to Rₓ₅ each independently represent a hydrogen atom or an alkyl group which may have a substituent.

R₁ to R₄ each independently represent a monovalent substituent, and p₁ to p₄ each independently represent 0 or a positive integer.

Ra represents a linear or branched alkyl group.

T₁ to T₅ each independently represent a single bond or a divalent linking group.

R₅ represents a monovalent organic group.

a to e each represent mol %. a to e each independently represent a number included in a range of 0≤a≤100, 0≤b≤100, 0≤c<100, 0≤d<100, and 0≤e<100. Here, a+b+c+d+e=100, and a+b≠0.

In Formula (I), the repeating unit (e) has a structure different from all of the repeating units (a) to (d).

Examples of the alkyl group represented by Rₓ₁ to Rₓ₅ that may have a substituent include a methyl group and a group represented by —CH₂—R₁₁. R₁₁ represents a halogen atom (such as a fluorine atom), a hydroxyl group, or a monovalent organic group.

Rₓ₁ to Rₓ₅ preferably each independently represent a hydrogen atom, a methyl group, a trifluoromethyl group, or a hydroxymethyl group.

Examples of the divalent linking group represented by T₁ to T₅ in Formula (I) include an alkylene group, a —COO-Rt- group, a —O-Rt- group, and the like. In the formula, Rt represents an alkylene group or a cycloalkylene group.

T₁ to T₅ preferably each independently represent a single bond or a —COO-Rt- group. Rt is preferably an alkylene group having 1 to 5 carbon atoms, and more preferably a —CH₂— group, a —(CH₂)₂— group, or a —(CH₂)₃— group.

In Formula (I), Ra represents a linear or branched alkyl group. Examples thereof include a methyl group, an ethyl group, a t-butyl group, and the like. Among these, a linear or branched alkyl group having 1 to 4 carbon atoms is preferable.

In Formula (I), R₁ to R₄ each independently represent a monovalent substituent. R₁ to R₄ are not particularly limited, and examples thereof include a hydroxyl group, a cyano group, and a linear or branched alkyl or cycloalkyl group having a hydroxyl group, a cyano group, and the like.

In Formula (I), p₁ to p₄ each independently represent 0 or a positive integer. The upper limit of p₁ to p₄ equals the number of hydrogen atoms which can be substituted in each repeating unit.

In formula (I), R₅ represents a monovalent organic group. R₅ is not particularly limited, and examples thereof include a monovalent organic group having a sultone structure, a monovalent organic group having a cyclic ether such as tetrahydrofuran, dioxane, 1,4-thioxane, dioxolane, and 2,4,6-trioxabicyclo[3.3.0]octane, and an acid-decomposable group (for example, an adamantyl group quaternized by the substitution of carbon at a position bonded to a —COO group with an alkyl group).

The repeating unit (b) in Formula (I) is preferably formed of the monomer described in paragraphs “0014” to “0018” in JP2016-138219A.

In Formula (I), a to e each represent mol %. a to e each independently represent a number included in a range of 0≤a≤100, 0≤b≤100, 0≤c<100, 0≤d<100, and 0≤e<100. Here, a+b+c+d+e=100, and a+b≠0.

In Formula (I), a+b (the content of the repeating unit having an acid-decomposable group with respect to all the repeating units) is preferably 20 to 90 mol %, more preferably 25 to 85 mol %, and even more preferably 30 to 80 mol %.

Furthermore, in Formula (I), c+d (the content of the repeating unit having a lactone structure with respect to all the repeating units) is preferably 3 to 80 mol %, and more preferably 3 to 60 mol %.

One kind of each of the repeating unit (a) to repeating unit (e) may be used singly, or two or more kinds of each of the repeating unit (a) to repeating unit (e) may be used in combination. In a case where two or more kinds of repeating units are used in combination, the total content of each repeating unit is preferably within the above range.

The weight-average molecular weight (Mw) of the resin represented by Formula (I) is preferably 1,000 to 200,000 in general, more preferably 2,000 to 20,000, and even more preferably 3,000 to 15,000. The weight-average molecular weight is determined by Gel Permeation Chromatography (GPC) by using tetrahydrofuran (THF) as a developing solvent, and expressed in terms of polystyrene.

In the actinic ray-sensitive or radiation-sensitive resin composition, the content of the resin represented by Formula (I) based on the total solid content of the actinic ray-sensitive or radiation-sensitive resin composition is preferably 30% to 99% by mass in general, and more preferably 50% to 95% by mass.

(Repeating Unit Having Phenolic Hydroxyl Group)

The resin P may contain a repeating unit having a phenolic hydroxyl group.

Examples of the repeating unit having a phenolic hydroxyl group include a repeating unit represented by General Formula (I).

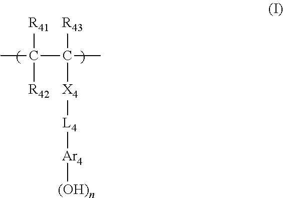

In the formula,

R₄₁, R₄₂, and R₄₃ each independently represent a hydrogen atom, an alkyl group, a halogen atom, a cyano group, or an alkoxycarbonyl group. Here, R₄₂ and Ar₄ may be bonded to each other to form a ring. In this case, R₄₂ represents a single bond or an alkylene group.

X₄ represents a single bond, —COO—, or —CONR₆₄—, and R₆₄ represents a hydrogen atom or an alkyl group.

L₄ represents a single bond or an alkylene group.

Ar₄ represents an (n+1)-valent aromatic ring group. In a case where Ar₄ is bonded to R₄₂ to form a ring, Ar₄ represents an (n+2)-valent aromatic ring group.

n represents an integer of 1 to 5.

The alkyl group represented by R₄₁, R₄₂, and R₄₃ in General Formula (I) is preferably an alkyl group having 20 or less carbon atoms such as a methyl group, an ethyl group, a propyl group, an isopropyl group, a n-butyl group, a sec-butyl group, a hexyl group, a 2-ethylhexyl group, an octyl group, or a dodecyl group which may have a substituent, more preferably an alkyl group having 8 or less carbon atoms, and even more preferably an alkyl group having 3 or less carbon atoms.

The cycloalkyl group represented by R₄₁, R₄₂, and R₄₃ in General Formula (I) may be monocyclic or polycyclic. The cycloalkyl group is preferably a monocyclic cycloalkyl group having 3 to 8 carbon atoms such as a cyclopropyl group, a cyclopentyl group, or a cyclohexyl group which may have a substituent.

Examples of the halogen atom represented by R₄₁, R₄₂, and R₄₃ in General Formula (I) include a fluorine atom, a chlorine atom, a bromine atom, and an iodine atom. Among these, a fluorine atom is preferable.

As the alkyl group contained in the alkoxycarbonyl group represented by R₄₁, R₄₂, and R₄₃ in General Formula (I), the same alkyl group as the alkyl group represented by R₄₁, R₄₂, and R₄₃ described above is preferable.

Examples of the substituent in each of the above groups include an alkyl group, a cycloalkyl group, an aryl group, an amino group, an amide group, a ureide group, a urethane group, a hydroxyl group, a carboxyl group, a halogen atom, an alkoxy group, a thioether group, an acyl group, an acyloxy group, an alkoxycarbonyl group, a cyano group, a nitro group, and the like. The number of carbon atoms in the substituent is preferably equal to or smaller than 8.

Ar₄ represents an (n+1)-valent aromatic ring group. Examples of a divalent aromatic ring group obtained in a case where n is 1 include an arylene group having 6 to 18 carbon atoms such as a phenylene group, a tolylene group, a naphthylene group, or an anthracenylene group which may have a substituent and an aromatic ring group containing a hetero ring such as thiophene, furan, pyrrole, benzothiophene, benzofuran, benzopyrrole, triazine, imidazole, benzimidazole, triazole, thiadiazole, or thiazole.

Specific examples of the (n+1)-valent aromatic ring group obtained in a case where n is an integer equal to or greater than 2 include groups obtained by removing (n−1) pieces of any hydrogen atoms from the specific examples of the divalent aromatic ring group described above.

The (n+1)-valent aromatic ring group may further have a substituent.

Examples of the substituent that the alkyl group, the cycloalkyl group, the alkoxycarbonyl group, the alkylene group, and the (n+1)-valent aromatic ring group described above can have include the alkyl group exemplified above as R₄₁, R₄₂, and R₄₃ in General Formula (I); an alkoxy group such as a methoxy group, an ethoxy group, a hydroxyethoxy group, a propoxy group, a hydroxypropoxy group, or a butoxy group; and an aryl group such as a phenyl group.

Examples of the alkyl group represented by R₆₄ in —CONR₆₄— (R₆₄ represents a hydrogen atom or an alkyl group) represented by X₄ include an alkyl group having 20 or less carbon atoms such as a methyl group, an ethyl group, a propyl group, an isopropyl group, a n-butyl group, a sec-butyl group, a hexyl group, a 2-ethylhexyl group, an octyl group, or a dodecyl group which may have a substituent. Among these, an alkyl group having 8 or less carbon atoms is more preferable.

X₄ is preferably a single bond, —COO—, or —CONH—, and more preferably a single bond or —COO—.

The alkylene group represented by L₄ is preferably an alkylene group having 1 to 8 carbon atoms such as a methylene group, an ethylene group, a propylene group, a butylene group, a hexylene group, or an octylene group which may have a substituent.

Ar₄ is preferably an aromatic ring group having 6 to 18 carbon atoms that may have a substituent, and more preferably a benzene ring group, a naphthalene ring group, or a biphenylene ring group.

It is preferable that the repeating unit represented by General Formula (I) comprises a hydroxystyrene structure. That is, Ar₄ is preferably a benzene ring group.

The repeating unit having a phenolic hydroxyl group is preferably a repeating unit represented by General Formula (p1).

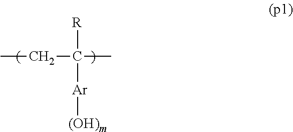

R in General Formula (p1) represents a hydrogen atom, a halogen atom, or a linear or branched alkyl group having 1 to 4 carbon atoms. A plurality of R's may be the same as or different from each other. As R in General Formula (p1), a hydrogen atom is preferable.

Ar in General Formula (p1) represents an aromatic ring, and examples thereof include an aromatic hydrocarbon ring having 6 to 18 carbon atoms that may have a substituent, such as a benzene ring, a naphthalene ring, an anthracene ring, a fluorene ring, or a phenanthrene ring, and an aromatic hetero ring containing a hetero ring such as a thiophene ring, a furan ring, a pyrrole ring, a benzothiophene ring, a benzofuran ring, a benzopyrrole ring, a triazine ring, an imidazole ring, a benzimidazole ring, a triazole ring, a thiadiazole ring, or a thiazole ring. Among these, a benzene ring is more preferable.

m in General Formula (p1) represents an integer of 1 to 5. m is preferably 1.

Specific examples of the repeating unit having a phenolic hydroxyl group will be shown below, but the present invention is not limited thereto. In the formulae, a represents 1 or 2.

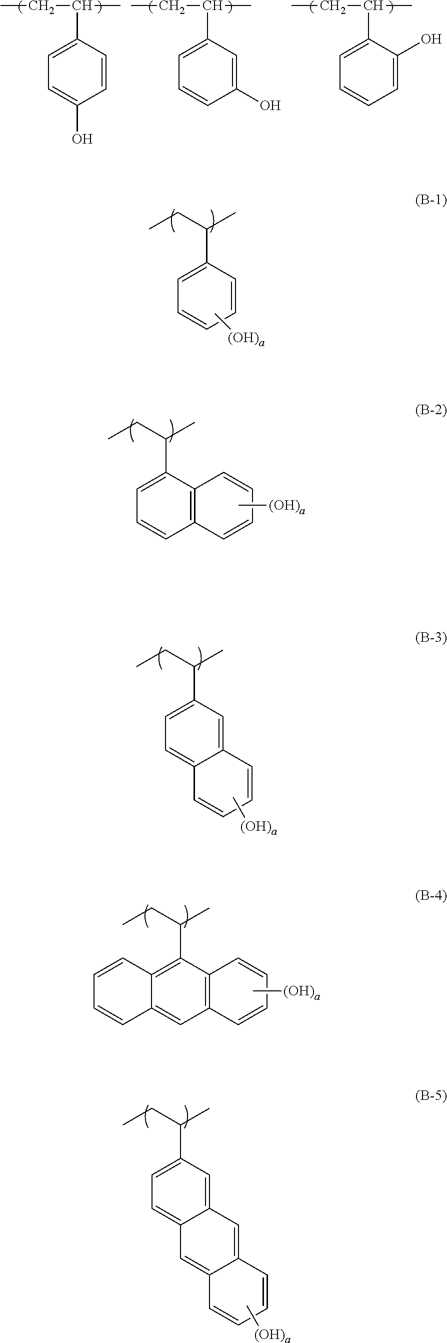

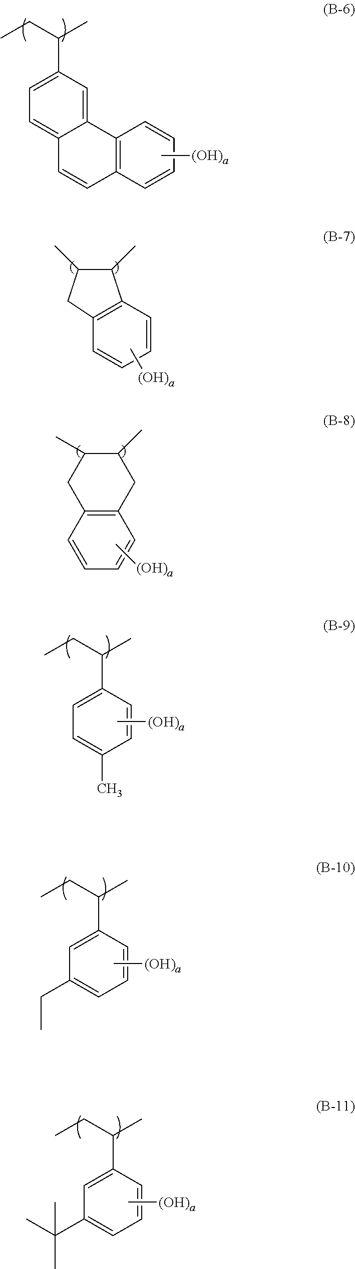

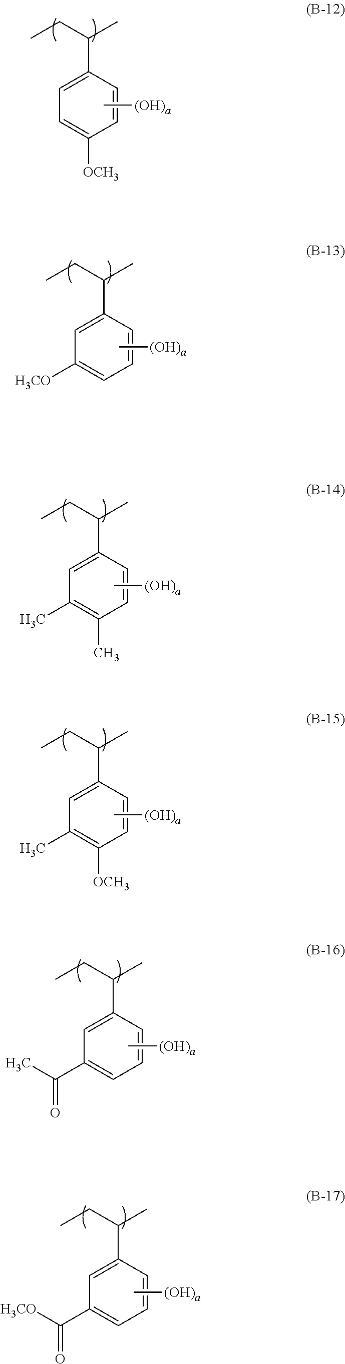

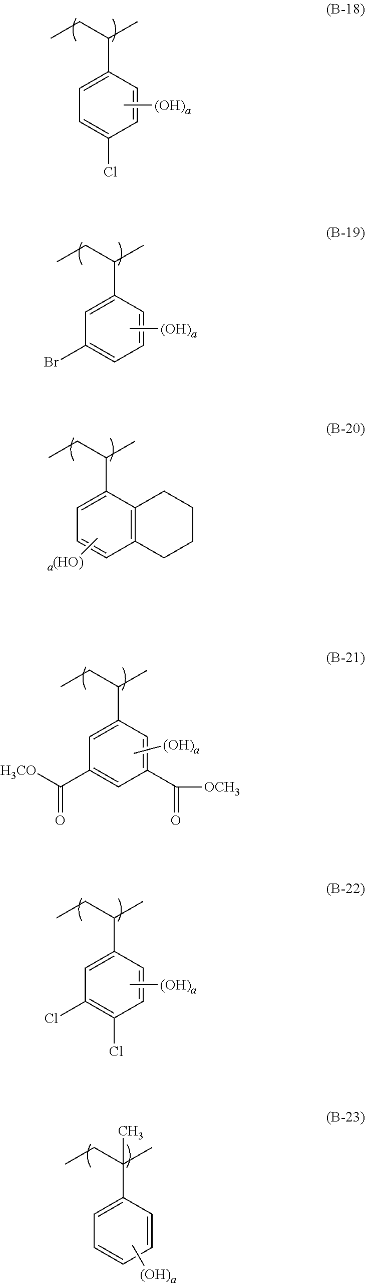

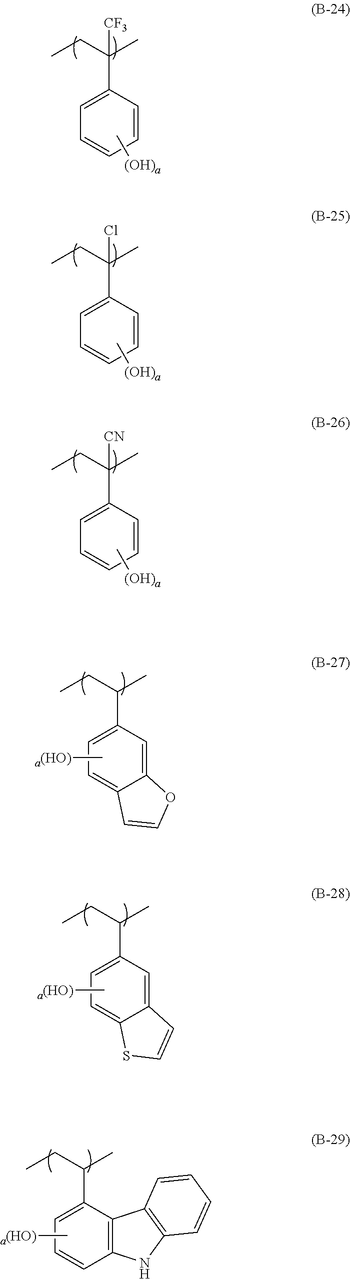

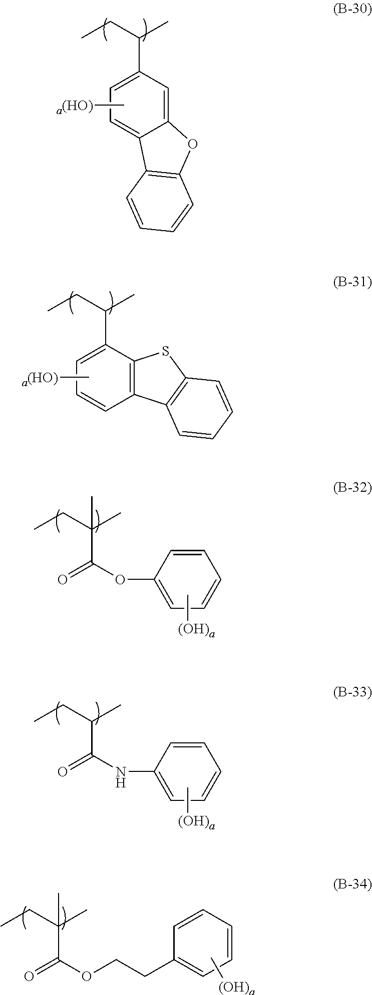

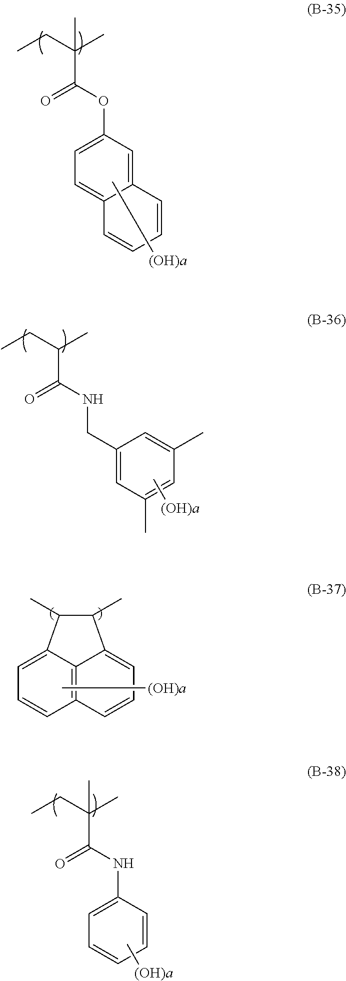

The content of the repeating unit having a phenolic hydroxyl group with respect to all the repeating units in the resin P is preferably 0 to 50 mol %, more preferably 0 to 45 mol %, and even more preferably 0 to 40 mol %.

(Repeating Unit Containing Organic Group Having Polar Group)

The resin P may further contain a repeating unit containing an organic group having a polar group, particularly, a repeating unit having an alicyclic hydrocarbon structure substituted with a polar group.

In a case where the resin P further contains such a repeating unit, the substrate adhesiveness and the affinity with a developer are improved. As the alicyclic hydrocarbon structure substituted with a polar group, an adamantyl group, a diamantyl group, or a norbornane group is preferable. As the polar group, a hydroxyl group or a cyano group is preferable.

Specific examples of the repeating unit having a polar group will be shown below, but the present invention is not limited thereto.

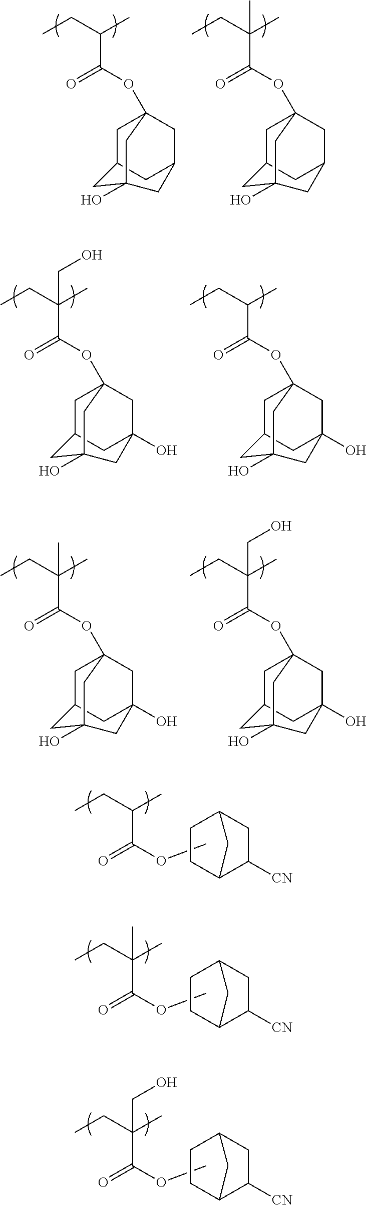

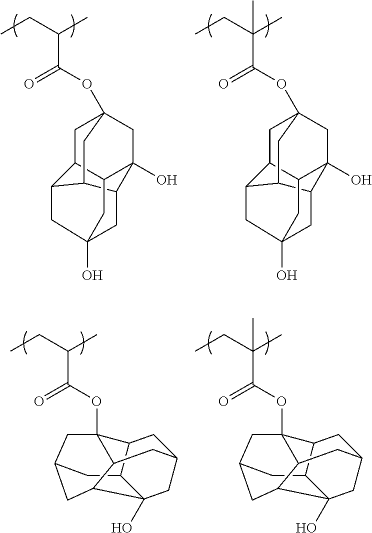

In a case where the resin P contains the repeating unit containing an organic group having a polar group, the content of the repeating unit with respect to all the repeating units in the resin P is preferably 1 to 50 mol %, more preferably 1 to 30 mol %, even more preferably 5 to 25 mol %, and particularly preferably 5 to 20 mol %.

(Repeating Unit Having Group (Photoacid Generating Group) Generating Acid by Irradiation with Actinic Rays or Radiation)

The resin P may contain a repeating unit having a group (photoacid generating group) generating an acid by the irradiation with actinic rays or radiation.

Examples of the repeating unit having a group (photoacid generating group) generating an acid by the irradiation with actinic rays or radiation include a repeating unit represented by Formula (4).

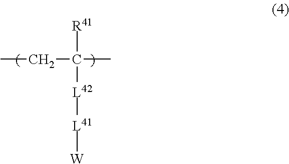

R⁴¹ represents a hydrogen atom or a methyl group. L⁴¹ represents a single bond or a divalent linking group. L⁴² represents a divalent linking group. W represents a structural moiety generating an acid on a side chain by being decomposed by the irradiation with actinic rays or radiation.

Specific examples of the repeating unit represented by Formula (4) will be shown below, but the present invention is not limited thereto.

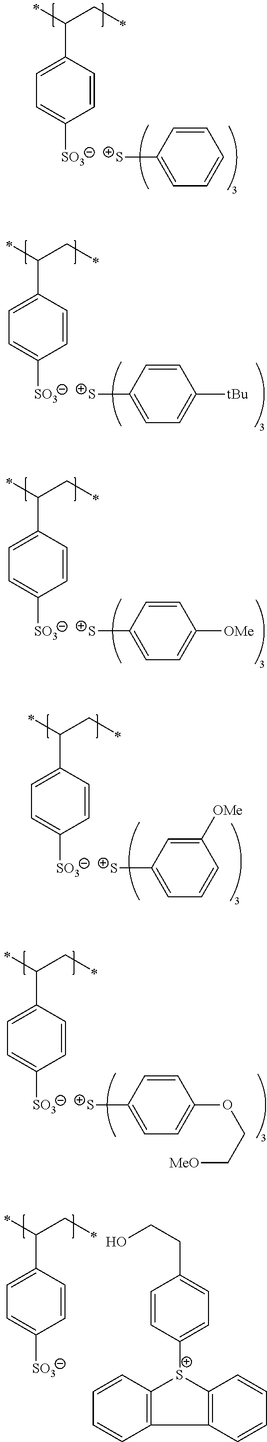

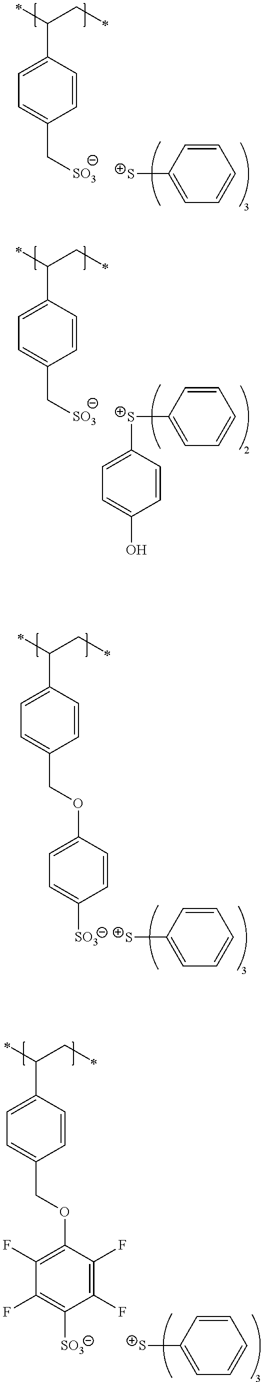

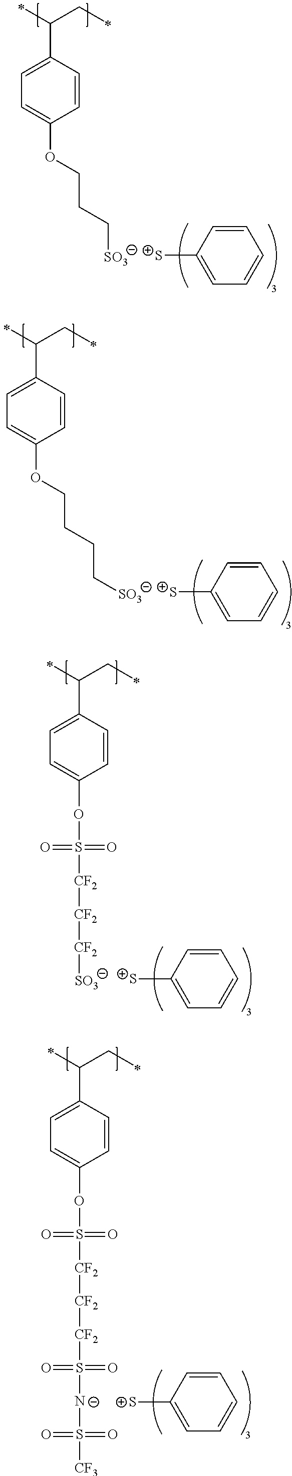

Examples of the repeating unit represented by Formula (4) also include the repeating units described in paragraphs “0094” to “0105” in JP2014-041327A.

In a case where the resin P contains the repeating unit having a photoacid generating group, the content of the repeating unit having a photoacid generating group with respect to all the repeating units in the resin P is preferably 1 to 40 mol %, more preferably 5 to 35 mol %, and even more preferably 5 to 30 mol %.

The resin P may contain a repeating unit represented by Formula (VI).

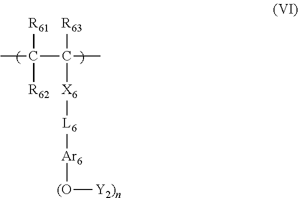

In Formula (VI),

R₆₁, R₆₂, and R₆₃ each independently represent a hydrogen atom, an alkyl group, a cycloalkyl group, a halogen atom, a cyano group, or an alkoxycarbonyl group. Here, R₆₂ may be bonded to Ar₆ to form a ring, and in this case, R₆₂ represents a single bond or an alkylene group.

X₆ represents a single bond, —COO—, or —CONR₆₄—. R₆₄ represents a hydrogen atom or an alkyl group.

L₆ represents a single bond or an alkylene group.

Ar₆ represents an (n+1)-valent aromatic ring group. In a case where Ar₆ is bonded to R₆₂ to form a ring, Ar₆ represents an (n+2)-valent aromatic ring group.

In a case where n≥2, Y₂ each independently represents a hydrogen atom or a group which is dissociated by the action of an acid. Here, at least one of Y₂'s represents a group which is dissociated by the action of an acid.

n represents an integer of 1 to 4.

As the group Y₂ which is dissociated by the action of an acid, a structure represented by Formula (VI-A) is preferable.

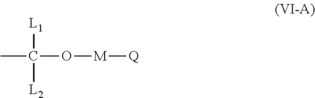

L₁ and L₂ each independently represent a hydrogen atom, an alkyl group, a cycloalkyl group, an aryl group, or a group obtained by combining an alkylene group and an aryl group.

M represents a single bond or a divalent linking group.

Q represents an alkyl group, a cycloalkyl group which may contain a heteroatom, an aryl group which may contain a heteroatom, an amino group, an ammonium group, a mercapto group, a cyano group, or an aldehyde group.

At least two out of Q, M, and L₁ may be bonded to each other to form a ring (preferably a 5- or 6-membered ring).

The repeating unit represented by Formula (VI) is preferably a repeating unit represented by Formula (3).

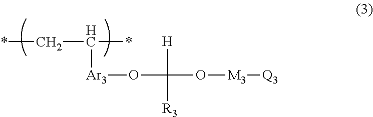

In Formula (3),

Ar₃ represents an aromatic ring group.

R₃ represents a hydrogen atom, an alkyl group, a cycloalkyl group, an aryl group, an aralkyl group, an alkoxy group, an acyl group, or a heterocyclic group.

M₃ represents a single bond or a divalent linking group.

Q₃ represents an alkyl group, a cycloalkyl group, an aryl group, or a heterocyclic group.

At least two out of Q₃, M₃, and R₃ may be bonded to each other to form a ring.

The aromatic ring group represented by Ar₃ is the same as Ar₆ in Formula (VI) in which n is 1. Ar₃ is more preferably a phenylene group or a naphthylene group, and even more preferably a phenylene group.

Specific examples of the repeating unit represented by Formula (VI) will be shown below, but the present invention is not limited thereto.

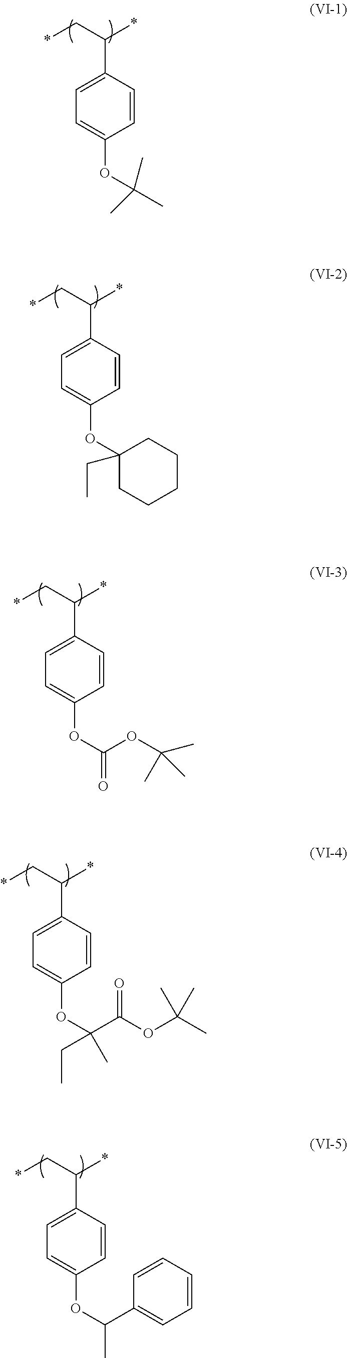

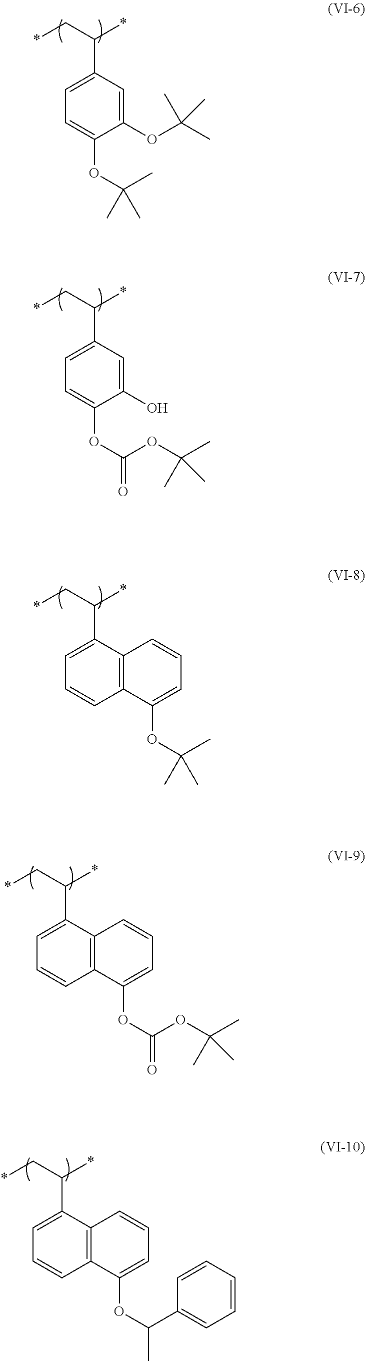

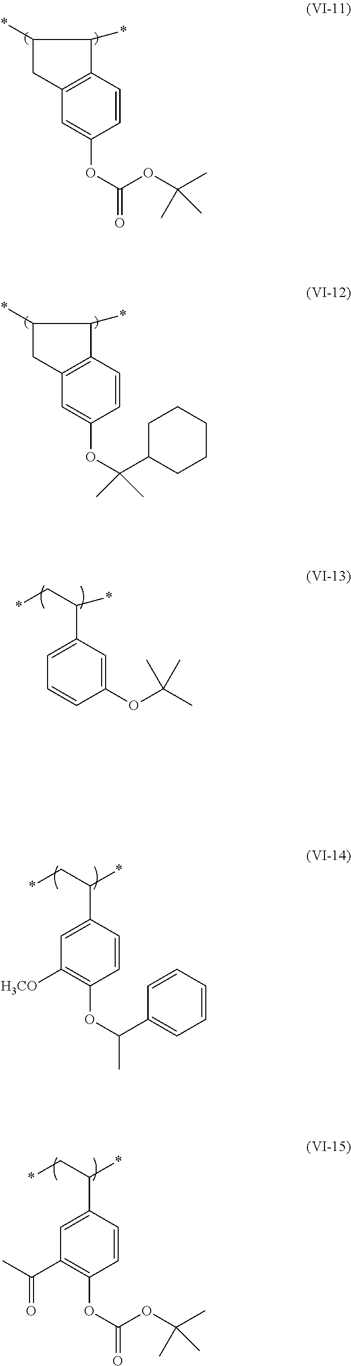

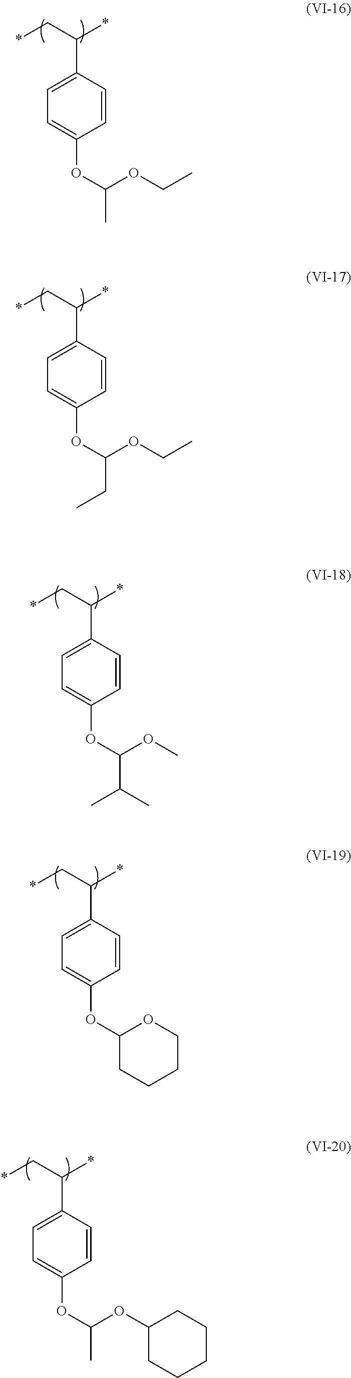

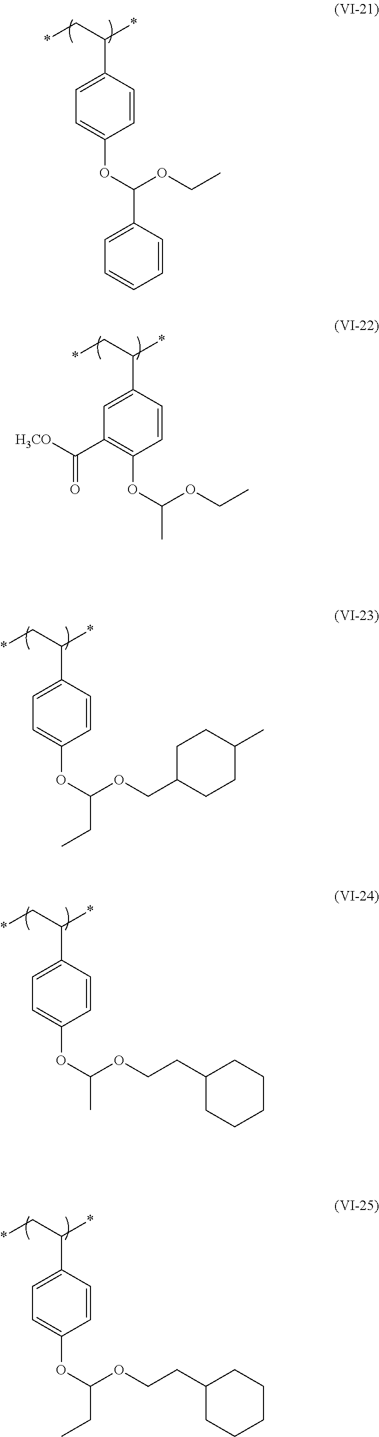

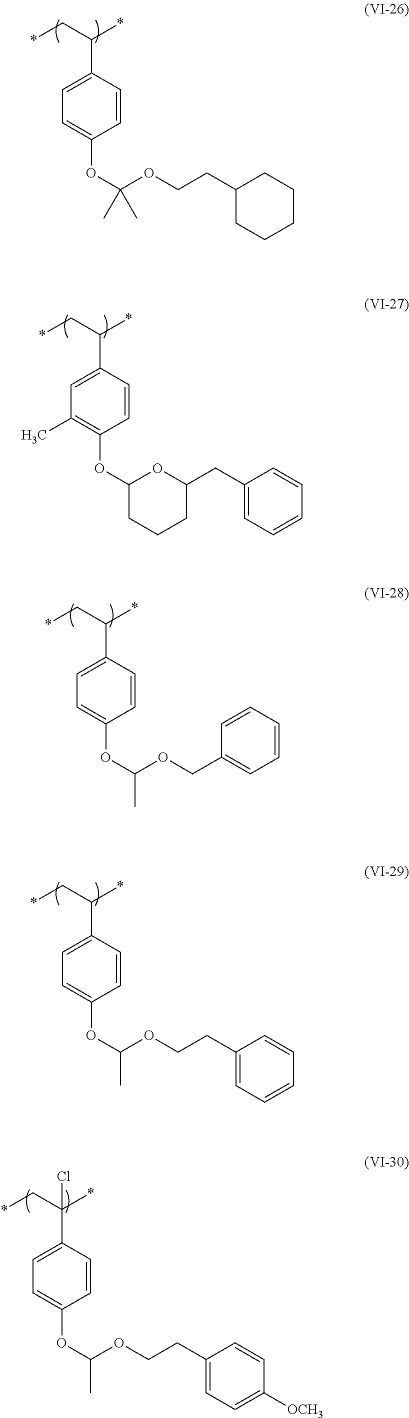

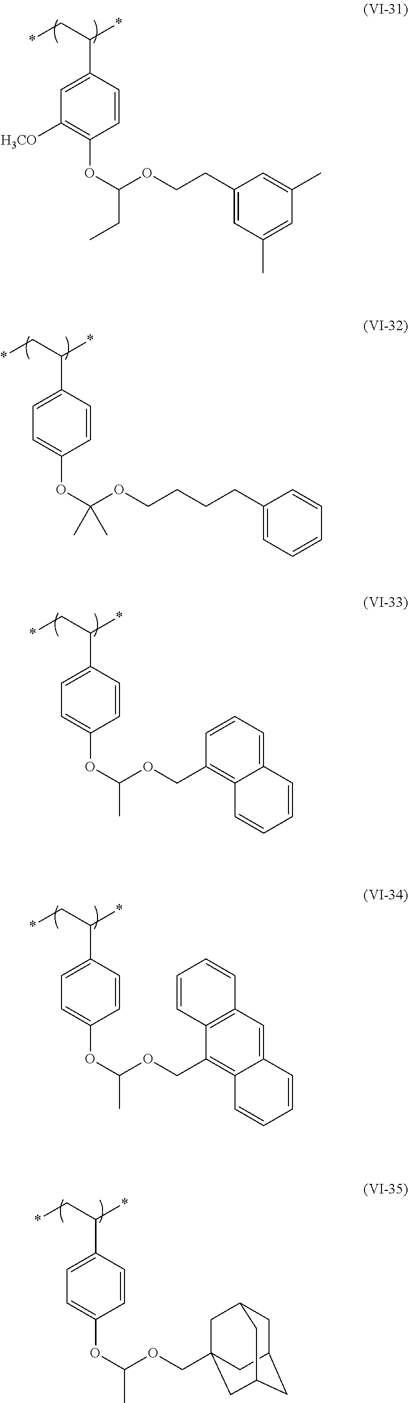

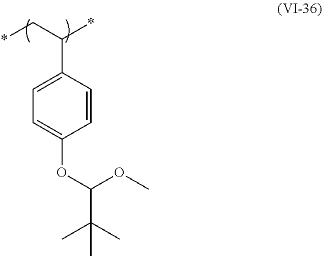

The resin P may contain a repeating unit represented by Formula (4).

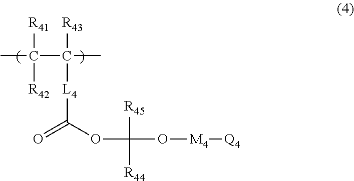

In Formula (4),

R₄₁, R₄₂, and R₄₃ each independently represent a hydrogen atom, an alkyl group, a cycloalkyl group, a halogen atom, a cyano group, or an alkoxycarbonyl group. R₄₂ and L₄ may be bonded to each other to form a ring, and in this case, R₄₂ represents an alkylene group.

L₄ represents a single bond or a divalent linking group. In a case where L₄ is bonded to R₄₂ to form a ring, L₄ represents a trivalent linking group.

R₄₄ and R₄₅ each represent a hydrogen atom, an alkyl group, a cycloalkyl group, an aryl group, an aralkyl group, an alkoxy group, an acyl group, or a heterocyclic group.

M₄ represents a single bond or a divalent linking group.

Q₄ represents an alkyl group, a cycloalkyl group, an aryl group, or a heterocyclic group.

At least two out of Q₄, M₄, and R₄₄ may be bonded to each other to form a ring.

R₄₁, R₄₂, and R₄₃ have the same definition as R₄₁, R₄₂, and R₄₃ in Formula (IA), and the preferable range thereof is also the same.

L₄ has the same definition as T in Formula (AI), and the preferable range thereof is also the same.

R₄₄ and R₄₅ have the same definition as R₃ in Formula (3), and the preferable range thereof is also the same.

M₄ has the same definition as M₃ in Formula (3), and the preferable range thereof is also the same.

Q₄ has the same definition as Q₃ in Formula (3), and the preferable range thereof is also the same.

Examples of the ring formed by the bonding of at least two out of Q₄, M₄, and R₄₄ include a ring formed by the bonding of at least two out of Q₃, M₃, and R₃, and the preferable range thereof is also the same.

Specific examples of the repeating unit represented by Formula (4) will be shown below, but the present invention is not limited thereto.

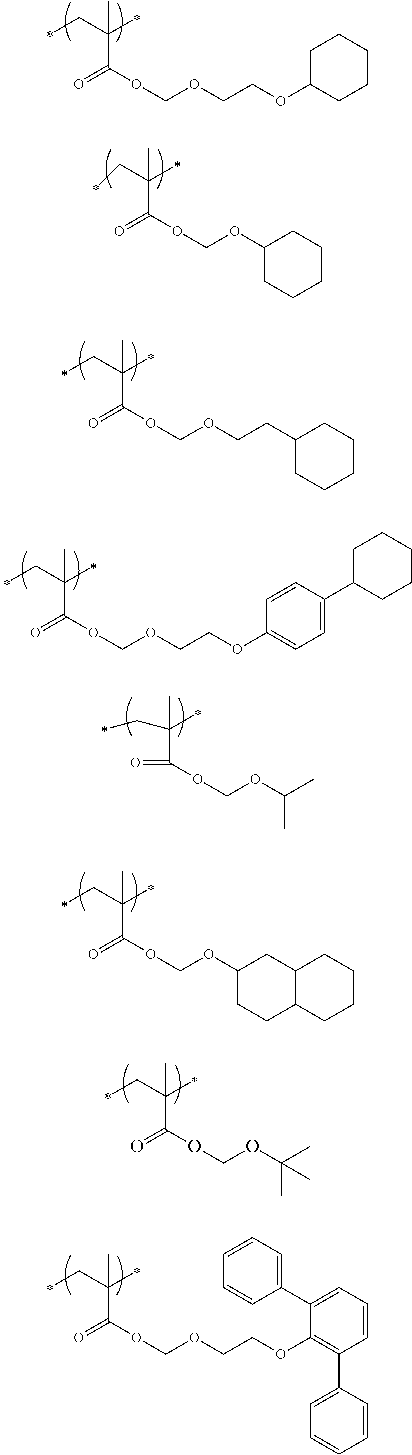

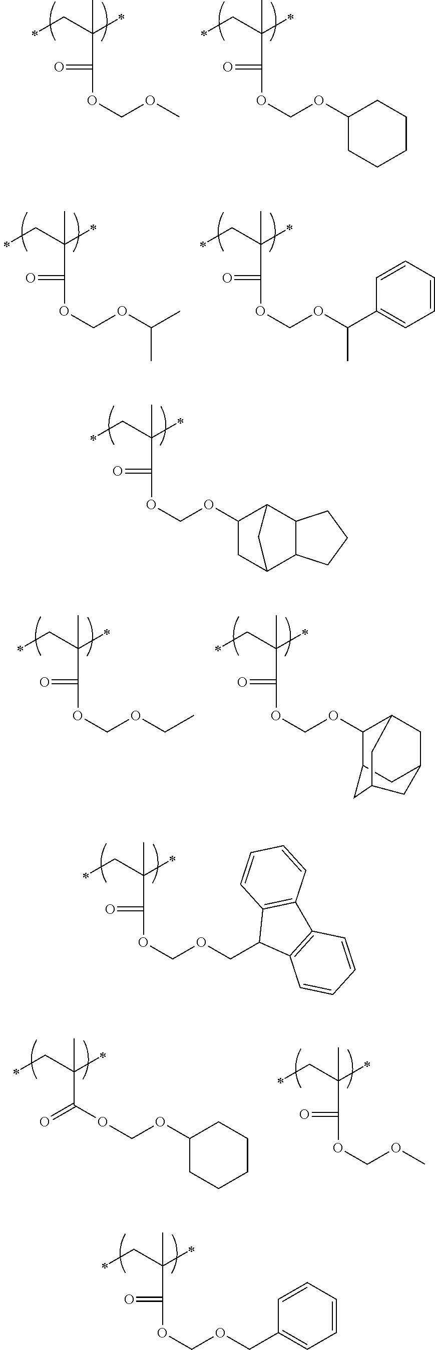

The resin P may contain a repeating unit represented by Formula (BZ).

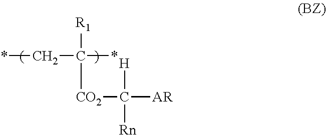

In Formula (BZ), AR represents an aryl group. Rn represents an alkyl group, a cycloalkyl group, or an aryl group. Rn and AR may be bonded to each other to form a nonaromatic ring.

R₁ represents a hydrogen atom, an alkyl group, a cycloalkyl group, a halogen atom, a cyano group, or an alkyloxycarbonyl group.

Specific examples of the repeating unit represented by Formula (BZ) will be shown below, but the present invention is not limited thereto.

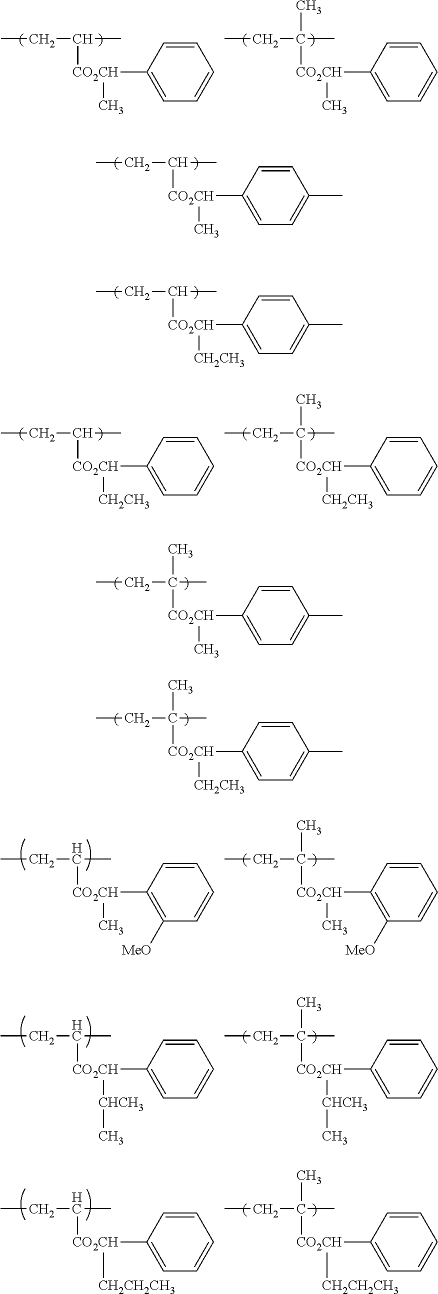

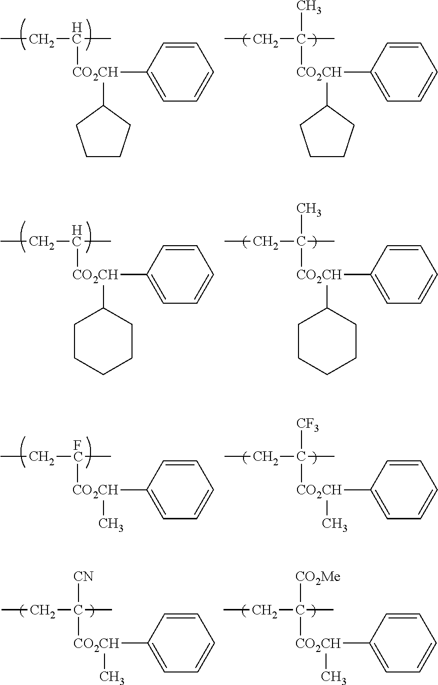

In the resin P, the content of the repeating unit having an acid-decomposable group (total content in a case where the resin P contains a plurality of kinds of the repeating units) with respect to all the repeating units in the resin P is preferably 5 to 80 mol %, more preferably 5 to 75 mol %, and even more preferably 10 to 65 mol %.

The resin P may contain a repeating unit represented by Formula (V) or Formula (VI).

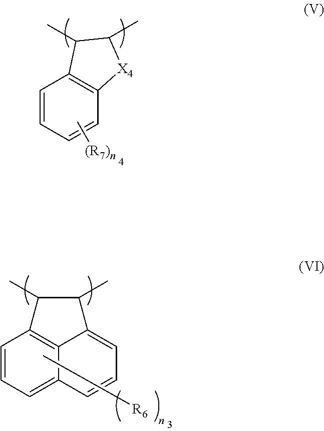

In the formula,

R₆ and R₇ each independently represent a hydrogen atom, a hydroxy group, a linear, branched, and cyclic alkyl group having 1 to 10 carbon atoms, an alkoxy group, an acyloxy group, a cyano group, a nitro group, an amino group, a halogen atom, an ester group (—OCOR or —COOR: R represents an alkyl group having 1 to 6 carbon atoms or a fluorinated alkyl group), or a carboxyl group.

n₃ represents an integer of 0 to 6.

n₄ represents an integer of 0 to 4.

X₄ represents a methylene group, an oxygen atom, or a sulfur atom.

Specific examples of the repeating unit represented by Formula (V) or Formula (VI) will be shown below, but the present invention is not limited thereto.

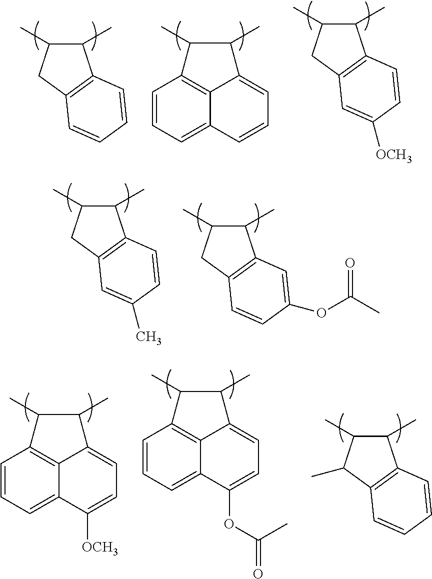

The resin P may further contain a repeating unit having a silicon atom on a side chain. Examples of the repeating unit having a silicon atom on a side chain include a (meth)acrylate-based repeating unit having a silicon atom, a vinyl-based repeating unit having a silicon atom, and the like. Typically, the repeating unit having a silicon atom on a side chain is a repeating unit having a silicon atom-containing group on a side chain. Examples of the silicon atom-containing group include a trimethylsilyl group, a triethylsilyl group, a triphenylsilyl group, a tricyclohexylsilyl group, a tristrimethylsiloxysilyl group, a tristrimethylsilyl silyl group, a methyl bistrimethylsilyl silyl group, a methyl bistrimethylsiloxysilyl group, a dimethyltrimethylsilyl silyl group, a dimethyl trimethylsiloxysilyl group, cyclic or linear polysiloxane shown below, a cage-like, ladder-like, or random silsesquioxane structure, and the like. In the formulae, R and R¹ each independently represent a monovalent substituent. * represents a bond.

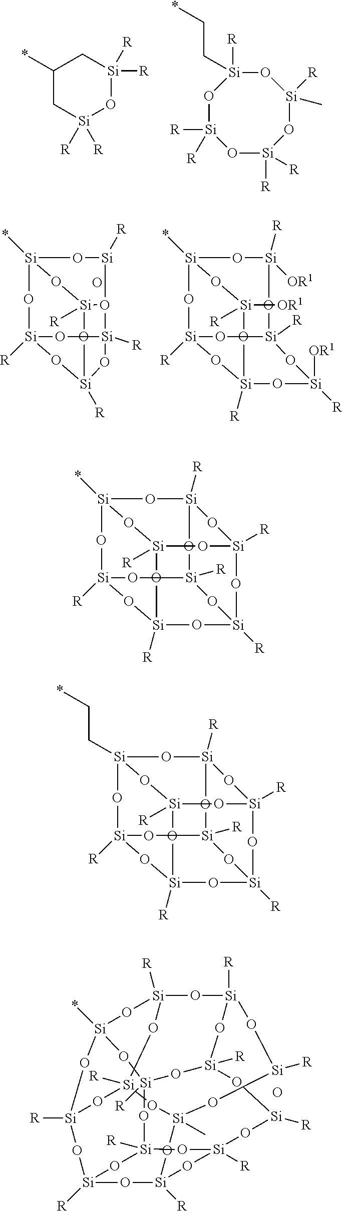

As the repeating unit having the aforementioned group, for example, a repeating unit derived from an acrylate or methacrylate compound having the aforementioned group or a repeating unit derived from a compound having the aforementioned group and a vinyl group is preferable.

It is preferable that the repeating unit having a silicon atom is preferably a repeating unit having a silsesquioxane structure. In a case where the repeating unit has a silsesquioxane structure, in forming an ultrafine pattern (for example, a line width equal to or smaller than 50 nm) having a cross-sectional shape with a high aspect ratio (for example, film thickness/line width is equal to or higher than 3), an extremely excellent collapse performance can be demonstrated.

Examples of the silsesquioxane structure include a cage-like silsesquioxane structure, a ladder-like silsesquioxane structure, and a random silsesquioxane structure. Among these, a cage-like silsesquioxane structure is preferable.

The cage-like silsesquioxane structure is a silsesquioxane structure having a cage-like skeleton. The cage-like silsesquioxane structure may be a complete cage-like silsesquioxane structure or an incomplete cage-like silsesquioxane structure, but is preferably a complete cage-like silsesquioxane structure.

The ladder-like silsesquioxane structure is a silsesquioxane structure having a ladder-like skeleton.

The random silsesquioxane structure is a silsesquioxane structure having a random skeleton.

The cage-like silsesquioxane structure is preferably a siloxane structure represented by Formula (S).

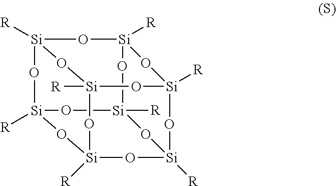

In Formula (S), R represents a monovalent organic group. A plurality of R's may be the same as or different from each other.

The organic group is not particularly limited, and specific examples thereof include a hydroxy group, a nitro group, a carboxyl group, an alkoxy group, an amino group, a mercapto group, a blocked mercapto group (for example, a mercapto group blocked (protected) by an acyl group), an acyl group, an imide group, a phosphino group, a phosphinyl group, a silyl group, a vinyl group, a hydrocarbon group which may have a heteroatom, a (meth)acryl group-containing group, an epoxy group-containing group, and the like.

Examples of the heteroatom in the hydrocarbon group which may have a heteroatom include an oxygen atom, a nitrogen atom, a sulfur atom, a phosphorus atom, and the like.

Examples of the hydrocarbon group which may have a heteroatom include an aliphatic hydrocarbon group, an aromatic hydrocarbon group, a group obtained by combining these, and the like.

The aliphatic hydrocarbon group may be any of a linear, branched, or cyclic aliphatic hydrocarbon group. Specific examples of the aliphatic hydrocarbon group include a linear or branched alkyl group (particularly having 1 to 30 carbon atoms), a linear or branched alkenyl group (particularly having 2 to 30 carbon atoms), a linear or branched alkynyl group (particularly having 2 to 30 carbon atoms), and the like.

Examples of the aromatic hydrocarbon group include an aromatic hydrocarbon group having 6 to 18 carbon atoms such as a phenyl group, a tolyl group, a xylyl group, or a naphthyl group.

In a case where the resin P has the repeating unit having a silicon atom on a side chain, the content of the repeating unit with respect to all the repeating units in the resin P is preferably 1 to 30 mol %, more preferably 5 to 25 mol %, and even more preferably 5 to 20 mol %.

The weight-average molecular weight of the resin P that is measured by gel permeation chromatography (GPC) and expressed in terms of polystyrene is preferably 1,000 to 200,000, more preferably 3,000 to 20,000, and even more preferably 5,000 to 15,000. In a case where the weight-average molecular weight is 1,000 to 200,000, it is possible to prevent the deterioration of heat resistance and dry etching resistance, to prevent the deterioration of developability, and to prevent film forming properties from deteriorating due to the increase in viscosity.

The dispersity (molecular weight distribution) is generally 1 to 5, preferably 1 to 3, more preferably 1.2 to 3.0, and even more preferably 1.2 to 2.0.

In the actinic ray-sensitive or radiation-sensitive composition, the content of the resin P in the total solid content is preferably 50% to 99.9% by mass, and more preferably 60% to 99.0% by mass.

In the actinic ray-sensitive or radiation-sensitive composition, one kind of resin P may be used, or two or more kinds of resins P may be used in combination.

(Photoacid Generator)

It is preferable that the actinic ray-sensitive or radiation-sensitive resin composition contains a photoacid generator. As the photoacid generator, known photoacid generators can be used without particular limitation.

The content of the photoacid generator in the actinic ray-sensitive or radiation-sensitive resin composition is not particularly limited. However, generally, the content of the photoacid generator with respect to the total solid content of the actinic ray-sensitive or radiation-sensitive resin composition is preferably 0.1% to 20% by mass, and more preferably 0.5% to 20% by mass. One kind of photoacid generator may be used singly, or two or more kinds of photoacid generators may be used in combination. In a case where two or more kinds of photoacid generators are used in combination, the total content thereof is preferably within the above range.

Examples of the photoacid generator include the compounds described in JP2016-057614A, JP2014-219664A, JP2016-138219A, and JP2015-135379A.

(Quencher)

The actinic ray-sensitive or radiation-sensitive resin composition may contain a quencher. As the quencher, known quenchers can be used without particular limitation.

The quencher is a basic compound and has a function of inhibiting the acid-decomposable resin from being unintentionally decomposed in an unexposed area by the acid spread from an exposed area.

The content of the quencher in the actinic ray-sensitive or radiation-sensitive resin composition is not particularly limited. However, generally, the content of the quencher with respect to the total solid content of the actinic ray-sensitive or radiation-sensitive resin composition is preferably 0.1% to 15% by mass, and more preferably 0.5% to 8% by mass. One kind of quencher may be used singly, or two or more kinds of quenchers may be used in combination. In a case where two or more kinds of quenchers are used in combination, the total content thereof is preferably within the above range.

Examples of the quencher include the compounds described in JP2016-057614A, JP2014-219664A, JP2016-138219A, and JP2015-135379A.

(Hydrophobic Resin)

The actinic ray-sensitive or radiation-sensitive resin composition may contain a hydrophobic resin.

It is preferable to design the hydrophobic resin such that the resin is localized within the surface of a resist film. However, unlike a surfactant, the hydrophobic resin does not need to have a hydrophilic group in a molecule and may not make a contribution to the homogeneous mixing of a polar substance with a nonpolar substance.

The addition of the hydrophobic resin brings about effects such as the control of static and dynamic contact angle formed between water and the resist film surface and the inhibition of outgas.

From the viewpoint of localization within the surface layer of a film, the hydrophobic resin preferably has any one or more kinds of groups among “fluorine atom”, “silicon atom”, and “CH₃ partial structure included in a side chain portion of the resin”, and more preferably has two or more kinds of groups among the above. Furthermore, it is preferable that the hydrophobic resin has a hydrocarbon group having 5 or more carbon atoms. These groups may be positioned in the main chain of the resin or may substitute a side chain of the resin.

In a case where the hydrophobic resin contains a fluorine atom and/or a silicon atom, the fluorine atom and/or the silicon atom in the hydrophobic resin may be contained in the main chain or the side chain of the resin.

In a case where the hydrophobic resin contains a fluorine atom, as a partial structure having the fluorine atom, a fluorine atom-containing alkyl group, a fluorine atom-containing cycloalkyl group, or a fluorine atom-containing aryl group is preferable.

The fluorine atom-containing alkyl group (preferably having 1 to 10 carbon atoms and more preferably having 1 to 4 carbon atoms) is a linear or branched alkyl group in which at least one hydrogen atom is substituted with a fluorine atom and which may further have a substituent other than a fluorine atom.

The fluorine atom-containing cycloalkyl group is a monocyclic or polycyclic cycloalkyl group in which at least one hydrogen atom is substituted with a fluorine atom and which may further have a substituent other than a fluorine atom.

Examples of the fluorine atom-containing aryl group include an aryl group in which at least one hydrogen atom is substituted with a fluorine atom, such as a phenyl group or a naphthyl group. The fluorine atom-containing aryl group may further have a substituent other than a fluorine atom.

Examples of the repeating unit having a fluorine atom or a silicon atom include the repeating units exemplified in paragraph “0519” in US2012/0251948A1.

As described above, it is also preferable that the hydrophobic resin contains a CH₃ partial structure in a side chain portion.

Herein, the CH₃ partial structure that the side chain portion of the hydrophobic resin has includes a CH₃ partial structure that an ethyl group, a propyl group, or the like has.

A methyl group directly bonded to the main chain of the hydrophobic resin (for example, an α-methyl group of a repeating unit having a methacrylic acid structure) makes a small contribution to the surface localization of the hydrophobic resin due to the influence of the main chain. Accordingly, such a methyl group is not included in the CH₃ partial structure in the present invention.

Regarding the hydrophobic resin, the description in paragraphs “0348” to “0415” in JP2014-010245A can be referred to, and the entire contents thereof are incorporated into the present specification.

As the hydrophobic resin, in addition to the above resins, the resins described in JP2011-248019A, JP2010-175859A, and JP2012-032544A can also be preferably used.

As the hydrophobic resin, for example, resins represented by Formula (1b) to Formula (5b) are preferable.

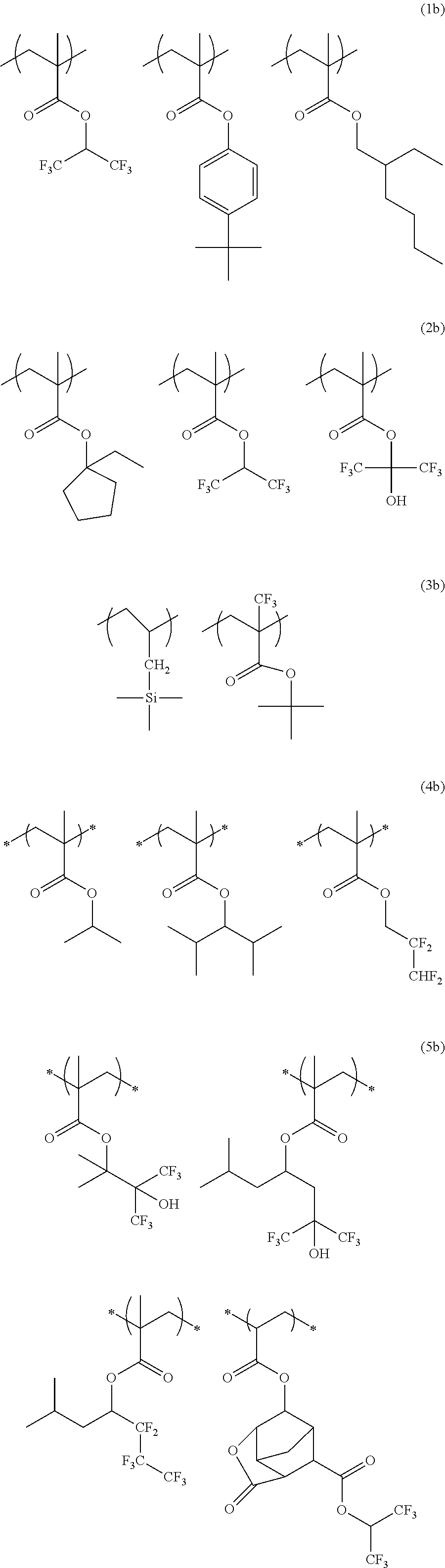

In a case where the resist composition contains the hydrophobic resin, the content of the hydrophobic resin with respect to the total solid content of the composition is preferably 0.01% to 20% by mass, and more preferably 0.1% to 15% by mass.

(Solvent)

The actinic ray-sensitive or radiation-sensitive resin composition may contain a solvent. As the solvent, known solvents can be used without particular limitation.

The solvent to be incorporated into the actinic ray-sensitive or radiation-sensitive resin composition may be the same as or different from the organic solvent to be incorporated into the mixture in the chemical liquid described above.

The content of the solvent in the actinic ray-sensitive or radiation-sensitive resin composition is not particularly limited. However, generally, it is preferable that the solvent is incorporated into the composition such that the total solid content of the actinic ray-sensitive or radiation-sensitive resin composition is adjusted to 0.1% to 20% by mass. One kind of solvent may be used singly, or two or more kinds of solvents may be used in combination. In a case where two or more kinds of solvents are used in combination, the total content thereof is preferably within the above range.

Examples of the solvent include the solvents described in JP2016-057614A, JP2014-219664A, JP2016-138219A, and JP2015-135379A.

(Other Additives)

If necessary, the actinic ray-sensitive or radiation-sensitive resin composition may additionally contain a surfactant, an acid proliferation agent, a dye, a plasticizer, a photosensitizer, a light absorber, an alkali-soluble resin other than the above resins, and/or a dissolution inhibitor.

(Exposure Step)

The exposure step is a step of exposing the resist film. As the method of exposing the resist film, known methods can be used without particular limitation.

Examples of the method of exposing the resist film include a method of irradiating the resist film with actinic rays or radiation through a predetermined mask. In a case where the method of irradiating the resist film with electron beams is used, the resist film may be irradiated without the intervention of a mask (this is also called “direct imaging” in some cases)

The actinic rays or the radiation used for exposure is not particularly limited, and examples thereof include a KrF excimer laser, an ArF excimer laser, extreme ultraviolet (EUV), electron beam (EB), and the like. Among these, extreme ultraviolet or electron beam is preferable. The exposure may be immersion exposure.

<Post Exposure Bake (PEB) Step>

It is preferable that the aforementioned pattern forming method additionally includes a Post Exposure Bake (PEB) step of baking the resist film obtained after exposure before the exposure step and the development step. By the baking, the reaction in the exposed portion is accelerated, and either or both of sensitivity and pattern shape are further improved.

The heating temperature is preferably 80° C. to 150° C., more preferably 80° C. to 140° C., and even more preferably 80° C. to 130° C.

The heating time is preferably 30 to 1,000 seconds, more preferably 60 to 800 seconds, and even more preferably 60 to 600 seconds.

The heating can be performed by means comprising a general exposure/development machine, or may be performed using a hot plate or the like.

[Development Step]

The development step is a step of developing the exposed resist film (hereinafter, also called “resist film obtained after exposure”) by using a developer. In the present embodiment, the chemical liquid X is used as a developer.

As the development method, known development methods can be used without particular limitation. Examples of the development method include a dipping method, a puddle method, a spray method, a dynamic dispense method, and the like.

Furthermore, the aforementioned pattern forming method may additionally include a step of substituting the developer with another solvent so as to stop the development after the development step.

The development time is not particularly limited, but is preferably 10 to 300 seconds in general and more preferably 10 to 120 seconds. The temperature of the developer is preferably 0° C. to 50° C., and more preferably 15° C. to 35° C. In the pattern forming method, the development step may be performed at least once or multiple times.

In the development step, both the development using the chemical liquid X and development using an alkaline developer may be performed (so-called double development may be performed).

[Rinsing Step]

The rinsing step is a step of washing the wafer, which comprises the resist film obtained after development, by using a rinsing solution. In the present embodiment, the chemical liquid Y is used as a rinsing solution.

As the washing method, known washing methods can be used without particular limitation. Examples of the washing method include a rotation jetting method, a dipping method, a spray method, and the like.

Among these, it is preferable to use the rotation jetting method in which the wafer is washed and then rotated at a rotation speed of 2,000 to 4,000 rpm such that the rinsing solution is removed from the substrate.

The rinsing time is preferably 10 to 300 seconds in general, more preferably 10 to 180 seconds, and even more preferably 20 to 120 seconds. The temperature of the rinsing solution is preferably 0° C. to 50° C., and more preferably 15° C. to 35° C.

[Other Steps]

The aforementioned pattern forming method may include other steps in addition to the steps described above. Examples of those other steps include a pre-wetting step, a washing step using a supercritical fluid, a heating step, and the like.

<(A) Pre-Wetting Step>

The pre-wetting step is a step of coating a substrate, on which a resist film will be formed, with the chemical liquid before the resist film forming step. In the pre-wetting step, known methods can be adopted. As the chemical liquid used in the pre-wetting step, the present chemical liquid or a chemical liquid other than the present chemical liquid may be used.

As the substrate, known substrates used for manufacturing semiconductors can be used without particular limitation. Examples of the substrate include an inorganic substrate such as silicon, SiO₂, or SiN, a coating-type inorganic substrate such as Spin On Glass (SOG), and the like, but the substrate is not limited to these.

Furthermore, the substrate may be a substrate with an antireflection film comprising an antireflection film. As the antireflection film, known organic or inorganic antireflection films can be used without particular limitation.

As the method of coating the substrate with the chemical liquid, known coating methods can be used without particular limitation. Particularly, as the coating method, spin coating is preferable because this method makes it possible to form a uniform resist film by using smaller amounts of the actinic ray-sensitive or radiation-sensitive resin composition in the resist film forming step which will be described later.

The thickness of a chemical liquid layer formed on the substrate by using the chemical liquid is not particularly limited. Generally, the thickness of the chemical liquid layer is preferably 0.001 to 10 μm, and more preferably 0.005 to 5 μm.

Provided that a resist solution, with which the substrate is to be coated, is a resist for ArF immersion exposure, and that the surface tension of the resist solution is 28.8 mN/m, although the surface tension of the mixture of the chemical liquid is not particularly limited, it is preferable to supply the chemical liquid to the wafer as a prewet solution by making the surface tension of the chemical liquid higher than the surface tension of the resist solution.

Generally, the chemical liquid is supplied to the wafer by a method of moving a prewet nozzle to a position above the central portion of the wafer. Then, by opening or closing a valve, the chemical liquid is supplied to the wafer.

In a state where the wafer stands still, a predetermined amount of the chemical liquid is supplied to the central portion of the wafer from the prewet nozzle. Then, the wafer is rotated at a first speed V1 which is, for example, about 500 rotation per minute (rpm) such that the chemical liquid on the wafer spreads over the entire surface of the wafer. As a result, the entire surface of the wafer is wet with the chemical liquid.

The upper limit of the first speed V1 is not particularly limited, but is preferably equal to or lower than 3,000 rpm.

Thereafter, the valve of a line connected to a resist solution is opened. As a result, the resist solution starts to be jetted from a resist nozzle, and the resist solution starts to be supplied to the central portion of the wafer.

In this way, the resist film forming step is started. In the resist film forming step, from the first speed V1, the rotation speed of the wafer is increased to a high speed which is a second speed V2 of about 2,000 to 4,000 rpm, for example. The wafer rotating at the first speed V1 before the start of the resist film forming step is then gradually accelerated such that the speed continuously and smoothly changes. At this time, the acceleration of the rotation of the wafer is gradually increased from zero, for example. In order to finish the resist film forming step, the acceleration of the rotation of the wafer is reduced such that the rotation speed of the wafer W smoothly reaches the second speed V2. In this way, during the resist film forming step, the rotation speed of the wafer changes such that the transition from the first speed V1 to the second speed V2 is represented by an S-shaped curve. In the resist film forming step, due to the centrifugal force, the resist solution supplied to the central portion of the wafer spreads over the entire surface of the wafer, whereby the surface of the wafer is coated with the resist solution.

The technique for saving resist by changing the rotation speed of a wafer during resist coating is specifically described in JP2008-131495 and JP2009-279476A.

The interval between the point in time when the pre-wetting step has been finished and the point in time when the coating with the resist solution in the resist film forming step is to be started is not particularly limited, but is preferably equal to or shorter than 7 seconds in general.

The chemical liquid may be recycled. That is, the chemical liquid used in the pre-wetting step can be recovered and reused in the pre-wetting step for other wafers.

In a case where the chemical liquid is recycled, it is preferable to adjust the content of the impurity metal, the organic impurities, water, and the like contained in the recovered chemical liquid.

<Removing Step Using Supercritical Fluid>

A removing step using a supercritical fluid is a step of removing the developer and/or the rinsing solution having adhered to the pattern by using a supercritical fluid after the development step and/or the rinsing step.

<Heating Step>

The heating step is a step of heating the resist film so as to remove the solvent remaining in the pattern after the development step, the rinsing step, or the removing step using a supercritical fluid.

The heating temperature is not particularly limited, but is preferably 40° C. to 160° C. in general, more preferably 50° C. to 150° C., and even more preferably 50° C. to 110° C.

The heating time is not particularly limited, but is preferably 15 to 300 seconds in general and more preferably 15 to 180 seconds.

### EXAMPLES

Hereinafter, the present invention will be more specifically described based on examples. The materials, the amount and proportion of the materials used, the details of treatments, the procedure of treatments, and the like shown in the following examples can be appropriately modified as long as the gist of the present invention is maintained. Accordingly, the scope of the present invention is not limited to the following examples.

For preparing chemical liquids of examples and comparative examples, the handling of containers, and the preparation, filling, storage, and analytical measurement of chemical liquids were all performed in a clean room of a level satisfying ISO class 2 or 1. In order to improve the measurement accuracy, in measuring the content of an organic compound and the content of a metal component, in a case where the content of the organic compound or metal component was found to be equal to or smaller than a detection limit by general measurement, the chemical liquid was concentrated for the measurement, and the content was calculated by converting the concentration into the concentration of the solution not yet being concentrated.

[Purification of Chemical Liquid A1]

A substance to be purified (commercial product) was prepared which contained propylene glycol monomethyl ether acetate (PGMEA) as an organic solvent.

Then, a first distillation portion (distillation step for rough distillation) having a first plate distillation column not comprising a pressure reducing mechanism, a second distillation portion (distillation step for fractionation treatment), in which a first packed portion (ion removing step) that is constituted with three packed columns each packed with a cation exchange resin and connected in series, a second packed portion (ion removing step) that is constituted with two packed columns each packed with an anion exchange resin and connected in series, a second plate distillation column that does not comprise a pressure reducing mechanism, and a third plate distillation column that comprises a pressure reducing mechanism, are connected in series in this order, a first filter, and a filtration portion (filtration step) in which a first filter and a second filter are connected in series in this order were connected in this order from the upstream side, thereby preparing a purification device.

The aforementioned substance to be purified was purified using the purification device, thereby manufacturing a chemical liquid. Whenever the substance to be purified is passed through the purification device once, the number of times of purification was counted as 1. The total number of times of purification was 2 (in the table, described as 2 in the column of “Number of times of circulation”).

Hereinafter, details of each member in the purification device will be shown in order from the upstream side (primary side).
First plate distillation column (theoretical number of plates: 10)
Cation exchange resin (ORLITE DS-4, manufactured by ORGANO CORPORATION)
Anion exchange resin (ORLITE DS-6, manufactured by ORGANO CORPORATION)
Second plate distillation column (theoretical number of plates: 23)
Third plate distillation column (theoretical number of plates: 23, distillation under reduced pressure)
First filter (Purasol SP/SN solvent purifier, manufactured by Entegris, ultra-high-molecular-weight polyethylene (UPE) filter)
Second filter (trade name “TORRENTO”, manufactured by Entegris, polytetrafluoroethylene (PTFE) filter)

[Purification of Other Chemical Liquids]

Under the conditions described in Table 1, the substances to be purified containing the organic solvents described in Table 1 were purified, thereby obtaining chemical liquids. The substances to be purified were sequentially passed through the respective members described in Table 1 from the upstream side (for each chemical liquid, a blank tells that the corresponding member was not used). The passing of the substances to be purified through the members was repeated by the number of times described in “Number of times of circulation”, thereby obtaining the chemical liquids.

Here, in Comparative Example NA2, the ion removing step was performed using the third packed portion packed with an adsorptive resin (trade name “DUOLITE 874”, styrene-based resin) instead of the first and second packed portions used in the ion removing step.

As each of the first, second, and third plate distillation columns, a distillation column including as many plates as the theoretical number of plates described in Table 1 was used. Furthermore, the number of plates of the cation exchange resin means the number of packed columns packed with the cation exchange resin that are connected in series. The number of plates of the anion exchange resin means the number of packed columns packed with the anion exchange resin that are connected in series. The number of plates of the adsorptive resin means the number of packed columns packed with the adsorptive resin that are connected in series.

The substances to be purified described in Table 1 were prepared from different lots. Therefore, in some cases, the components other than the organic solvent contained in the substances to be purified from the first vary between the substances to be purified.

The abbreviations in Table 1 mean the following components.
PGMEA: propylene glycol monomethyl ether acetate (boiling point: 146° C., SP value: 17.86)
NBA: n-butyl acetate (boiling point: 126° C., SP value: 17.80)
IAA: isoamyl acetate (boiling point: 142° C., SP value: 17.42)
CHN: cyclohexanone (boiling point: 155.6° C., SP value: 20.05)
PGME: propylene glycol monoethyl ether (boiling point: 132.8° C., SP value: 23.05)
MIBC: 4-methyl-2-pentanol (boiling point: 131.6° C., SP value: 21.15)
EL: ethyl lactate (boiling point: 154° C., SP value: 24.41)
PC: propylene carbonate (boiling point: 242° C., SP value: 20.26)

TABLE 1
Table 1
(Table 1-1)

| | | Purification device (manufacturing step) | | | | | | | | |
|---|---|---|---|---|---|---|---|---|---|---|
| | | | | | | | Third plate | | | |
| | | | | | | | distillation | | | |
| | | | | | | | column | | | |
| | | First plate | Cation | Anion | | Second plate | (distillation | | | |
| | | distillation | exchange | exchange | Adsorptive | distillation | under reduced | | | |
| | Substance | column | resin | resin | resin | column | pressure) | | | Number of |
| | to be | (number of | (number of | (number of | (number of | (number of | (number of | First | Second | times of |
| | purified | plates) | plates) | plates) | plates) | plates) | plates) | filter | filter | circulation |
| Chemical | PGMEA | 10 | 2 | 1 | | 23 | 23 | 1 | 1 | 2 |
| liquid A1 | | | | | | | | | | |
| Chemical | PGMEA | 10 | 3 | 2 | | 23 | 23 | 1 | 1 | 4 |
| liquid A2 | | | | | | | | | | |
| Chemical | PGMEA | 12 | 3 | 2 | | 23 | 23 | 1 | 1 | 8 |
| liquid A3 | | | | | | | | | | |
| Chemical | PGMEA | 13 | 2 | | | 23 | 23 | 1 | 1 | 2 |
| liquid A4 | | | | | | | | | | |
| Chemical | PGMEA | 15 | 2 | | | 23 | 10 | 1 | 1 | 2 |
| liquid A5 | | | | | | | | | | |
| Chemical | PGMEA | 5 | 2 | 1 | | 18 | 23 | 1 | 1 | 2 |
| liquid A6 | | | | | | | | | | |
| Chemical | PGMEA | 10 | 2 | 1 | | 23 | 10 | 1 | 1 | 2 |
| liquid A7 | | | | | | | | | | |
| Chemical | PGMEA | 5 | 2 | 1 | | 23 | 10 | 1 | 1 | 2 |
| liquid A8 | | | | | | | | | | |
| Chemical | PGMEA | 10 | 2 | 1 | | 23 | 18 | 1 | 1 | 2 |
| liquid A9 | | | | | | | | | | |
| Chemical | PGMEA | 8 | 2 | | | 23 | | | 1 | 2 |
| liquid A10 | | | | | | | | | | |
| Chemical | PGMEA | 5 | 2 | 1 | | 13 | 9 | 1 | 1 | 2 |
| liquid A11 | | | | | | | | | | |
| Chemical | PGMEA | 10 | 2 | | | 23 | 23 | 1 | 1 | 3 |
| liquid A12 | | | | | | | | | | |
| Chemical | PGMEA | 10 | 2 | | | 23 | 23 | 1 | 1 | 3 |
| liquid A13 | | | | | | | | | | |
| Chemical | PGMEA | 15 | 3 | 2 | | 23 | 23 | 1 | 1 | 6 |
| liquid A14 | | | | | | | | | | |
| Chemical | PGMEA | 13 | 3 | 2 | | 23 | 23 | 1 | 1 | 6 |
| liquid A15 | | | | | | | | | | |
| Chemical | PGMEA | 5 | 2 | 1 | | 23 | 9 | 1 | 1 | 6 |
| liquid A16 | | | | | | | | | | |
| Chemical | PGMEA | 5 | 2 | 1 | | 23 | 10 | 1 | 1 | 2 |
| liquid A17 | | | | | | | | | | |
| Chemical | PGMEA | 5 | 2 | 1 | | 23 | 10 | 1 | 1 | 2 |
| liquid A18 | | | | | | | | | | |
| Chemical | PGMEA | 5 | 2 | 1 | | 23 | 10 | 1 | 1 | 2 |
| liquid A19 | | | | | | | | | | |
| Chemical | PGMEA | 10 | 2 | | | 23 | 23 | 1 | 1 | 3 |
| liquid NA1 | | | | | | | | | | |
| Chemical | PGMEA | 10 | | | 1 | 23 | 23 | | 1 | 2 |
| liquid NA2 | | | | | | | | | | |
| Chemical | PGMEA | 10 | | 1 | | 23 | 23 | | 1 | 2 |
| liquid NA3 | | | | | | | | | | |
| Chemical | PGMEA | 15 | | 1 | | 23 | 23 | 1 | 1 | 4 |
| liquid NA4 | | | | | | | | | | |
| Chemical | PGMEA | 15 | | 1 | | 23 | 23 | | 1 | 4 |
| liquid NA5 | | | | | | | | | | |
| Chemical | PGMEA | 17 | | 2 | | 23 | 23 | 1 | 1 | 4 |
| liquid NA6 | | | | | | | | | | |

TABLE 2
Table 1
(Table 1-2)

| | | Purification device (manufacturing step) | | | | | | | | |
|---|---|---|---|---|---|---|---|---|---|---|
| | | | | | | | Third plate | | | |
| | | | | | | | distillation | | | |
| | | | | | | | column | | | |
| | | First plate | Cation | Anion | | Second plate | (distillation | | | |
| | | distillation | exchange | exchange | Adsorptive | distillation | under reduced | | | |
| | Substance | column | resin | resin | resin | column | pressure) | | | Number of |
| | to be | (number of | (number of | (number of | (number of | (number of | (number of | | Second | times of |
| | purified | plates) | plates) | plates) | plates) | plates) | plates) | First filter | filter | circulation |
| Chemical | nBA | 10 | 2 | 1 | | 23 | 23 | 1 | 1 | 2 |
| liquid B1 | | | | | | | | | | |
| Chemical | nBA | 10 | 2 | 1 | | 23 | 23 | 1 | 1 | 2 |
| liquid B2 | | | | | | | | | | |
| Chemical | nBA | 10 | 2 | 1 | | 23 | 23 | 1 | 1 | 2 |
| liquid B3 | | | | | | | | | | |
| Chemical | nBA | 10 | 2 | | | 15 | 15 | 1 | 1 | 3 |
| liquid B4 | | | | | | | | | | |
| Chemical | nBA | 10 | 3 | 2 | | 23 | 23 | 1 | 1 | 4 |
| liquid B5 | | | | | | | | | | |
| Chemical | nBA | 12 | 1 | 3 | | 23 | 23 | | 1 | 6 |
| liquid B6 | | | | | | | | | | |
| Chemical | nBA | 10 | 2 | | | 23 | 23 | 1 | 1 | 3 |
| liquid NB1 | | | | | | | | | | |
| Chemical | iAA | 10 | 2 | 1 | | 23 | 23 | 1 | 1 | 2 |
| liquid C1 | | | | | | | | | | |
| Chemical | CHN | 10 | 2 | 1 | | 23 | 23 | 1 | 1 | 2 |
| liquid D1 | | | | | | | | | | |
| Chemical | CHN | 10 | 2 | 1 | | 23 | 23 | 1 | 1 | 2 |
| liquid ND1 | | | | | | | | | | |
| Chemical | PGME | 10 | 2 | 1 | | 23 | 23 | 1 | 1 | 2 |
| liquid E1 | | | | | | | | | | |
| Chemical | PGME | 10 | 2 | 1 | | 23 | 23 | 1 | 1 | 2 |
| liquid E2 | | | | | | | | | | |
| Chemical | MIBC | 10 | 2 | 1 | | 23 | 23 | 1 | 1 | 2 |
| liquid F1 | | | | | | | | | | |
| Chemical | EL | 10 | 2 | 1 | | 23 | 23 | 1 | 1 | 2 |
| liquid G1 | | | | | | | | | | |
| Chemical | PC | 10 | 2 | 1 | | 23 | 23 | 1 | 1 | 2 |
| liquid H1 | | | | | | | | | | |

[Measurement of Content of Each Component Contained in Chemical Liquid, and the Like]

For measuring the content of each component contained in the chemical liquid and the like, the following method was used. All of the following measurements were performed in a clean room that met the level equal to or lower than International Organization for Standardization (ISO) Class 2. In order to improve the measurement accuracy, in measuring each component, in a case where the content of the component was found to be equal to or smaller than a detection limit by general measurement, the organic solvent was concentrated by 1/100 in terms of volume for performing the measurement, and the content was calculated by converting the concentration into the content of the organic solvent not yet being concentrated. The results are summarized in Table 2.

The content of each component in the chemical liquid was measured immediately after the chemical liquid was prepared.

[Acid Component and Organic Compound]

The content of acid components and organic compounds in each of the chemical liquids was measured using a gas chromatography mass spectrometry (tradename “GCMS-2020”, manufactured by Shimadzu Corporation, the measurement conditions were as described below).

<Measurement Conditions>

Capillary column: InertCap 5MS/NP 0.25 mmI.D.×30 m df=0.25 μm

Sample introduction method: split 75 kPa constant pressure

Vaporizing chamber temperature: 230° C.

Column oven temperature: 80° C. (2 min)-500° C. (13 min) heating rate 15° C./min

Carrier gas: helium

Septum purge flow rate: 5 mL/min

Split ratio: 25:1

Interface temperature: 250° C.

Ion source temperature: 200° C.

Measurement mode: Scan m/z=85-500

Amount of sample introduced: 1 μL

[Metal Component]

The content of the metal component (metal ions and metal-containing particles) in the chemical liquid was measured by a method using ICP-MS and SP-ICP-MS.

The used devices are as follows. The results are shown in Table 2.
Manufacturer: PerkinElmer
Model: NexION350S

The following analysis software was used for analysis.
Syngistix nano application module dedicated for “SP-ICP-MS”
Syngistix for ICP-MS software

[Metal Nanoparticles]

The number of metal nanoparticles (metal-containing particles having a particle size of 0.5 to 17 nm) contained in the chemical liquid was measured by the following method.

First, a silicon substrate was coated with a certain amount of chemical liquid, thereby forming a substrate with a chemical liquid layer. Then, the surface of the substrate with a chemical liquid layer was scanned with a laser beam, and the scattered light was detected. In this way, the position and particle size of defects present on the surface of the substrate with a chemical liquid layer were specified. Thereafter, based on the position of the defects, elemental analysis was carried out by the energy dispersive X-ray (EDX) spectroscopy, thereby investigating the composition of the defects. By this method, the number of metal nanoparticles on the substrate was determined, and the determined number was converted into the number of particles contained in a unit volume of the chemical liquid (particles/cm³).

For the analysis, a wafer inspection device “SP-5” manufactured by KLA-Tencor Corporation. and a fully automatic defect review/classification device “SEMVision G6” manufactured by Applied Materials, Inc. were used in combination.

Furthermore, for a sample in which particles having a desired particle size could not be detected due to the resolution of a measurement device and the like, the method described in paragraphs “0015” to “0067” in JP2009-188333A was used for detection. That is, a SiO_{X} layer was formed on a substrate by a chemical vapor deposition (CVD) method, and then a chemical liquid layer covering the SiO_{X} layer was formed. Subsequently, a method was used in which the composite layer including the SiO_{X} layer and the chemical liquid layer with which the SiO_{X} layer was coated was subjected to dry etching, the obtained projections were irradiated with light, the scattered light was detected, the volume of the projections was calculated from the scattered light, and the particle size of the particles was calculated from the volume of the projections.

[Evaluation of Defect Inhibition Performance]

Defect inhibition performance was evaluated using the obtained chemical liquid as a prewet solution.

The defect inhibition performance was evaluated for both the case where a chemical liquid was used immediately after manufacturing (described as “Immediately after manufacturing” in the table) and the case where a chemical liquid was used after being preserved for 45 days at 40° C. in a state of being stored in a container (material of the liquid contact portion: high-density polyethylene (HDPE) resin) included in a chemical liquid storage body (described as “After passage of time” in the table).

The used resist composition is as follows.

[Resist Composition 1]

A resist composition 1 was obtained by mixing together components according to the following composition.
Resin (A-1): 0.77 g
Photoacid generator (B-1): 0.03 g
Basic compound (E-3): 0.03 g
PGMEA: 67.5 g
EL: 75 g

<Resin (A) and the Like>

### (Synthesis Example 1) Synthesis of Resin (A-1)

A 2 L flask was filled with 600 g of cyclohexanone and subjected to nitrogen purging for 1 hour at a flow rate of 100 mL/min. Thereafter, 4.60 g (0.02 mol) of a polymerization initiator V-601 (manufactured by FUJIFILM Wako Pure Chemical Corporation) was added thereto, and the flask was heated until the internal temperature thereof reached 80° C. Subsequently, the following monomers and 4.60 g (0.02 mol) of a polymerization initiator V-601 (manufactured by FUJIFILM Wako Pure Chemical Corporation) were dissolved in 200 g of cyclohexanone, thereby preparing a monomer solution. The monomer solution was added dropwise for 6 hours to the flask heated to 80° C. After the dropwise addition ended, the reaction was further performed for 2 hours at 80° C.

4-Acetoxystyrene 48.66 g (0.3 mol)

1-Ethylcyclopentyl methacrylate 109.4 g (0.6 mol)

Monomer 1 22.2 g (0.1 mol)

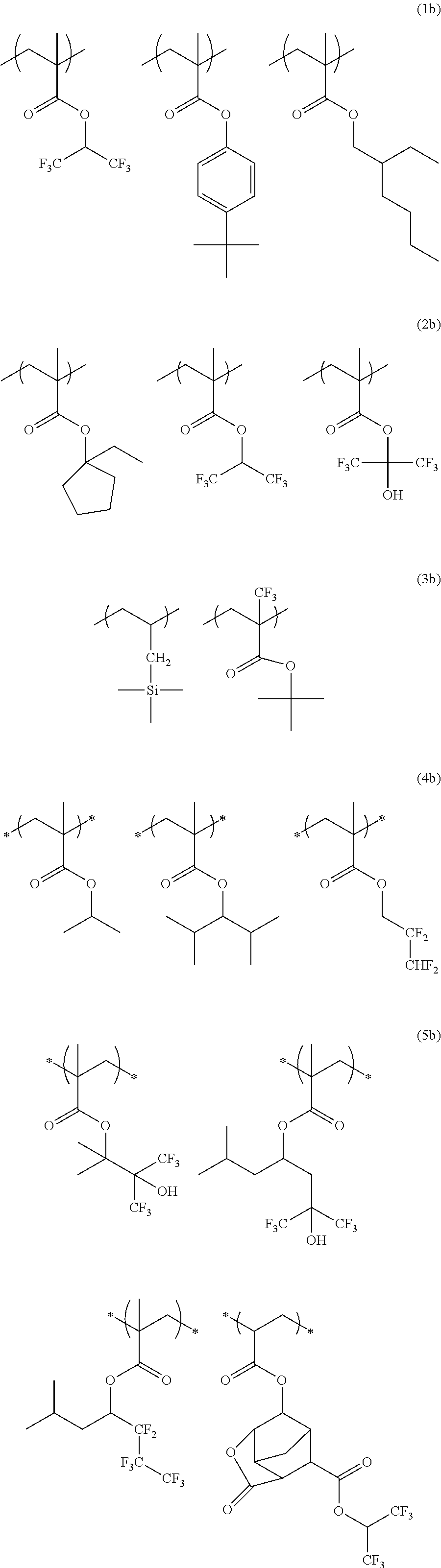

The reaction solution was cooled to room temperature and added dropwise to 3 L of hexane such that polymers were precipitated. The filtered solids were dissolved in 500 mL of acetone, added dropwise again to 3 L of hexane, and the filtered solids were dried under reduced pressure, thereby obtaining 160 g of a 4-acetoxystyrene/1-ethylcyclopentyl methacrylate/monomer 1 copolymer (A-1).

The obtained polymer (10 g), 40 mL of methanol, 200 mL of 1-methoxy-2-propanol, and 1.5 mL of concentrated hydrochloric acid were added to a reaction container, heated at 80° C., and stirred for 5 hours. The reaction solution was left to cool to room temperature and added dropwise to 3 L of distilled water. The filtered solids were dissolved in 200 mL of acetone, added dropwise again to 3 L of distilled water, and the filtered solids were dried under reduced pressure, thereby obtaining a resin (A-1) (8.5 g). The resin had a weight-average molecular weight (Mw) of 11,200, which was measured by gel permeation chromatography (GPC) (solvent: tetrahydrofuran (THF)) and expressed in terms of standard polystyrene, and a molecular weight dispersity (Mw/Mn) of 1.45. The structure of the resin A-1 or the like is shown below.

| | | Compositional | | |
|---|---|---|---|---|
| | | ratio | | |
| | | (molar ratio) | | |
| | Structure | from left [symbol] | Mw | Mw/Mn |
| Resin A-1 | 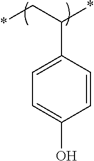 | 30/60/10 | 11,200 | 1.45 |
| | 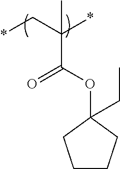 | | | |
| | 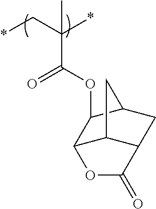 | | | |

[symbol]

indicates data missing or illegible when filed

<Photoacid Generator (B)>

The following compound was used as photoacid generators.

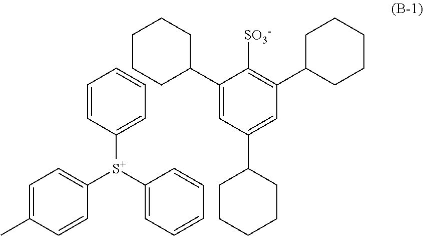

<Basic Compound (E)>

As a basic compound, the following compound was used.

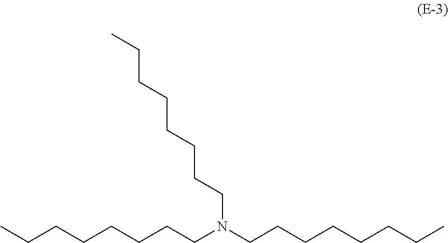 [SMILES: CCCCCCCCN(CCCCCCCC)CCCCCCCC]

(Defect Inhibition Performance)

The defect inhibition performance of the chemical liquid was evaluated by the following method. A coater developer “RF^{3S}” manufactured by Sokudo Co., Ltd. was used for test.

First, a silicon wafer was coated with AL412 (manufactured by Brewer Science, Inc.) and baked at 200° C. for 60 seconds, thereby forming a resist underlayer film having a film thickness of 20 nm. The film was coated with a prewet solution (chemical liquid 1), then coated with the resist composition 1, and baked at 100° C. for 60 seconds (PB: Prebake), thereby forming a resist film having a film thickness of 30 nm.

By using an EUV exposure machine (manufactured by ASML; NXE3350, NA 0.33, Dipole 90°, outer sigma 0.87, inner sigma 0.35), this resist film was exposed through a reflective mask having a pitch of 20 nm and a pattern width of 15 nm. Then, the resist film was baked at 85° C. for 60 seconds (PEB:Post Exposure Bake). Thereafter, the resist was developed for 30 seconds by using an organic solvent-based developer and then rinsed for 20 seconds. Subsequently, the wafer was rotated at a rotation speed of 2,000 rpm for 40 seconds, thereby forming a line-and-space pattern having a pitch of 20 nm and a pattern line width of 15 nm.

The image of the above pattern was captured. The obtained image was analyzed using a pattern defect inspection device “UVsion 7” from Applied Materials, Inc. and a fully automatic defect review/classification device “SEMVision G6” manufactured by Applied Materials, Inc. in combination, and the number of residues per unit area in an unexposed portion was counted.

For a sample in which particles having a desired particle size could not be detected due to the resolution of a measurement device and the like, the method described in paragraphs “0015” to “0067” in JP2009-188333A was used for detection. That is, a SiO_{X} layer was formed on a substrate by a chemical vapor deposition (CVD) method, and then a chemical liquid layer covering the SiO_{X} layer was formed. Subsequently, a method was used in which the composite layer including the SiO_{X} layer and the chemical liquid layer with which the SiO_{X} layer was coated was subjected to dry etching, the obtained projections were irradiated with light, the scattered light was detected, the volume of the projections was calculated from the scattered light, and the particle size of the particles was calculated from the volume of the projections.

The results were evaluated based on the following standards, and shown in Table 2.

A: The number of defects was less than 50.

B: The number of defects was equal to or greater than 50 and less than 70.

C: The number of defects was equal to or greater than 70 and less than 90.

D: The number of defects was equal to or greater than 90 and less than 110.

E: The number of defects was equal to or greater than 110 and less than 130.

F: The number of defects was equal to or greater than 130.

TABLE 3
Table 2
(Table 2-1)

| | | Acid component (organic acid: mass ppm) | | | | | |
|---|---|---|---|---|---|---|---|
| | Chemical | Acetic | Propionic | n-Butanoic | Pentanoic | Lactic | Adipic |
| | liquid | acid | acid | acid | acid | acid | acid |
| Example A1 | A1 | 0.8 | 0.1 | 0.1 | 0 | 0 | 0 |
| Example A2 | A2 | 0.01 | 0.01 | 0.002 | 0 | 0 | 0 |
| Example A3 | A3 | 0.0001 | 0.0001 | 0.0001 | 0 | 0 | 0 |
| Example A4 | A4 | 3 | 0.5 | 0.5 | 0 | 0 | 0 |
| Example A5 | A5 | 0.7 | 0.09 | 0.08 | 0 | 0 | 0 |
| Example A6 | A6 | 0.6 | 0.2 | 0.2 | 0 | 0 | 0 |
| Example A7 | A7 | 0.5 | 0.08 | 0.09 | 0 | 0 | 0 |
| Example A8 | A8 | 0.5 | 0.08 | 0.09 | 0 | 0 | 0 |
| Example A9 | A9 | 0.4 | 0.06 | 0.08 | 0 | 0 | 0 |
| Example A10 | A10 | 0.6 | 0.05 | 0.06 | 0 | 0 | 0 |
| Example A11 | A11 | 0.9 | 0.1 | 0.1 | 0 | 0 | 0 |
| Example A12 | A12 | 4 | 0.06 | 0.08 | 0 | 0 | 0 |
| Example A13 | A13 | 5 | 0.06 | 0.08 | 0 | 0 | 0 |
| Example A14 | A14 | 0.008 | 0.0018 | 0.0003 | 0 | 0 | 0 |
| Example A15 | A15 | 0.015 | 0.003 | 0.001 | 0 | 0 | 0 |
| Example A16 | A16 | 0.015 | 0.003 | 0.001 | 0 | 0 | 0 |
| Example A17 | A17 | 0.4 | 0.07 | 0.09 | 0 | 0 | 0 |
| Example A18 | A18 | 0.3 | 0.08 | 0.08 | 0 | 0 | 0 |
| Example A19 | A19 | 0.4 | 0.09 | 0.07 | 0 | 0 | 0 |
| Comparative | NA1 | 25 | 0.06 | 0.08 | 0 | 0 | 0 |
| Example NA1 | | | | | | | |
| Comparative | NA2 | 123 | 0.06 | 0.06 | 0 | 0 | 0 |
| Example NA2 | | | | | | | |
| Comparative | NA3 | 0.8 | 0.06 | 0.09 | 0 | 0 | 0 |
| Example NA3 | | | | | | | |
| Comparative | NA4 | 0.001 | 0 | 0 | 0 | 0 | 0 |
| Example NA4 | | | | | | | |
| Comparative | NA5 | 0.0011 | 0 | 0 | 0 | 0 | 0 |
| Example NA5 | | | | | | | |
| Comparative | NA6 | 5E−07 | 0 | 0 | 0 | 0 | 0 |
| Example NA6 | | | | | | | |

| | | | Acid component | | | | |
|---|---|---|---|---|---|---|---|
| | | | (inorganic acid: | | | | |
| | | | mass ppb) | | | | Number of |
| | Acid component (organic | | | Cl⁻ Ions | Metal component | | metal |
| | acid: mass ppm) | | SO³⁻ Ions | derived from | (mass ppt) | | nanoparticles |
| | Maleic | Fumaric | derived from | hydrochloric | | Metal-containing | contained |
| | acid | acid | sulfuric acid | acid | Ions | particles | (particles/cm³) |
| Example A1 | 0.1 | 0.01 | 1 | 0 | 10 | 0.1 | 6 |
| Example A2 | 0.001 | 0.001 | 0.1 | 0 | 4 | 0.01 | 0.8 |
| Example A3 | 0.0001 | 0.0001 | 0.1 | 0 | 2 | 0.01 | 0.07 |
| Example A4 | 0.2 | 0.01 | 3 | 0 | 21 | 0.1 | 3 |
| Example A5 | 0.5 | 0.01 | 10 | 0 | 10 | 0.1 | 2 |
| Example A6 | 0.1 | 0.01 | 1 | 0 | 10 | 0.1 | 5 |
| Example A7 | 0.2 | 0.01 | 3 | 0 | 10 | 0.1 | 0.9 |
| Example A8 | 0.5 | 0.01 | 1 | 0 | 10 | 0.1 | 9 |
| Example A9 | 0.1 | 0.1 | 2 | 0 | 10 | 0.1 | 7 |
| Example A10 | 0.2 | 0.05 | 120 | 0 | 88 | 10 | 835 |
| Example A11 | 0.04 | 0.05 | 1.2 | 0 | 80 | 7 | 220 |
| Example A12 | 0.1 | 0.01 | 0.5 | 0 | 93 | 0.1 | 3 |
| Example A13 | 0.1 | 0.01 | 0.5 | 0 | 77 | 0.1 | 11 |
| Example A14 | 0.0005 | 0.0001 | 0.1 | 0 | 1 | 0.02 | 7 |
| Example A15 | 0.001 | 0.001 | 0.1 | 0 | 4 | 0.03 | 12 |
| Example A16 | 0.001 | 0.001 | 0.1 | 0 | 3 | 0.03 | 12 |
| Example A17 | 0.4 | 0.01 | 1 | 0 | 10 | 15 | 1,300 |
| Example A18 | 0.4 | 0.01 | 1 | 0 | 10 | 9 | 1,079,300 |
| Example A19 | 0.3 | 0.01 | 1 | 0 | 165 | 0.7 | 9 |
| Comparative | 0.1 | 0.01 | 0.5 | 0 | 13 | 0.1 | 25 |
| Example NA1 | | | | | | | |
| Comparative | 0.1 | 0.01 | 28 | 0 | 351 | 110 | 258,000 |
| Example NA2 | | | | | | | |
| Comparative | 0.1 | 0.01 | 1 | 0 | 19800 | 162 | 423,000 |
| Example NA3 | | | | | | | |
| Comparative | 0.001 | 0.001 | 1 | 0 | 36400 | 118 | 215,000 |
| Example NA4 | | | | | | | |
| Comparative | 0.0003 | 0 | 0.1 | 0 | 63500 | 151 | 501,000 |
| Example NA5 | | | | | | | |
| Comparative | 0 | 0 | 0.001 | 0 | 88 | 151 | 398,000 |
| Example NA6 | | | | | | | |

| | | | | | Defect inhibition | |
|---|---|---|---|---|---|---|
| | Organic compound | | | Acid | performance | |
| | (mass ppm) | | | component/Metal | Immediately | After |
| | Phthalic | Sulfonamide-based | Water (mass | component | after | passage of |
| | acid ester | plasticizer | ppm) | (mass ratio) | manufacturing | time |
| Example A1 | 0.1 | 0.01 | 0.4 | 1.1E+05 | B | B |
| Example A2 | 0.01 | 0.01 | 0.2 | 6.0E+03 | A | A |
| Example A3 | 0.0001 | 0.0001 | 0.2 | 3.0E+02 | A | B |
| Example A4 | 0.1 | 0.01 | 0.3 | 2.0E+05 | C | D |
| Example A5 | 0.1 | 0.01 | 0.5 | 1.4E+05 | D | D |
| Example A6 | 0.1 | 0.01 | 0.3 | 1.1E+05 | C | D |
| Example A7 | 0.5 | 0.4 | 0.4 | 8.7E+04 | C | D |
| Example A8 | 3.1 | 1.2 | 0.3 | 1.2E+05 | D | D |
| Example A9 | 0.1 | 0.01 | 0.3 | 7.3E+04 | B | B |
| Example A10 | 0.1 | 0.01 | 0.5 | 1.1E+04 | D | D |
| Example A11 | 0.3 | 0.1 | 27 | 1.4E+04 | D | D |
| Example A12 | 0.1 | 0.01 | 0.4 | 4.6E+04 | D | D |
| Example A13 | 0.1 | 0.01 | 0.4 | 6.8E+04 | D | D |
| Example A14 | 0.01 | 0.01 | 0.2 | 1.1E+04 | A | A |
| Example A15 | 0.01 | 0.01 | 0.2 | 5.2E+03 | A | A |
| Example A16 | 0.3 | 0.1 | 21 | 7.0E+03 | A | B |
| Example A17 | 2.8 | 0.8 | 0.3 | 3.9E+04 | D | E |
| Example A18 | 1.9 | 0.9 | 0.3 | 4.6E+04 | D | E |
| Example A19 | 3.1 | 0.7 | 0.3 | 5.3E+03 | D | E |
| Comparative | 0.1 | 0.01 | 0.4 | 1.9E+06 | F | F |
| Example NA1 | | | | | | |
| Comparative | 0.1 | 0.01 | 0.1 | 2.7E+05 | F | F |
| Example NA2 | | | | | | |
| Comparative | 0.1 | 0.01 | 0.2 | 5.3E+01 | F | F |
| Example NA3 | | | | | | |
| Comparative | 0.001 | 0.0001 | 0.9 | 1.1E−01 | D | F |
| Example NA4 | | | | | | |
| Comparative | 0.0001 | 0.0001 | 0.9 | 2.4E−02 | D | F |
| Example NA5 | | | | | | |
| Comparative | 0 | 0 | 0.9 | 6.3E−03 | D | F |
| Example NA6 | | | | | | |

TABLE 4
Table 2
(Table 2-2)

| | | Acid component (organic acid: mass ppm) | | | | | |
|---|---|---|---|---|---|---|---|
| | Chemical | Acetic | Propionic | n-Butanoic | Pentanoic | Lactic | Adipic |
| | liquid | acid | acid | acid | acid | acid | acid |
| Example B1 | B1 | 0.8 | 0.06 | 0.05 | 0 | 0 | 0 |
| Example B2 | B2 | 0.1 | 0.03 | 0 | 0 | 0.1 | 0 |
| Example B3 | B3 | 0.1 | 0.1 | 0 | 0 | 0.1 | 0 |
| Example B4 | B4 | 12 | 1 | 1 | 0 | 0 | 0 |
| Example B5 | B5 | 0.01 | 0.01 | 0.01 | 0 | 0 | 0 |
| Example B6 | B6 | 0.0001 | 0.0001 | 0.0001 | 0 | 0 | 0 |
| Comparative | NB1 | 21 | 2 | 2 | 0 | 0 | 0 |
| Example NB1 | | | | | | | |
| Example C1 | C1 | 0.7 | 0.08 | 0.07 | 0 | 0 | 0 |
| Example D1 | D1 | 0 | 0 | 0 | 0.01 | 0 | 0.8 |
| Comparative | ND1 | 0 | 0 | 0 | 0.02 | 0 | 15 |
| Example ND1 | | | | | | | |
| Example E1 | E1 | 0.1 | 0.1 | 0 | 0 | 0 | 0 |
| Example E2 | E2 | 0.1 | 0.1 | 0 | 0 | 0 | 0 |
| Example F1 | F1 | 0.1 | 0.1 | 0 | 0 | 0 | 0 |
| Example G1 | G1 | 0.1 | 0.1 | 0 | 0 | 0.1 | 0 |
| Example H1 | H1 | 0 | 0.1 | 0 | 0 | 0 | 0 |

| | | | Acid component | | | | |
|---|---|---|---|---|---|---|---|
| | Acid component | | (inorganic acid: | | | | |
| | (organic acid: | | mass ppb) | | | | |
| | mass ppm) | | | Cl⁻ Ions | Metal component | | Number of metal |
| | | Immediately | SO³⁻ Ions | derived from | (mass ppt) | | nanoparticles |
| | Maleic | after | derived from | hydrochloric | | Metal-containing | contained |
| | acid | manufacturing | sulfuric acid | acid | Ions | particles | (particles/cm³) |
| Example B1 | 0.07 | 0.01 | 0.9 | 0 | 10 | 0.1 | 6 |
| Example B2 | 0.01 | 0.01 | 0 | 1 | 10 | 0.1 | 9 |
| Example B3 | 0.1 | 0.01 | 0 | 78 | 10 | 0.1 | 12 |
| Example B4 | 0.1 | 0.01 | 0.5 | 0 | 20 | 0.1 | 3 |
| Example B5 | 0.01 | 0.01 | 0.1 | 0 | 4 | 0.01 | 0.2 |
| Example B6 | 0.0001 | 0.0001 | 0.1 | 0 | 43 | 35 | 51,500 |
| Comparative | 0.1 | 0.01 | 0.5 | 0 | 13 | 0.1 | 15 |
| Example NB1 | | | | | | | |
| Example C1 | 0.7 | 0.01 | 0.6 | 0 | 10 | 0.1 | 7 |
| Example D1 | 0.1 | 0.01 | 0 | 0 | 10 | 0.1 | 13 |
| Comparative | 0.2 | 0.05 | 0 | 0 | 10 | 0.1 | 21 |
| Example ND1 | | | | | | | |
| Example E1 | 0.2 | 0.03 | 1 | 0 | 10 | 0.1 | 9 |
| Example E2 | 0.2 | 0.03 | 0 | 1 | 10 | 0.1 | 13 |
| Example F1 | 0.2 | 0.03 | 1 | 0 | 10 | 0.1 | 8 |
| Example G1 | 0.06 | 0.01 | 1 | 0 | 10 | 0.1 | 18 |
| Example H1 | 0.014 | 0.01 | 0.1 | 0 | 10 | 0.1 | 15 |

| | | | | | Defect inhibition | |
|---|---|---|---|---|---|---|
| | Organic compound | | | Acid | performance | |
| | (mass ppm) | | | component/Metal | Immediately | After |
| | Phthalic | Sulfonamide-based | Water (mass | component (mass | after | passage of |
| | acid ester | plasticizer | ppm) | ratio) | manufacturing | time |
| Example B1 | 0.1 | 0.01 | 1 | 9.8E+04 | A | A |
| Example B2 | 0.1 | 0.01 | 1 | 2.5E+04 | A | A |
| Example B3 | 0.1 | 0.01 | 1 | 4.8E+04 | D | D |
| Example B4 | 0.1 | 0.01 | 0.4 | 7.0E+05 | D | D |
| Example B5 | 0.01 | 0.01 | 0.2 | 1.2E+04 | A | B |
| Example B6 | 0.0001 | 0.0001 | 0.2 | 7.7E+00 | A | D |
| Comparative | 0.1 | 0.01 | 0.4 | 1.9E+06 | F | F |
| Example NB1 | | | | | | |
| Example C1 | 0.1 | 0.01 | 1 | 8.5E+04 | A | A |
| Example D1 | 0.1 | 0.01 | 1 | 9.1E+04 | B | B |
| Comparative | 0.1 | 0.01 | 1 | 1.5E+06 | F | F |
| Example ND1 | | | | | | |
| Example E1 | 0.1 | 0.01 | 1 | 4.3E+04 | B | B |
| Example E2 | 0.1 | 0.01 | 1 | 4.3E+04 | B | B |
| Example F1 | 0.1 | 0.01 | 1 | 4.3E+04 | B | B |
| Example G1 | 0.1 | 0.01 | 1 | 3.7E+04 | A | A |
| Example H1 | 0.1 | 0.01 | 1 | 1.2E+04 | A | A |

In Table 2, the exponents of numerical values described in the columns of “Acid component” and “Acid component/metal component (mass ratio)” are abbreviated in some cases. For example, “1.1E+05” means “1.1×10⁵”, and “6.3E-03” means “6.3×10⁻³”.

As shown in Table 2, it has been revealed that in a case where a chemical liquid is used in which the content of the acid component is equal to or greater than 1 mass ppt and equal to or smaller than 15 mass ppm with respect to the total mass of the chemical liquid and the content of the metal component is 0.001 to 100 mass ppt with respect to the total mass of the chemical liquid, the obtained chemical liquid exhibits excellent defect inhibition performance even after the long-term preservation (examples).

For example, from the comparison between Examples A1 and A2, it has been revealed that in a case where the content of an organic acid is equal to or smaller than 1 mass ppm with respect to the total mass of the chemical liquid (Example A2), the chemical liquid exhibits further improved defect inhibition performance immediately after the manufacturing and after the long-term preservation.

For example, from the comparison between Examples A2 and A3, it has been revealed that in a case where the content of an organic acid having a boiling point equal to or higher than the boiling point of the organic solvent is equal to or smaller than 20% by mass with respect to the total mass of the organic acid (Example A2), the chemical liquid exhibits further improved defect inhibition performance after the long-term preservation.

For example, from the comparison between Examples A1 and A4, it has been revealed that in a case where the content of an inorganic acid is equal to or smaller than 1 mass ppb with respect to the total mass of the chemical liquid (Example A1), the chemical liquid exhibits further improved defect inhibition performance immediately after the manufacturing and after the long-term preservation.

For example, from the comparison between Examples A15 and A16, it has been revealed that in a case where the content of water is equal to or smaller than 1 mass ppm with respect to the total mass of the chemical liquid (Example A15), the chemical liquid exhibits further improved defect inhibition performance after the long-term preservation.

For example, from the comparison between Examples A8 and A17, it has been revealed that in a case where the content of metal-containing particles is within a range of 0.00001 to 10 mass ppt with respect to the total mass of the chemical liquid (Example A8), the chemical liquid exhibits further improved defect inhibition performance after the long-term preservation.

For example, from the comparison between Examples A8 and A18, it has been revealed that in a case where the number of metal nanoparticles contained in a unit volume of the chemical liquid is within a range of 1.0×10⁻² to 1.0×10⁶ particles/cm³ (Example A8), the chemical liquid exhibits further improved defect inhibition performance after the long-term preservation.

For example, from the comparison between Examples A8 and A19, it has been revealed that in a case where the content of metal ions is within a range of 0.01 to 100 mass ppt with respect to the total mass of the chemical liquid (Example A8), the chemical liquid exhibits further improved defect inhibition performance after the long-term preservation.

As shown in Table 2, it has been revealed that in a case where a chemical liquid is used in which at least either the content of the acid component with respect to the total mass of the chemical liquid or the content of the metal component with respect to the total mass of the chemical liquid is outside the above range, the chemical liquid exhibits poor defect inhibition performance after the long-term preservation (comparative examples).

As defect inhibition performance evaluation methods other than the above, the methods described in Document (1) and Document (2) were used to evaluate defect inhibition performance. As a result, it has been revealed that all of the evaluation results of the defect inhibition performance of examples and comparative examples show the same tendency as that of the defect inhibition performance described above.
Document (1) Journal of photopolymer science and technology, Vol 28, No. 1 (2015) 17-24 (Renesus)
Document (2) “Development of Novel Purifiers with Appropriate Functional Groups Based on Solvent Polarities at Bulk Filtration” Enteglis News letter (May 2017)

### Example X1

The chemical liquid B1 was prepared as a chemical liquid X to be used as a developer.

In addition, butyl butyrate was prepared as a chemical liquid Y to be used as a rinsing solution. The butyl butyrate used as the chemical liquid Y was purchased and used as it was without being subjected to the filtration treatment and the like described above.

The organic solvent used as the chemical liquid Y in the following examples and comparative examples was purchased and used as it was without being subjected to the filtration treatment and the like described above.

### Examples X2 to X16

The chemical liquid X and the chemical liquid Y combined as shown in Table 3 were prepared in the same manner as in Example X1, except that the organic solvent listed in the column of Chemical liquid Y in Table 3 was used as the chemical liquid Y (rinsing solution).

### Example X17

As the chemical liquid Y (rinsing solution), a mixed solvent A1 of butyl butyrate and undecane (butyl butyrate:undecane=1:1 (based on mass)) was prepared.

The chemical liquid X and the chemical liquid Y combined as shown in Table 3 were prepared in the same manner as in Example X1, except that the above chemical liquid Y was used.

### Example X18

The chemical liquid B2 was prepared as a chemical liquid X to be used as a developer.

As a chemical liquid Y (rinsing solution), a mixed solvent B1 of butyl butyrate and methanol (butyl butyrate:methanol=1:1 (based on mass)) was prepared.

### Example X19

As a chemical liquid Y (rinsing solution), a mixed solvent A2 of butyl butyrate and undecane (butyl butyrate:undecane=9:1 (based on mass)) was prepared.

The chemical liquid X and the chemical liquid Y combined as shown in Table 3 were prepared in the same manner as in Example X1, except that the above chemical liquid Y was used.

### Example X20

As a chemical liquid Y (rinsing solution), a mixed solvent B2 of butyl butyrate and methanol (butyl butyrate:methanol=9:1 (based on mass)) was prepared.

The chemical liquid X and the chemical liquid Y combined as shown in Table 3 were prepared in the same manner as in Example X1, except that the above chemical liquid Y was used.

### Examples X21 to X26

A chemical liquid X and a chemical liquid Y combined as shown in Table 3 were prepared in the same manner as in Example X1, except that the organic solvent shown in Table 3 was used as the chemical liquid Y (rinsing solution).

Here, in Example X26, the chemical liquid Y (rinsing solution) was not used.

### Comparative Examples NX1 to NX16

By using the chemical liquid NB1 as a chemical liquid X (developer) and using an organic solvent shown in Table 3 as a chemical liquid Y (rinsing solution), chemical liquids X and Y combined as shown in Table 3 were prepared.

### Comparative Examples NX17 to NX20

A chemical liquid X and a chemical liquid Y combined as shown in Table 3 were prepared in the same manner as in Comparative Example NX1, except that the mixed solvent A1, A2, B1, or B2 was used as the chemical liquid Y (rinsing solution).

### Comparative Examples NX21 to NX26

A chemical liquid X and a chemical liquid Y combined as shown in Table 3 were prepared in the same manner as in Example NX1, except that the organic solvent shown in Table 3 was used as the chemical liquid Y (rinsing solution).

Here, in Comparative Example NX26, the chemical liquid Y (rinsing solution) was not used.

[Evaluation of Defect Inhibition Performance]

For each of Examples X1 to X26 and Comparative Examples NX1 to NX26, defect inhibition performance was evaluated in the same manner as in the evaluation of defect inhibition performance described above, except that PGMEA was used as a prewet solution, a developer and a rinsing solution combined as shown in Table 3 were used, and the exposure conditions for the resist film and the conditions of washing using a rinsing solution were changed as follows. The defect inhibition performance was evaluated based on the same evaluation standard as that of the evaluation of defect inhibition performance described above.

PGMEA used as a prewet solution was purchased and used as it was without being subjected to the filtration treatment and the like described above.

In addition, the defect inhibition performance was evaluated for the case where the chemical liquid X (developer) was used after being preserved for 45 days at 40° C. in a state of being stored in a container (material of the liquid contact portion: high-density polyethylene (HDPE) resin) included in a chemical liquid storage body (described as “After passage of time” in the table). The prewet solution and the chemical liquid Y (rinsing solution), which were prepared or commercial products, were used immediately after prepared or opened without being preserved.

(Exposure Conditions for Resist Film)

The prepared wafer with a resist film was subjected to EUV exposure using a dipole lighting (Dipole 60×, outer sigma 0.81, inner sigma 0.43) at a lens numerical aperture (NA) of 0.25. Specifically, by changing the exposure amount, EUV exposure was performed through a mask including a pattern for forming a line-and-space pattern having a pitch of 40 nm and a width of 20 nm on the wafer. After being irradiated, the wafer was taken out of the EUV exposure machine and then immediately baked (PEB) for 60 seconds under the condition of 90° C.

(Washing Conditions)

A rinsing treatment was performed in which the chemical liquid Y (23° C.) was sprayed for 15 seconds at a flow rate of 200 mL/min on the wafer that was being rotated at 50 rpm. Finally, the wafer was dried by being rotated at a high speed of 2,000 rpm for T_{R} seconds.

[Resolution (Pattern Collapse Performance)]

The resolution of the line-and-space pattern exposed in different exposure amounts was observed using a scanning electron microscope (S-9380II manufactured by Hitachi, Ltd.) at a magnification of 200 k. In one field of view observed, the minimum line width at which no pattern collapse occurred was determined, and the line width was adopted as an index of pattern collapse. The lower the index, the better the pattern collapse performance. The obtained minimum line width was evaluated based on the following evaluation standards. The evaluation of pattern collapse performance was performed on a pattern formed using a mask for forming a dense pattern.

(Evaluation Standard)

“A”: The minimum line width was equal to or smaller than 16 nm.

“B”: The minimum line width was greater than 16 nm and equal to or smaller than 18 nm.

“C”: The minimum line width was greater than 18 nm and equal to or smaller than 20 nm.

“D”: The minimum line width was greater than 20 nm and equal to or smaller than 22 nm.

“E”: The minimum line width was greater than 22 nm.

[Comprehensive Evaluation]

For Examples X1 to X26 and Comparative Examples NX1 to NX26, the evaluation standards A to F applied to the evaluation results of defect inhibition performance were converted into 5 to 0 points in this order. Furthermore, the evaluation standards A to E applied to the evaluation results of resolution were converted into 4 to 0 points in this order.

Then, based on the total score of the defect inhibition performance and the resolution, the examples were comprehensively evaluated according to the following standards.

S: The total score was 9.

A: The total score was 8.

B: The total score was 6 to 7.

C: The total score was equal to or lower than 5.

For practical use, the evaluation results graded “B” or higher are preferable.

Table 3 shows the evaluation results. Regarding the chemical liquid Y, the numerical values in each parenthesis for an organic solvent contained in a mixed solution means the Hansen solubility parameter distance to eicosene [unit: MPa^{0.5}].

TABLE 5
Table 3
(Table 3-1)

| | | | Evaluation results | | |
|---|---|---|---|---|---|
| | | | Defect inhibition | | |
| | Chemical liquid X | Chemical liquid Y | performance (after | | Comprehensive |
| | (developer) | (rinsing solution) | passage of time) | Resolution | evaluation |
| Example X1 | Chemical liquid B1 | Butyl butyrate | 5 | 3 | A |
| Example X2 | Chemical liquid B1 | Isobutyl isobutyrate | 5 | 3 | A |
| Example X3 | Chemical liquid B1 | Pentyl propionate | 5 | 3 | A |
| Example X4 | Chemical liquid B1 | Isopentyl propionate | 5 | 3 | A |
| Example X5 | Chemical liquid B1 | Ethyl cyclohexane | 5 | 3 | A |
| Example X6 | Chemical liquid B1 | Mesitylene | 5 | 3 | A |
| Example X7 | Chemical liquid B1 | Decane | 5 | 3 | A |
| Example X8 | Chemical liquid B1 | Undecane | 5 | 3 | A |
| Example X9 | Chemical liquid B1 | 3,7-Dimethyl-3-octanol | 5 | 3 | A |
| Example X10 | Chemical liquid B1 | 2-Ethyl-1-hexanol | 5 | 3 | A |
| Example X11 | Chemical liquid B1 | 1-Octanol | 5 | 3 | A |
| Example X12 | Chemical liquid B1 | 2-Octanol | 5 | 3 | A |
| Example X13 | Chemical liquid B1 | Ethyl acetoacetate | 5 | 3 | A |
| Example X14 | Chemical liquid B1 | Dimethyl malonate | 5 | 3 | A |
| Example X15 | Chemical liquid B1 | Methyl pyruvate | 5 | 3 | A |
| Example X16 | Chemical liquid B1 | Dimethyl oxalate | 5 | 3 | A |
| Example X17 | Chemical liquid B1 | Mixed solvent A1 | 5 | 4 | S |
| | | Butyl butyrate | | | |
| | | (4.6):Undecane | | | |
| | | (1.8) = 1:1 | | | |
| Example X18 | Chemical liquid B2 | Mixed solvent B1 | 5 | 4 | S |
| | | Butyl butyrate | | | |
| | | (4.6):Methanol | | | |
| | | (23.7) = 1:1 | | | |
| Example X19 | Chemical liquid B1 | Mixed solvent A2 | 5 | 3 | A |
| | | Butyl butyrate | | | |
| | | (4.6):Undecane | | | |
| | | (1.8) = 9:1 | | | |
| Example X20 | Chemical liquid B1 | Mixed solvent B2 | 5 | 3 | A |
| | | Butyl butyrate | | | |
| | | (4.6):Methanol | | | |
| | | (23.7) = 9:1 | | | |
| Example X21 | Chemical liquid B1 | Methyl benzoate | 5 | 1 | B |
| Example X22 | Chemical liquid B1 | 2-Ethoxyethyl acetate | 5 | 1 | B |
| Example X23 | Chemical liquid B1 | Benzyl alcohol | 5 | 1 | B |
| Example X24 | Chemical liquid B1 | 2-Butanol | 5 | 1 | B |
| Example X25 | Chemical liquid B1 | 2-Ethoxyethyl acetate | 5 | 1 | B |
| Example X26 | Chemical liquid B1 | N/A | 5 | 1 | B |

TABLE 6
Table 3
(Table 3-2)

| | | | Evaluation results | | |
|---|---|---|---|---|---|
| | | | Defect inhibition | | |
| | Chemical liquid X | Chemical liquid Y | performance (after | | Comprehensive |
| | (developer) | (rinsing solution) | passage of time) | Resolution | evaluation |
| Comparative | Chemical | Butyl butyrate | 0 | 3 | C |
| Example NX1 | liquid NB1 | | | | |
| Comparative | Chemical | Isobutyl isobutyrate | 0 | 3 | C |
| Example NX2 | liquid NB1 | | | | |
| Comparative | Chemical | Pentyl propionate | 0 | 3 | C |
| Example NX3 | liquid NB1 | | | | |
| Comparative | Chemical | Isopentyl propionate | 0 | 3 | C |
| Example NX4 | liquid NB1 | | | | |
| Comparative | Chemical | Ethyl cyclohexane | 0 | 3 | C |
| Example NX5 | liquid NB1 | | | | |
| Comparative | Chemical | Mesitylene | 0 | 3 | C |
| Example NX6 | liquid NB1 | | | | |
| Comparative | Chemical | Decane | 0 | 3 | C |
| Example NX7 | liquid NB1 | | | | |
| Comparative | Chemical | Undecane | 0 | 3 | C |
| Example NX8 | liquid NB1 | | | | |
| Comparative | Chemical | 3,7-Dimethyl-3-octanol | 0 | 3 | C |
| Example NX9 | liquid NB1 | | | | |
| Comparative | Chemical | 2-Ethyl-1-hexanol | 0 | 3 | C |
| Example NX10 | liquid NB1 | | | | |
| Comparative | Chemical | 1-Octanol | 0 | 3 | C |
| Example NX11 | liquid NB1 | | | | |
| Comparative | Chemical | 2-Octanol | 0 | 3 | C |
| Example NX12 | liquid NB1 | | | | |
| Comparative | Chemical | Ethyl acetoacetate | 0 | 3 | C |
| Example NX13 | liquid NB1 | | | | |
| Comparative | Chemical | Dimethyl malonate | 0 | 3 | C |
| Example NX14 | liquid NB1 | | | | |
| Comparative | Chemical | Methyl pyruvate | 0 | 3 | C |
| Example NX15 | liquid NB1 | | | | |
| Comparative | Chemical | Dimethyl oxalate | 0 | 3 | C |
| Example NX16 | liquid NB1 | | | | |
| Comparative | Chemical | Mixed solvent A1 | 0 | 4 | C |
| Example NX17 | liquid NB1 | Butyl butyrate | | | |
| | | (4.6):Undecane | | | |
| | | (1.8) = 1:1 | | | |
| Comparative | Chemical | Mixed solvent B1 | 0 | 4 | C |
| Example NX18 | liquid NB1 | Butyl butyrate | | | |
| | | (4.6):Methanol | | | |
| | | (23.7) = 1:1 | | | |
| Comparative | Chemical | Mixed solvent A2 | 0 | 3 | C |
| Example NX19 | liquid NB1 | Butyl butyrate | | | |
| | | (4.6):Undecane | | | |
| | | (1.8) = 9:1 | | | |
| Comparative | Chemical | Mixed solvent B2 | 0 | 3 | C |
| Example NX20 | liquid NB1 | Butyl butyrate | | | |
| | | (4.6):Methanol | | | |
| | | (23.7) = 9:1 | | | |
| Comparative | Chemical | Methyl benzoate | 0 | 1 | C |
| Example NX21 | liquid NB1 | | | | |
| Comparative | Chemical | 2-Ethoxyethyl acetate | 0 | 1 | C |
| Example NX22 | liquid NB1 | | | | |
| Comparative | Chemical | Benzyl alcohol | 0 | 1 | C |
| Example NX23 | liquid NB1 | | | | |
| Comparative | Chemical | 2-Butanol | 0 | 1 | C |
| Example NX24 | liquid NB1 | | | | |
| Comparative | Chemical | 2-Ethoxyethyl acetate | 0 | 1 | C |
| Example NX25 | liquid NB1 | | | | |
| Comparative | Chemical | N/A | 0 | 1 | C |
| Example NX26 | liquid NB1 | | | | |

As is evident from Table 3 (Table 3-1), in a case where the chemical liquid according to an embodiment of the present invention is used as either a chemical liquid or a rinsing solution, excellent defect inhibition properties are exhibited (Examples X1 to X26).

Particularly, it has been revealed that in a case where the chemical liquid according to the embodiment of the present invention is used as the chemical liquid X (developer) and the organic solvent Y1 is used as the chemical liquid Y (rinsing solution) (Examples X1 to X16), the result of the comprehensive evaluation is better and a higher level of defect inhibition performance and a higher level of resolution can be simultaneously achieved, than in a case where an organic solvent other than the organic solvent Y1 is used as the chemical liquid Y (rinsing solution) (Examples X21 to X26).

Furthermore, from the comparison between Examples X17 and X18 and the comparison between Examples X19 and X20, it has been revealed that in a case where the content of the organic solvent Y₁ (organic solvent having a Hansen solubility parameter distance of 3 to 20 MPa^{0.5} to eicosene) is 20% to 80% by mass with respect to the total mass of the chemical liquid Y (Examples X17 and X18), the result of the comprehensive evaluation is better.

On the other hand, as is evident from Table 3 (Table 3-2), in a case where the chemical liquid according to the embodiment of the present invention is used as none of the chemical liquid and the rinsing solution, at least the defect inhibition performance is insufficient, and the result of the comprehensive evaluation is poor (Comparative Examples NX1 to NX26).

What is claimed is:

1. A chemical liquid comprising:
an organic solvent;
an acid component; and
a metal component,
wherein a content of the acid component is equal to or greater than 1 mass ppt and equal to or smaller than 15 mass ppm with respect to a total mass of the chemical liquid, and
a content of the metal component is 0.001 to 100 mass ppt with respect to the total mass of the chemical liquid.

2. The chemical liquid according to claim 1,
wherein a mass ratio of the content of the acid component to the content of the metal component is 10⁻² to 10⁶.

3. The chemical liquid according to claim 1,
wherein the acid component includes an organic acid, and
a content of the organic acid is equal to or smaller than 1 mass ppm with respect to the total mass of the chemical liquid.

4. The chemical liquid according to claim 3,
wherein the organic acid includes an organic acid having a boiling point equal to or higher than a boiling point of the organic solvent, and
a content of the organic acid having a boiling point equal to or higher than a boiling point of the organic solvent is equal to or smaller than 20% by mass with respect to a total mass of the organic acid.

5. The chemical liquid according to claim 1,
wherein the acid component includes an inorganic acid, and
a content of the inorganic acid is equal to or smaller than 1 mass ppb with respect to the total mass of the chemical liquid.

6. The chemical liquid according to claim 1,
wherein the metal component includes metal-containing particles containing metal atoms, and
a content of the metal-containing particles is 0.00001 to 10 mass ppt with respect to the total mass of the chemical liquid.

7. The chemical liquid according to claim 6,
wherein the metal-containing particles include metal nanoparticles having a particle size of 0.5 to 17 nm, and
the number of the metal nanoparticles contained in a unit volume of the chemical liquid is 1.0×10⁻² to 1.0×10⁶ particles/cm³.

8. The chemical liquid according to claim 1,
wherein the metal component includes metal ions, and
a content of the metal ions is 0.01 to 100 mass ppt with respect to the total mass of the chemical liquid.

9. The chemical liquid according to claim 1,
wherein the metal component includes metal-containing particles and metal ions, and
a mass ratio of a content of the metal-containing particles to a content of the metal ions is 0.00001 to 1.

10. The chemical liquid according to claim 1, further comprising:
water,
wherein a content of the water is equal to or smaller than 1 mass ppm with respect to the total mass of the chemical liquid.

11. The chemical liquid according to claim 1, further comprising:
at least one kind of organic compound selected from the group consisting of a compound having an amide structure, a compound having a sulfonamide structure, a compound having a phosphonamide structure, a compound having an imide structure, a compound having a urea structure, a compound having a urethane structure, and an organic acid ester,
wherein a content of the organic compound is equal to or smaller than 1 mass ppm with respect to the total mass of the chemical liquid.

12. The chemical liquid according to claim 11,
wherein the organic compound is an organic compound having a boiling point equal to or higher than 300° C.

13. The chemical liquid according to claim 11,
wherein the organic acid ester includes at least one kind of compound selected from the group consisting of a phthalic acid ester and a citric acid ester.

14. The chemical liquid according to claim 1,
wherein the organic solvent includes an organic solvent having a boiling point equal to or lower than 250° C., and
a content of the organic solvent having a boiling point equal to or lower than 250° C. is equal to or greater than 90% by mass with respect to a total mass of the organic solvent.

15. The chemical liquid according to claim 1,
wherein the organic solvent has an SP value equal to or smaller than 21.

16. The chemical liquid according to claim 1,
wherein the organic solvent has an ester structure.

17. The chemical liquid according to claim 1,
wherein the organic solvent includes butyl acetate, the acid component includes acetic acid, and
a content of the acetic acid is 0.01 to 15 mass ppm with respect to the total mass of the chemical liquid.

18. The chemical liquid according to claim 1,
wherein the organic solvent includes butyl acetate, the acid component includes n-butanoic acid, and
a content of the n-butanoic acid is equal to or greater than 1 mass ppt and equal to or smaller than 1 mass ppm with respect to the total mass of the chemical liquid.

19. A kit comprising:
a chemical liquid X which is the chemical liquid according to claim 17; and
a chemical liquid Y containing an organic solvent,
wherein the organic solvent contained in the chemical liquid Y includes at least one kind of organic solvent Y selected from the group consisting of butyl butyrate, isobutyl isobutyrate, pentyl propionate, isopentyl propionate, ethylcyclohexane, mesitylene, decane, undecane, 3,7-dimethyl-3-octanol, 2-ethyl-1-hexanol, 1-octanol, 2-octanol, ethyl acetoacetate, dimethyl malonate, methyl pyruvate, and dimethyl oxalate.

20. The kit according to claim 19,
wherein the chemical liquid X is a developer, and
the chemical liquid Y is a rinsing solution.

21. The kit according to claim 19,
wherein the organic solvent Y includes an organic solvent Y1 having a Hansen solubility parameter distance of 3 to 20 MPa^{0.5} to eicosene, and
a content of the organic solvent Y1 is 20% to 80% by mass with respect to a total mass of the chemical liquid Y.

22. A pattern forming method comprising:
a resist film forming step of forming a resist film by using an actinic ray-sensitive or radiation-sensitive resin composition;
an exposure step of exposing the resist film;
a development step of developing the exposed resist film by using a chemical liquid X which is the chemical liquid according to claim 17; and
a rinsing step of performing washing by using a chemical liquid Y containing an organic solvent after the development step,
wherein the organic solvent contained in the chemical liquid Y includes at least one kind of organic solvent Y selected from the group consisting of butyl butyrate, isobutyl isobutyrate, pentyl propionate, isopentyl propionate, ethylcyclohexane, mesitylene, decane, undecane, 3,7-dimethyl-3-octanol, 2-ethyl-1-hexanol, 1-octanol, 2-octanol, ethyl acetoacetate, dimethyl malonate, methyl pyruvate, and dimethyl oxalate.

23. The pattern forming method according to claim 22,
wherein the organic solvent Y includes an organic solvent Y1 having a Hansen solubility parameter distance of 3 to 20 MPa^{0.5} to eicosene, and
a content of the organic solvent Y1 is 20% to 80% by mass with respect to a total mass of the chemical liquid Y.

24. A chemical liquid manufacturing method for obtaining the chemical liquid according to claim 1 by purifying a substance to be purified containing an organic solvent, the method comprising:
a filtration step of filtering the substance to be purified;
an ion removing step of performing an ion exchange process or ion adsorption by a chelating group on the substance to be purified; and
a distillation step of distilling the substance to be purified.

25. The chemical liquid manufacturing method according to claim 24,
wherein a cation exchange resin is used in the ion exchange process.

26. The chemical liquid manufacturing method according to claim 24,
wherein a cation exchange resin and an anion exchange resin are used in the ion exchange process.

27. A chemical liquid storage body comprising:
a container; and
the chemical liquid according to claim 1 that is stored in the container.
